(19) United States
(12) Patent Application Publication
(10) Pub. No.: US 2003/0227059 A1
(43) Pub. Date: Dec. 11, 2003

(54) Semiconductor device and method for manufacturing the same

(75) Inventors: Shinichi Miyake, Kanagawa (JP); Kiyotaka Imai, Kanagawa (JP); Masahiro Ikeda, Kanagawa (JP); Tomohiko Kudo, Kanagawa (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, KANAGAWA (JP)

(21) Appl. No.: 10/457,493

(22) Filed: Jun. 10, 2003

(30) Foreign Application Priority Data
Jun. 10, 2002 (JP) 2002-168980
Nov. 26, 2002 (JP) 2002-343017

(51) Int. Cl. H01L 21/00; H01L 27/01

(52) U.S. Cl. 257/350; 438/152; 257/351; 438/153

(57) ABSTRACT

A BOX layer and an SOI layer are formed on a P type silicon substrate and a P well and an N well are formed in the SOI layer. First P type diffusion regions positioned below S/D regions, a second P type diffusion region positioned below a channel region, a third P type diffusion region positioned between an STI region 4 and a BOX layer 2, and a fourth P type diffusion region as a body contact are formed within the P well, and the second and third P type diffusion regions are positioned at the same level, and further, the second and third P type diffusion regions are formed to have a dopant concentration higher than that of the first P type diffusion region.

### BACKGROUND OF THE INVENTION

1. Field of the Invention

The present invention relates to a semiconductor device having transistors formed in a Silicon On Insulator (SOI) and a method for manufacturing the same, and particularly to a semiconductor device that is able to reduce the size of transistors while keeping current transistor performance and a method for manufacturing the same.

2. Description of the Related Art

Conventionally, an SOI technique has been developed as a method comprising: forming a Buried Oxide (BOX) layer on a silicon substrate; forming an SOI layer on the BOX layer; and forming a MOS transistor in the SOI layer (refer, for example, to Japanese Patent Application No. 2001-36092). FIG. 1A is a cross sectional view of the conventional semiconductor device having Metal Oxide Semiconductor Field Effect Transistors (MOSFETs) formed in the SOI layer and FIG. 1B is a plan view thereof. FIG. 1B illustrates an NMOS transistor 116 shown in FIG. 1A. Note that in FIG. 1B, sidewalls 109 are omitted for simplification.

As shown in FIGS. 1A and 1B, in the conventional semiconductor device, a BOX layer 102 is formed on a P type silicon substrate 101 and an SOI layer 103 is formed thereon. The SOI layer 103 is formed to have a thickness of, for example, 150 nm. Furthermore, a Shallow Trench Isolation (STI) region 104 is formed in the desired portion of the SOI layer 103 and the regions partitioned by the STI region 104 constitute an NMOS transistor formation region 105 and a PMOS transistor formation region 106. The STI region 104 is formed such that the upper surface thereof is exposed at the level of the upper surface of the SOI layer 103 and the lower surface thereof contacts the BOX layer 102. The NMOS transistor formation region 105 and the PMOS transistor formation region 106 of the SOI layer 103 each have a gate insulating film 107 formed therein and a gate electrode 108 formed on the gate insulating film. Moreover, a set of gate insulating film 107 and gate electrode 108 has its side surfaces covered by sidewalls 109. Additionally, the NMOS transistor formation region 105 of the SOI layer 103 has P wells 110 formed therein and the PMOS transistor formation region 106 has N wells 111 formed therein.

A pair of n⁺ (heavily N type doped) diffusion regions 112 disposed facing each other are formed in regions which are established by excluding regions directly below the gate electrode 108 and the sidewalls 109 from the P well 110 and extension regions 113 are formed in regions which are positioned directly below the sidewalls 109 within the P well 110. A set of n⁺ diffusion region 112 and extension region 113 constitutes each of source/drain regions and a region between the extension regions constitutes a channel region. The P well 110, the n⁺ diffusion regions 112, the extension regions 113, the gate insulating film 107, the gate electrode 108 and the sidewalls 109 constitute an NMOS transistor 116.

On the other hand, a pair of p⁺ (heavily P type doped) diffusion regions 114 disposed facing each other are formed in regions which are established by excluding regions directly below the gate electrode 108 and the sidewalls 109 from the N well 111 and extension regions 115 are formed in regions which are positioned directly below the sidewalls 109 within the N well 111. A set of p⁺ diffusion region 114 and extension region 115 constitutes each of source/drain regions and a region between the extension regions constitutes a channel region. The N well 111, the p⁺ diffusion regions 114, the extension regions 115, the gate insulating film 107, the gate electrode 108 and the sidewalls 109 constitute a PMOS transistor 117.

FIGS. 2A through 2D are cross sectional views illustrating a method for manufacturing the aforementioned semiconductor device in the order of manufacturing steps. First, as shown in FIG. 2A, a BOX layer 102 is formed on a P type silicon substrate 101. Then, an SOI layer 103 is formed thereon and an SiO₂ film 118 and an Si₃N₄ 119 film are formed in order on the SOI layer 103. Thereafter, a laminated film consisting of the SiO₂ film 118 and the Si₃N₄ film 119 is patterned to form in the laminated film an opening through which an STI region 104 (refer to FIG. 1A) will be formed in a subsequent step. Subsequently, the SOI layer 103 is etched using the patterned laminated film consisting of the SiO₂ film 118 and the Si₃N₄film as a mask to form a trench 120 that reaches the BOX layer 102.

As shown in FIG. 2B, an SiO₂ film is formed within the trench 120 by High Density Plasma CVD (HDP-CVD) to form the STI region 104 in the desired portion of the SOT layer and the BOX layer. In this case, regions partitioned by the STI region 104 constitute an NMOS transistor formation region 105 and a PMOS transistor formation region 106.

As shown in FIG. 2C, a resist 121 is formed to cover the PMOS transistor formation region 106. Then, P type dopants are implanted using the resist 121 as a mask into the NMOS transistor formation region 105 to form P wells 110. Thereafter, the resist 121 is removed.

As shown in FIG. 2D, a resist 122 is formed to cover the NMOS transistor formation region 105. Then, N type. dopants are implanted using the resist 122 as a mask into the PMOS transistor formation region 106 to form N wells 111. Thereafter, the resist 122 is removed.

Thereafter, as shown in FIG. 1A, sets of gate insulating film 107 and gate electrode 108 are formed on the SOT layer 103 and ion implantation is performed using the sets of gate insulating film 107 and gate electrode 108 as a mask to form extension regions 113 and 115. Then, sidewalls 109 are formed to cover the side surfaces of a set of gate insulating film 107 and gate electrode 108 and ion implantation is performed using a set of gate insulating film 107, gate electrode 108 and sidewalls 109 as a mask to form n⁺ diffusion regions 112 and P⁺ diffusion regions 114. Thus, the semiconductor device shown in FIG. 1A is fabricated.

In the semiconductor device fabricated using an SOI technique, when the NMOS transistor 116 and the PMOS transistor 117 are turned on, a depletion layer formed in each of the P wells 110 and the N wells 111 reaches the BOX layer 102 and the depletion layer appears as if it had a thickness larger than actual thickness. This reduces the source-drain capacitance of SOI transistor down to about one-fourth times the source-drain capacitance of a transistor formed in a bulk semiconductor material, thereby allowing an SOI transistor to operate at a higher speed. Note that a region directly below the gate electrode 108 in each of the P wells 110 and the N wells 111 becomes a neutral region (body) in which a depletion layer is not formed.

Furthermore, in the above-described semiconductor device, increasing the potential of body advantageously decreases the threshold voltage of transistor. Moreover, the transistors formed in the SOT layer are advantageously not affected by variations in the potential of substrate.

However, in the semiconductor device fabricated using the SOI technique, the transistors unfavorably exhibit what is known as the “history effect.” That is, in the above-described semiconductor device, since the BOX layer 102 and the STI region 104 are configured to surround each of the P wells 110 and the N wells 111 in order to completely isolate a well from other wells, the body is floating. This prevents electrons and holes that are injected into the body upon beginning the operation of transistor from exiting to the outside of the body, causing the electrons and holes to accumulate in the body. Consequently, once the transistor begins operating, the potential of the body never returns to a reference potential until the transistor will subsequently begin operating and therefore, the threshold voltage of the transistor never returns to its specific value. This causes the transistor to operate at a speed that varies with frequency.

In order to solve the aforementioned problem, a technique, which is known in the art, for forming a body contact, used to connect a body to the outside, in a source region has been conventionally proposed. FIG. 3 is a plan view of a conventional semiconductor device having a body contact formed therein. N⁺ diffusion regions 112a and 112b are formed correspondingly as a drain region and a source region, and a gate electrode 132 is formed on a channel region (not shown) between the drain and source regions. A p⁺ diffusion region 131 serving as a body contact is formed in the n⁺ diffusion region 112b serving as a source region. Furthermore, the gate electrode 132 is formed in the shape of a letter “T” and one end 133 of the gate electrode 132 is made to extend to the vicinity of the p⁺ diffusion region 131. This allows a body (not shown) formed directly below the gate electrode 132 to extend exhibiting the same geometrical profile as that of the gate electrode 132, resulting in contact with the p⁺ diffusion region 131. Consequently, the body is connected to the outside through the body contact (i.e., the p⁺ diffusion region 131) and then the potential of body is fixed.

However, in the semiconductor device shown in FIG. 3, the layout of a semiconductor device formed in a bulk material needs to be changed to form the gate electrode in the shape of a letter “T.” Furthermore, formation of the “T” shaped gate electrode reduces the width (W₁+W₂) of the source region, reducing on-current while increasing gate capacitance. As a result, transistor performance degrades. Moreover, the source region and the drain region each are unfavorably fixed.

Additionally, a technique has been disclosed as a method comprising: forming an STI region for isolating each of NMOS transistors and PMOS transistors from other transistor components as a partially isolating oxide film (hereinafter, the term “partially isolating oxide film” represents an oxide film formed within a trench that does not reach the BOX layer) so that the STI regions are partially oxidized and the oxidized portions of the STI region never reaches a BOX layer; forming a P well in a region between the BOX layer and the STI region that isolates adjacent NMOS transistors from each other; forming an N well in a region between the BOX layer and the STI region that isolates adjacent PMOS transistors from each other; and connecting the body of transistor to a body contact through the P well or the N well (refer, for example, to Japanese Patent Application No. 2000-243973). Additionally, the STI region between the NMOS transistor and the PMOS transistor is formed as a completely isolating oxide film so that an oxide film is formed within a trench that reaches the BOX layer. Alternatively, the STI region therebetween is formed as a partially isolating oxide film and further both a P well and an N well adjacent each other are formed in the region between the STI region and the BOX layer, thereby isolating the PMOS transistor and the NMOS transistor from each other. This allows the transistor to have the potential of body fixed without degrading its performance.

However, the above-described conventional technique includes the following problems. In order for the transistor disclosed in Japanese Patent Application No. 2000-243973 to maximize its performance, the layout of a transistor needs to be designed satisfying the following conditions. First, a depletion layer is made to reach the BOX layer so that the transistor is able to operate at a higher speed. Secondly, the partially isolating oxide film is formed deeper than the source/drain regions (hereinafter, referred also to as S/D regions) to isolate MOS transistors from one another. Thirdly, the resistance of the SOI layer between the partially isolating oxide film and the BOX layer is made as low as possible to connect the body to the body contact. However, as a semiconductor device is fabricated in a smaller size, it becomes harder for a transistor to satisfy all of the above-described conditions.

That is, as a semiconductor device is fabricated in a smaller size, a transistor comes to have a shorter gate length and therefore, a PN junction of each of S/D regions needs to be formed shallow in order to suppress the short channel effect.

FIG. 4 is a graph illustrating the degree to which the depth of depletion layer is affected by the dopant concentration of well, where an axis of abscissas represents the dopant-concentration of well and an axis of ordinates represents the depth of depletion layer. FIG. 5 is a graph illustrating the degree to which the resistance of substrate is affected by the dopant concentration of well, where an axis of abscissas represents the dopant concentration of well and an axis of ordinates represents the resistance of substrate. FIG. 6 is a graph illustrating relationship between the depth of depletion layer and the resistance of substrate, where an axis of abscissas represents the depth of depletion layer and an axis of ordinates represents the resistance of substrate. As shown in FIG. 4, when the dopant concentration of well is made higher, the depletion layer formed below each of the S/D regions becomes shallower, thereby preventing the depletion layer from reaching the BOX layer. On the other hand, when the dopant concentration of well is made lower in order for the depletion layer to reach the BOX layer, the resistance of substrate becomes higher, increasing the resistance between the body and the body contact, as shown in FIG. 5. That is, as shown in FIG. 6, when the depletion layer is made deeper, the resistance of substrate increases and when the resistance of substrate is made lower, the depletion layer becomes shallower.

Accordingly, the SOI layer needs to be formed thin to allow the depletion layer to reach the BOX layer while the dopant concentration of well is kept high and the resistance of substrate is kept low. However, when the SOI layer is formed thin, it becomes difficult to simultaneously form an STI layer (completely isolating oxide film) that reaches the BOX layer and an STI layer (partially isolating oxide film) that does not reach the BOX layer. Particularly, it becomes difficult to leave the STI layer between the partially isolating oxide film and the BOX layer in order to lower the resistance between the body and the body contact while isolating the S/D regions of adjacent MOS transistors from each other by precisely controlling the thickness of the partially isolating oxide film.

### SUMMARY OF THE INVENTION

The present invention is directed to a semiconductor device having MOS transistors formed in an SOI layer and an object of the present invention is to provide a semiconductor device that allows a depletion layer to reach a BOX layer in order for a transistor to operate at a higher speed and is capable of securely isolate S/D regions of adjacent transistors from each other and fixing the potential of body by reducing a resistance between a body contact and the body of transistor, and further, a method for manufacturing the same.

A first semiconductor device according to the invention comprises: a semiconductor substrate; an insulation film formed on the semiconductor substrate; a semiconductor layer formed on the insulation film; a well of a first conductivity type formed in the semiconductor layer; a transistor of a second conductivity type formed in the well of a first conductivity type; and a field isolation region formed in a surface of the semiconductor layer and isolating each of the transistors of a second conductivity type from other transistor components within the semiconductor layer. In this case, the well of a first conductivity type includes: first diffusion regions of a first conductivity type formed directly below source/drain regions of the transistor of a second conductivity type; a second diffusion region of a first conductivity type formed in a region between the insulation film and the field isolation region, the second diffusion region having a dopant concentration higher than that of the first diffusion region of a first conductivity type; a third diffusion region of a first conductivity type formed at the same level as the second diffusion region of a first conductivity type and directly below a channel region of the transistor, the third diffusion region having a dopant concentration higher than that of the first diffusion region of a first conductivity type; and a fourth diffusion region of a first conductivity type formed in a surface portion of a region connected to the third diffusion region of a first conductivity type, the fourth diffusion region allowing a reference voltage to be applied thereto.

Since the first semiconductor device according to the invention is configured to have the first diffusion region, underlying the S/D regions, of a first conductivity type formed so as to have a dopant concentration lower than that of the third diffusion region of a first conductivity type serving as a body, the device is able to make the junction depth of the S/D regions shallow while making depletion layers formed under the S/D regions reach the insulation film. As a result, the device is able to shorten the gate length of a transistor while suppressing the short channel effect and reduce parasitic capacitance associated with the transistor to increase the speed at which the transistor operates, and further, securely isolate the S/D regions of adjacent transistors from each other. Moreover, since the device is configured to have the second diffusion region of a first conductivity type formed at the same level as the third diffusion region of a first conductivity type and formed to have a dopant concentration higher than that of the first diffusion region of a first conductivity type, the device is able to reduce the resistance between the third diffusion region of a first conductivity type serving as a body and the fourth diffusion region of a first conductivity type serving as a body contact; and thereby securely fix the potential of body.

A second semiconductor device according to the invention comprises: a semiconductor substrate; an insulation film formed on the semiconductor substrate; a semiconductor layer formed on the insulation film; a P well and an N well formed in the semiconductor layer; an N type transistor and a P type transistor formed in the P well and the N well, respectively; and a field isolation region formed in the surface of the P well and the N well, and isolating each of the N type transistor and the P type transistor from other transistor components. In this case, the P well includes: first P type diffusion regions formed directly below source/drain regions of the N type transistor; a second P type diffusion region formed in a region between the insulation film and the field isolation region, and having a dopant concentration higher than that of the first P type diffusion region; a third P type diffusion region formed at the same level as the second P type diffusion region and formed directly below a channel region of the N type transistor, the third P type diffusion region having a dopant concentration higher than that of the first P type diffusion region; and a fourth P type diffusion region formed in a surface portion of a region connected to the third P type diffusion region, the fourth P type diffusion region allowing a first reference voltage to be applied thereto, and the N well includes: first N type diffusion regions formed directly below source/drain regions of the P type transistor; a second N type diffusion region formed in a region between the insulation film and the field isolation region, and having a dopant concentration higher than that of the first N type diffusion region; a third N type diffusion region formed at the same level as the second N type diffusion region and directly below a channel region of the P type transistor, and having a dopant concentration higher than that of the first N type diffusion region; and a fourth N type diffusion region formed in a surface portion of a region connected to the third N type diffusion region, the fourth N type diffusion region allowing a second reference voltage to be applied thereto.

In the invention, employment of the second semiconductor device incorporating therein an N type transistor and a P type transistor produces beneficial effects similar to those produced by employment of the aforementioned first semiconductor device.

Furthermore, the second semiconductor device may be configured to make the second reference voltage higher than the first reference voltage and have the second P type diffusion region and the second N type diffusion region disposed between the field isolation region and the insulation film and between the N type transistor and the P type transistor so as to contact each other. This allows the device to have a PN-junction isolation formed in a boundary between the second P type diffusion region and the second N type diffusion region, securely isolating the N type transistor and the P type transistor from each other.

Alternatively, the device may be configured so that a lower end of the field isolation region positioned between the N type transistor and the P type transistor contacts an upper surface of the insulation film. This allows the device to make the width of the field isolation region narrower and further, securely isolate the N type transistor and the P type transistor from each other.

Moreover, the device may be constructed such that the N type transistor and the P type transistor share a gate electrode and the fourth P type diffusion region, the N type transistor, the P type transistor and the fourth N type diffusion region are arranged in this order in a line. This allows the device to shorten the distance between the third P type diffusion region serving as a body and the fourth P type diffusion region serving as a body contact to reduce the resistance therebetween, and further, shorten the distance between the third N type diffusion region serving as a body and the fourth N type diffusion region serving as a body contact to reduce the resistance therebetween.

Still furthermore, the device may be constructed such that the fourth P type diffusion region is formed in a region of the semiconductor layer so as to interpose a part of the field isolation region between the N type transistor and the region of the semiconductor layer, and the second P type diffusion region is formed between the part of the field isolation region and the insulation film, and further, the first reference voltage is applied to the third P type diffusion region via the second P type diffusion region and the fourth P type diffusion region. This allows the device to further reduce the resistance of body formed between the third P type diffusion region and the fourth P type diffusion region, thereby, more effectively fixing the potential of body. Likewise, the device may be constructed such that the fourth N type diffusion region is formed in a region of the semiconductor layer so as to interpose a part of the field isolation region between the P type transistor and the region of the semiconductor layer, and the second N type diffusion region is formed between the part of the field isolation region and the insulation film, and further, the second reference voltage is applied to the third N type diffusion region via the second N type diffusion region and the fourth N type diffusion region.

A third semiconductor device according to the invention comprises: a semiconductor substrate; an insulation film formed on the semiconductor substrate; a semiconductor layer formed on the insulation film; a well of a first conductivity type formed in the semiconductor layer; a first transistor of a second conductivity type and a second transistor of a second conductivity type, both transistors being formed in the well of a first conductivity type; and a field isolation region formed in a surface of the semiconductor layer and isolating each of the first and second transistors of a second conductivity type from other transistor components. In this case, the well of a first conductivity type includes: first diffusion regions of a first conductivity type formed directly below source/drain regions of the first transistor of a second conductivity type; a second diffusion region of a first conductivity type formed in a region between the insulation film and the field isolation region, and having a dopant concentration higher than that of the first diffusion region of a first conductivity type; a third diffusion region of a first conductivity type formed at the same level as the second diffusion region of a first conductivity type and directly below a channel region of each of the first and second transistor of a second conductivity type, and having a dopant concentration higher than that of the first diffusion region of a first conductivity type; and a fourth diffusion region of a first conductivity type formed in a surface portion of a region connected to the third diffusion region of a first conductivity type, the fourth diffusion region allowing a reference voltage to be applied thereto; and fifth diffusion regions of a first conductivity type formed directly below source/drain regions of the second transistor of a second conductivity type, and having a dopant concentration higher than that of the first diffusion region of a first conductivity type.

The third semiconductor device according to the invention employs the first transistor of a second conductivity type configured to produce beneficial effects similar to those produced by employment of the corresponding transistor in the first semiconductor device and further, the second transistor of a second conductivity type configured to include the fifth diffusion region of a first conductivity type formed to have a dopant concentration higher than that of the first diffusion region of a first conductivity type, allowing the second transistor of a second conductivity type to reduce the depth of depletion layer. Accordingly, although the operating speed at which the second transistor of a second conductivity type operates becomes lower than the operating speed at which the first transistor of a second conductivity type, the third diffusion region of a first conductivity type is connected to the fourth diffusion region of a first conductivity type via the fifth diffusion region of a first conductivity type and therefore, the potential of body can more securely be fixed, allowing the transistor to reduce floating body effects and then, more securely suppress variations in threshold voltage. The semiconductor device constructed as described above is suitably made available so that, for example, the first transistor of a second conductivity type is used in a digital circuit and the second transistor of a second conductivity type is used in an analog circuit.

Furthermore, preferably, the device is constructed such that a lower end of the field isolation region positioned between the first transistor of a second conductivity type and the second transistor of a second conductivity type contacts an upper surface of the insulation film. This prevents noise generated by the first transistor of a second conductivity type from entering the second transistor of a second conductivity type, allowing the second transistor of a second conductivity type to more securely suppress variations in threshold voltage.

A fourth semiconductor device according to the invention comprises: a semiconductor substrate; an insulation film formed on the semiconductor substrate; a semiconductor layer formed on the insulation film; a well of a first conductivity type locally formed in the semiconductor layer; first and second transistors of a second conductivity type formed in the well of a first conductivity type; a first field isolation region formed in a surface of the semiconductor layer and having a lower surface positioned such that at least a part of the lower surface does not contact the insulation film, the first field isolation region isolating the first transistor of a second conductivity type from other transistor components; and a second field isolation region formed in a surface of the semiconductor layer and having a lower surface positioned so as to contact the insulation film, the second field isolation region isolating the second transistor of a second conductivity type from other transistor components. In this case, the well of a first conductivity type includes: first diffusion regions of a first conductivity type formed directly below source/drain regions of each of the first and second transistors of a second conductivity type; a second diffusion region of a first conductivity type formed in a region between the insulation film and the first field isolation region, and having a dopant concentration higher than that of the first diffusion region of a first conductivity type; a third diffusion region of a first conductivity type formed at the same level as the second diffusion region of a first conductivity type and directly below a channel region of each of the first and second transistors of a second conductivity type, and having a dopant concentration higher than that of the first diffusion region of a first conductivity type; and a fourth diffusion region of a first conductivity type formed in a surface portion of a region connected to the third diffusion region of a first conductivity type via the second diffusion region of a first conductivity type, the third diffusion region being positioned in the first transistor of a second conductivity type, the fourth diffusion region allowing a reference voltage to be applied thereto.

The fourth semiconductor device according to the invention employs the first transistor of a second conductivity type configured to produce beneficial effects similar to those produced by employment of the corresponding transistor in the first semiconductor device of the invention and further, the second transistor of a second conductivity type constructed to show the floating biased body configuration, allowing the second transistor of a second conductivity type to operate at a more higher speed. As a result, the first transistor of a second conductivity type is used as a transistor in a case where stability of threshold voltage of transistor takes priority over operating speed at which a transistor operates and the second transistor of a second conductivity type is used as a transistor in a case where operating speed at which a transistor operates takes priority over stability of threshold voltage of transistor. This results in optimal performance in the semiconductor device.

A fifth semiconductor device according to the invention comprises: a semiconductor substrate; an insulation film formed on the semiconductor substrate; a semiconductor layer formed on the insulation film; a P well and an N well, both being locally formed in the semiconductor layer; first and second N type transistors formed in the P well; first and second P type transistors formed in the N well; a first field isolation region formed in a surface of the semiconductor layer and having a lower surface positioned such that at least a part of the lower surface does not contact the insulation film, the first field isolation region isolating each of the first P type transistor and the first N type transistor from other transistor components; and a second field isolation region formed in a surface portion of the semiconductor layer and having a lower surface positioned so as to contact the insulation film, the second field isolation region isolating each of the second P type transistor and the second N type transistor from other transistor components. In this case, the P well includes: first P type diffusion regions formed directly below source/drain regions of each of the first and second N type transistors; a second P type diffusion region formed in a region between the insulation film and the first field isolation region, and having a dopant concentration higher than that of the first P type diffusion region; a third P type diffusion region formed at the same level as the second P type diffusion region and directly below a channel region of each of the first and second N type transistors, and having a dopant concentration higher than that of the first P type diffusion region; and a fourth P type diffusion region formed in a surface portion of a region connected via the second P type diffusion region to the third P type diffusion region of the first N type transistor, the fourth P type diffusion region allowing a first reference voltage to be applied thereto, and further, the N well includes: first N type diffusion regions formed directly below source/drain regions of each of the first and second P type transistors; a second N type diffusion region formed in a region between the insulation film and the first field isolation region, and having a dopant concentration higher than that of the first N type diffusion region; a third N type diffusion region formed at the same level as the second N type diffusion region and directly below a channel region of each of the first and second P type transistors, and having a dopant concentration higher than that of the first N type diffusion region; and a fourth N type diffusion region formed in a surface portion of a region connected via the second N type diffusion region to the third N type diffusion region of the first P type transistor, the fourth N type diffusion region allowing a second reference voltage to be applied thereto.

A first method for manufacturing a semiconductor device according to the invention comprises the steps of: forming an insulation film on a semiconductor substrate; forming a semiconductor layer on the insulation film; forming a well of a first conductivity type within the semiconductor layer; forming a field isolation region in a surface of the semiconductor layer; forming a second diffusion region of a first conductivity type between the insulation film and the field isolation region within the well of a first conductivity type, and further, forming a fourth diffusion region of a first conductivity type in a part of a surface portion of the well of a first conductivity type, the fourth diffusion region allowing a reference voltage to be applied thereto; forming a gate insulating film and a gate electrode on the well of a first conductivity type; implanting dopants of a first conductivity type within the semiconductor layer through the gate insulating film and the gate electrode to form a third diffusion region of a first conductivity type in a region positioned directly below the gate electrode and at the same level as the second diffusion region of a first conductivity type within the semiconductor layer; and implanting dopants of a second conductivity type into a surface portion of the well of a first conductivity type using the gate insulating film and the gate electrode as a mask to form source/drain regions in specific regions within the well of a first conductivity type, resulting in formation of a transistor of a second conductivity type, the specific regions interposing a region positioned directly below the gate electrode therebetween.

According to the first method employed in the invention, the third diffusion region of a first conductivity type can be formed self-aligned to and directly below the gate electrode. This allows the aforementioned first semiconductor device of the invention to be manufactured with high accuracy.

A second method for manufacturing a semiconductor device according to the invention comprises the steps of: forming an insulation film on a semiconductor substrate; forming a semiconductor layer on the insulation film; forming a well of a first conductivity type within the semiconductor layer; forming a field isolation region in a surface of the semiconductor layer; implanting dopants of a first conductivity type into the well of a first conductivity type to form a second diffusion region of a first conductivity type in a region between the insulation film and the field isolation region within the well of a first conductivity type, and further, form a third diffusion region of a first conductivity type and a fourth diffusion region of a first conductivity type in a part of a surface portion of the well of a first conductivity type, the fourth diffusion region allowing a reference voltage to be applied thereto; forming a gate insulating film and a gate electrode on the third diffusion region of a first conductivity type; and implanting dopants of a second conductivity type into a surface portion of the well of a first conductivity type using the gate insulating film and the gate electrode as a mask to form source/drain regions in specific regions within the well of a first conductivity type, resulting in formation of a transistor of a second conductivity type, the specific regions interposing a region positioned directly below the gate electrode therebetween.

A third method for manufacturing a semiconductor device according to the invention comprises the steps of: forming an insulation film on a semiconductor substrate; forming a semiconductor layer on the insulation film; forming a field isolation region in a surface of the semiconductor layer; forming a well of a first conductivity type within the semiconductor layer; forming a gate insulating film and a gate electrode on the semiconductor layer; implanting dopants of a second conductivity type into the well of a first conductivity type using the gate insulating film and the gate electrode as a mask to form first diffusion regions of a first conductivity type in specific regions within the well of a first conductivity type, the specific regions interposing a region positioned directly below the gate electrode therebetween, the first diffusion regions having a net dopant concentration lower than that of the well of a first conductivity type; and implanting dopants of a second conductivity type into a surface portion of the well of a first conductivity type using the gate insulating film and the gate electrode as a mask to form source/drain regions in specific regions within the well of a first conductivity type, resulting in formation of a transistor of a second conductivity type, the specific regions interposing a region positioned directly below the gate electrode therebetween.

A fourth method for manufacturing a semiconductor device according to the invention comprises the steps of: forming an insulation film on a semiconductor substrate; forming a semiconductor layer on the insulation film; forming a P well and an N well within the semiconductor layer; forming a field isolation region in a surface of the semiconductor layer; forming a second P type diffusion region in a region between the insulation film and the field isolation region within the P well, and further, forming a fourth P type diffusion region in a part of a surface portion of the P well, the fourth P type diffusion region allowing a reference voltage to be applied thereto; forming a second N type diffusion region in a region between the insulation film and the field isolation region within the N well, and further, forming a fourth N type diffusion region in a part of a surface portion of the N well, the fourth N type diffusion region allowing a reference voltage to be applied thereto; forming a gate insulating film and a gate electrode on each of the P well and the N well; implanting P type dopants within the P well through the gate insulating film and the gate electrode to form a third P type diffusion region in a region positioned directly below the gate electrode and at the same level as the second P type diffusion region within the P well; implanting N type dopants within the N well through the gate insulating film and the gate electrode to form a third N type diffusion region in a region positioned directly below the gate electrode and at the same level as the second N type diffusion region within the N well; implanting N type dopants into a surface portion of the P well using the gate insulating film and the gate electrode as a mask to form source/drain regions in specific regions within the P well, resulting in formation of an N type transistor, the specific regions interposing a region positioned directly below the gate electrode therebetween; and implanting P type dopants into a surface portion of the N well using the gate insulating film and the gate electrode as a mask to form source/drain regions in specific regions within the N well, resulting in formation of a P type transistor, the specific regions interposing a region positioned directly below the gate electrode therebetween.

A fifth method for manufacturing a semiconductor device according to the invention comprises the steps of: forming an insulation film on a semiconductor substrate; forming a semiconductor layer on the insulation film; forming a P well and an N well within the semiconductor layer; forming a field isolation region in a surface of the semiconductor layer; implanting P type dopants into the P well to form a second P type diffusion region in a region between the insulation film and the field isolation region within the P well, and further, form a third P type diffusion region and a fourth P type diffusion region in a part of a surface portion of the P well, the fourth P type diffusion region allowing a first reference voltage to be applied thereto; implanting N type dopants into the N well to form a second N type diffusion region in a region between the insulation film and the field isolation region within the N well, and further, form a third N type diffusion region and a fourth N type diffusion region in a part of a surface portion of the N well, the fourth P type diffusion region allowing a second reference voltage to be applied thereto; forming a gate insulating film and a gate electrode on each of the third P type diffusion region and the third N type diffusion region; implanting N type dopants into a surface portion of the P well using the gate insulating film and the gate electrode as a mask to form source/drain regions in specific regions within the P well, resulting in formation of an N type transistor, the specific regions interposing a region positioned directly below the gate electrode therebetween; and implanting P type dopants into a surface portion of the N well using the gate insulating film and the gate electrode as a mask to form source/drain regions in specific regions within the N well, resulting in formation of a P type transistor, the specific regions interposing a region positioned directly below the gate electrode therebetween.

According to the fifth method employed in the invention, each of the third P type diffusion region and the third N type diffusion region can be formed self-aligned to and directly below the gate electrode. This allows the aforementioned second semiconductor device of the invention to be manufactured with high accuracy.

A sixth method for manufacturing a semiconductor device according to the invention comprises the steps of: forming an insulation film on a semiconductor substrate; forming a semiconductor layer on the insulation film; forming a field isolation region in a surface of the semiconductor layer; forming a P well and an N well within the semiconductor layer; forming a gate insulating film and a gate electrode on each of the P well and the N well; implanting N type dopants into the P well using the gate insulating film and the gate electrode as a mask to form first P type diffusion regions in specific regions within the P well, the specific regions interposing a region positioned directly below the gate electrode therebetween, the first P type diffusion regions having a net dopant concentration lower than that of the P well; implanting P type dopants into the N well using the gate insulating film and the gate electrode as a mask to form first N type diffusion regions in specific regions within the N well, the specific regions interposing a region positioned directly below the gate electrode therebetween, the first N type diffusion regions having a net dopant concentration lower than that of the N well; implanting N type dopants into a surface portion of the P well using the gate insulating film and the gate electrode as a mask to form source/drain regions in specific regions within the P well, resulting in formation of an N type transistor, the specific regions interposing a region positioned directly below the gate electrode therebetween; and implanting P type dopants into a surface portion of the N well using the gate insulating film and the gate electrode as a mask to form source/drain regions in specific regions within the N well, resulting in formation of a P type transistor, the specific regions interposing a region positioned directly below the gate electrode therebetween.

A seventh method for manufacturing a semiconductor device according to the invention comprises the steps of: forming an insulation film on a semiconductor substrate; forming a semiconductor layer on the insulation film; forming a P well and an N well within the semiconductor layer; forming a field isolation region in a surface of the semiconductor layer; implanting P type dopants into a portion of the P well to form a third P type diffusion region and further form a second P type diffusion region in a region between the insulation film and the field isolation region; implanting N type dopants into a portion of the N well to form a third N type diffusion region and further form a second N type diffusion region in a region between the insulation film and the field isolation region; forming a gate insulating film and a gate electrode on each of the third P type diffusion region and the third N type diffusion region; and implanting N type dopants into a surface portion of the P well using the gate insulating film and the gate electrode as a mask to form source/drain regions in specific regions within the P well, resulting in formation of an N type transistor, the specific regions interposing a region positioned directly below the gate electrode therebetween; implanting P type dopants into a surface portion of the N well using the gate insulating film and the gate electrode as a mask to form source/drain regions in specific regions within the N well, resulting in formation of a P type transistor, the specific regions interposing a region positioned directly below the gate electrode therebetween; forming a fourth P type diffusion region in a part of a surface portion of the P well, the fourth P type diffusion region allowing a reference voltage to be applied thereto; and forming a fourth N type diffusion region in a part of a surface portion of the N well, the fourth N type diffusion region allowing a reference voltage to be applied thereto.

An eighth method for manufacturing a semiconductor device according to the invention comprises the steps of: forming an insulation film on a semiconductor substrate; forming a semiconductor layer on the insulation film; locally forming a well of a first conductivity type within the semiconductor layer; forming a first trench in a surface of the semiconductor layer, the first trench being formed so as not to reach the insulation film; forming a second trench in a part of the first trench, the second trench being formed so as to reach the insulation film; implanting dopants of a first conductivity type into a portion of a region surrounded by the first trench within the well of a first conductivity type to form a second diffusion region of a first conductivity type; filling the first and second trenches with an insulating material to form first and second field isolation regions, respectively; implanting dopants of a first conductivity type into a portion of the well of a first conductivity type to form a third diffusion region of a first conductivity type and further form a fourth diffusion region of a first conductivity type connected via the second diffusion region of a first conductivity type to the third diffusion region of a first conductivity type, the third diffusion region being formed in a region partitioned by the first field isolation region, the fourth diffusion region allowing a reference voltage to be applied thereto; and forming source/drain regions in first diffusion regions of a first conductivity type, the first diffusion regions interposing the third diffusion region of a first conductivity type therebetween, and further, forming a gate insulating film and a gate electrode on the third diffusion region of a first conductivity type, resulting in formation of a first transistor of a second conductivity type in a region partitioned by the first field isolation region and formation of a second transistor of a second conductivity type in a region partitioned by the second field isolation region.

A ninth method for manufacturing a semiconductor device according to the invention comprises the steps of: forming an insulation film on a semiconductor substrate; forming a semiconductor layer on the insulation film; locally forming a P well and an N well within the semiconductor layer; forming a first trench in a surface of the semiconductor layer, the first trench being formed so as not to reach the insulation film; forming a second trench in a part of the first trench, the second trench being formed so as to reach the insulation film; implanting P type dopants into a portion of a region surrounded by the first trench within the P well to form a second P type diffusion region; implanting N type dopants into a portion of a region surrounded by the first trench within the N well to form a second N type diffusion region; filling the first and second trenches with an insulating material to form first and second field isolation regions, respectively; implanting P type dopants into a portion of the P well to form a third P type diffusion region and further form a fourth P type diffusion region connected via the second P type diffusion region to the third P type diffusion region, the third P type diffusion region being formed in a region partitioned by the first field isolation region, the fourth P type diffusion region allowing a first reference voltage to be applied thereto; implanting N type dopants into a portion of the N well to form a third N type diffusion region and further form a fourth N type diffusion region connected via the second N type diffusion region to the third N type diffusion region, the third N type diffusion region being formed in a region partitioned by the first field isolation region, the fourth N type diffusion region allowing a second reference voltage to be applied thereto; forming source/drain regions in first P type diffusion regions, the first P type diffusion regions interposing the third P type diffusion region therebetween, and further, forming a gate insulating film and a gate electrode on the third P type diffusion region, resulting in formation of a first N type transistor in a region partitioned by the first field isolation region and formation of a second N type transistor in a region partitioned by the second field isolation region; and forming source/drain regions in first N type diffusion regions, the first N type diffusion regions interposing the third N type diffusion region therebetween, and further, forming a gate insulating film and a gate electrode on the third N type diffusion region, resulting in formation of a first P type transistor in a region partitioned by the first field isolation region and formation of a second P type transistor in a region partitioned by the second field isolation region.

As described above, according to the methods employed in the invention, since the regions underlying S/D regions are formed to have a dopant concentration lower than that of the body, the depletion layer can be made to reach the insulation film and at the same time, the S/D regions can be formed to have a shallow junction depth, allowing the transistor to operate at a higher speed and reduce its size. In addition, since the body contact is provided within the transistor formation region and further the diffusion region is provided between the insulation film and the field isolation region and at the same level as the body to have a dopant concentration higher than that of the regions underlying the S/D regions, the resistance between the body and the body contact can be reduced and the potential of body can securely be fixed.

### BRIEF DESCRIPTION OF THE DRAWINGS

FIG. 1A is a cross sectional view of the conventional semiconductor device having MOSFETs formed in the SOI layer and FIG. 1B is a plan view thereof;

FIGS. 2A through 2D are cross sectional views illustrating a method for manufacturing the aforementioned semiconductor device in the order of manufacturing steps;

FIG. 3 is a plan view of a conventional semiconductor device having a body contact formed therein;

FIG. 4 is a graph illustrating the degree to which the depth of depletion layer is affected by the dopant concentration of well, where an axis of abscissas represents the dopant concentration of well and an axis of ordinates represents the depth of depletion layer;

FIG. 5 is a graph illustrating the degree to which the resistance of substrate is affected by the dopant concentration of well, where an axis of abscissas represents the dopant concentration of well and an axis of ordinates represents the resistance of substrate;

FIG. 6 is a graph illustrating relationship between the depth of depletion layer and the resistance of substrate, where an axis of abscissas represents the depth of depletion layer and an axis of ordinates represents the resistance of substrate;

FIG. 7A is a plan view of a semiconductor device of a first embodiment of the invention and FIG. 7B is a cross sectional view taken along line A-A shown in FIG. 7A;

FIG. 8 is a schematic plan view illustrating body resistors employed in the semiconductor device;

FIGS. 9A through 9D are cross sectional views illustrating a method for manufacturing a semiconductor device in accordance with the embodiment in the order of manufacturing steps;

FIGS. 10A through 10D are cross sectional views illustrating a method for manufacturing a semiconductor device in accordance with a modification of the first embodiment of the invention in the order of manufacturing steps;

FIGS. 11A through 11D are cross sectional views illustrating a method for manufacturing a semiconductor device in accordance with the modification in the order of manufacturing steps, wherein the step shown FIG. 11A is the step subsequent to the step shown in FIG. 10D;

FIGS. 12A through 12D are cross sectional views illustrating a method for manufacturing a semiconductor device in accordance with another modification of the first embodiment in the order of manufacturing steps;

FIGS. 13A and 13B are cross sectional views illustrating a method for manufacturing a semiconductor device in accordance with the modification in the order of manufacturing steps, wherein the step shown FIG. 13A is the step subsequent to the step shown in FIG. 12D;

FIGS. 14A and 14B are cross sectional views illustrating a method for manufacturing a semiconductor device in accordance with the modification in the order of manufacturing steps, wherein the step shown FIG. 14A is the step subsequent to the step shown in FIG. 13D;

FIG. 15A is a plan view of a semiconductor device according to a second embodiment of the invention and FIG. 15B is a cross sectional view taken along line B-B shown in FIG. 15A;

FIGS. 16A through 16D are cross sectional views illustrating a method for manufacturing a semiconductor device in accordance with the embodiment in the order of manufacturing steps;

FIGS. 17A through 17D are cross sectional views illustrating a method for manufacturing a semiconductor device in accordance with the modification of the second embodiment of the invention in the order of manufacturing steps;

FIGS. 18A through 18D are cross sectional views illustrating a method for manufacturing a semiconductor device in accordance with the modification in the order of manufacturing steps, wherein the step shown FIG. 18A is the step subsequent to the step shown in FIG. 17D;

FIGS. 19A and 19B are cross sectional views illustrating a method for manufacturing a semiconductor device in accordance with another modification of the second embodiment in the order of manufacturing-steps;

FIGS. 20A and 20B are cross sectional views illustrating a method for manufacturing a semiconductor device in accordance with the modification in the order of manufacturing steps, wherein the step shown FIG. 20A is the step subsequent to the step shown in FIG. 19B;

FIG. 21A is a plan view of a semiconductor device according to a third embodiment of the invention and FIG. 21B is a cross sectional view taken along line C-C shown in FIG. 21A;

FIG. 22A is a plan view of a semiconductor device according to a fourth embodiment of the invention and FIG. 22B is a cross sectional view taken along line D-D shown in FIG. 22A;

FIG. 23A is a plan view of a semiconductor device according to a fifth embodiment of the invention and FIG. 23B is a cross sectional view taken along line E-E shown in FIG. 23A, and FIG. 23C is a cross sectional view taken along line E-E shown in FIG. 23A and schematically illustrating regions over which a depletion layer is formed;

FIG. 24A is a plan view of a semiconductor device according to a sixth embodiment of the invention and FIG. 24B is a cross sectional view taken along line F-F shown in FIG. 24A, and FIG. 24C is a cross sectional view taken along line F-F shown in FIG. 24A and schematically illustrating regions over which a depletion layer is formed;

FIG. 25 is a cross sectional view of a semiconductor device according to a seventh embodiment of the invention;

FIGS. 26A through 26C are cross sectional views illustrating a method for manufacturing a semiconductor device in accordance with the embodiment in the order of manufacturing steps;

FIGS. 27A and 27B are cross sectional views illustrating a method for manufacturing a semiconductor device in accordance with the embodiment in the order of manufacturing steps, wherein the step shown FIG. 27A is the step subsequent to the step shown in FIG. 26C;

FIG. 28A is a plan view of a semiconductor device according to an eighth embodiment of the invention and FIG. 28B is a cross sectional view taken along line G-G shown in FIG. 28A;

FIG. 29A is a plan view of a semiconductor device according to a ninth embodiment of the invention and FIG. 29B is a cross sectional view taken along line H-H shown in FIG. 29A;

FIGS. 30A through 30C are cross sectional views of a BST type SOI transistor according to the embodiment and FIG. 30A illustrates core transistors formed in a core section of the semiconductor device, and FIG. 30B illustrates I/O transistors formed in an I/O section, and FIG. 30C illustrates SRAM transistors formed in an SRAM section;

FIGS. 31A and 31B are views illustrating a method for manufacturing a semiconductor device in accordance with the embodiment in the order of manufacturing steps and FIG. 31A is a plan view, and FIG. 31B is a cross sectional view;

FIGS. 32A and 32B are views illustrating a method for manufacturing a semiconductor device in accordance with the embodiment in the order of manufacturing steps, wherein FIGS. 32A and 32B are the steps subsequent to the steps shown in FIGS. 31A and 31B, respectively, and FIG. 32A is a plan view, and FIG. 32B is a cross sectional view;

FIGS. 33A and 33B are views illustrating a method for manufacturing a semiconductor device in accordance with the embodiment in the order of manufacturing steps, wherein FIGS. 33A and 33B are the steps subsequent to the steps shown in FIGS. 32A and 32B, respectively, and FIG. 33A is a plan view, and FIG. 33B is a cross sectional view;

FIGS. 34A and 34B are views illustrating a method for manufacturing a semiconductor device in accordance with the embodiment in the order of manufacturing steps, wherein FIGS. 34A and 34B are the steps subsequent to the steps shown in FIGS. 33A and 33B, respectively, and FIG. 34A is a plan view, and FIG. 34B is a cross sectional view;

FIGS. 35A and 35B are views illustrating a method for manufacturing a semiconductor device in accordance with the embodiment in the order of manufacturing steps, wherein FIGS. 35A and 35B are the steps subsequent to the steps shown in FIGS. 34A and 34B, respectively, and FIG. 35A is a plan view, and FIG. 35B is a cross sectional view;

FIGS. 36A and 36B are views illustrating a method for manufacturing a semiconductor device in accordance with the embodiment in the order of manufacturing steps, wherein FIGS. 36A and 36B are the steps subsequent to the steps shown in FIGS. 35A and 35B, respectively, and FIG. 36A is a plan view, and FIG. 36B is a cross sectional view;

FIGS. 37A and 37B are views illustrating a method for manufacturing a semiconductor device in accordance with the embodiment in the order of manufacturing steps, wherein FIGS. 37A and 37B are the steps subsequent to the steps shown in FIGS. 36A and 36B, respectively, and FIG. 37A is a plan view, and FIG. 37B is a cross sectional view;

FIGS. 38A and 38B are views illustrating a method for manufacturing a semiconductor device in accordance with the embodiment in the order of manufacturing steps, wherein FIGS. 38A and 38B are the steps subsequent to the steps shown in FIGS. 37A and 37B, respectively, and FIG. 38A is a plan view, and FIG. 38B is a cross sectional view;

FIGS. 39A and 39B are views illustrating a method for manufacturing a semiconductor device in accordance with the embodiment in the order of manufacturing steps, wherein FIGS. 39A and 39B are the steps subsequent to the steps shown in FIGS. 38A and 38B, respectively, and FIG. 39A is a plan view, and FIG. 39B is a cross sectional view;

FIGS. 40A and 40B are views illustrating a method for manufacturing a semiconductor device in accordance with the embodiment in the order of manufacturing steps, wherein FIGS. 40A and 40B are the steps subsequent to the steps shown in FIGS. 39A and 39B, respectively, and FIG. 40A is a plan view, and FIG. 40B is a cross sectional view;

FIGS. 41A and 41B are views illustrating a method for manufacturing a semiconductor device in accordance with the embodiment in the order of manufacturing steps, wherein FIGS. 41A and 41B are the steps subsequent to the steps shown in FIGS. 40A and 40B, respectively, and FIG. 41A is a plan view, and FIG. 41B is a cross sectional view; and

FIGS. 42A and 42B are views illustrating a method for manufacturing a semiconductor device in accordance with the embodiment in the order of manufacturing steps, wherein FIGS. 42A and 42B are the steps subsequent to the steps shown in FIGS. 41A and 41B, respectively, and FIG. 42A is a plan view, and FIG. 42B is a cross sectional view.

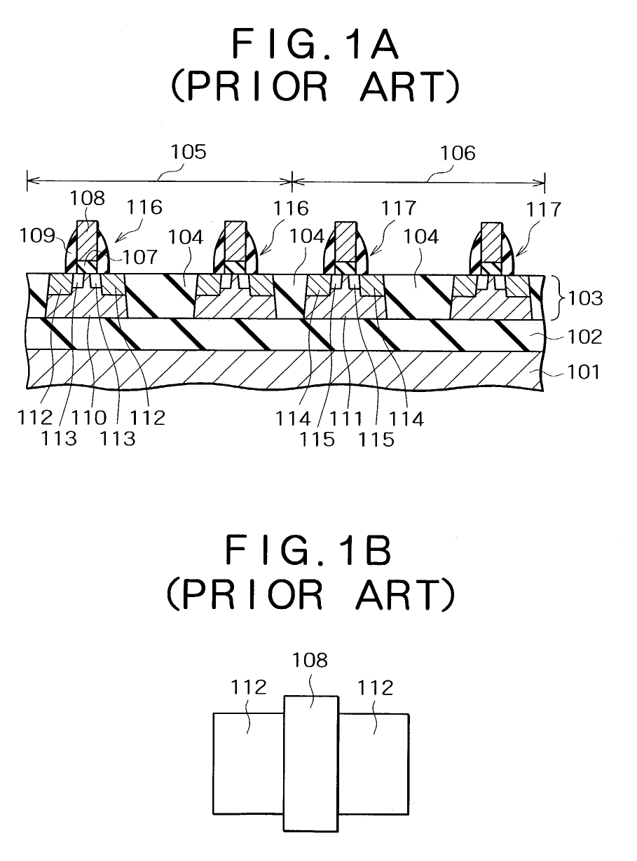

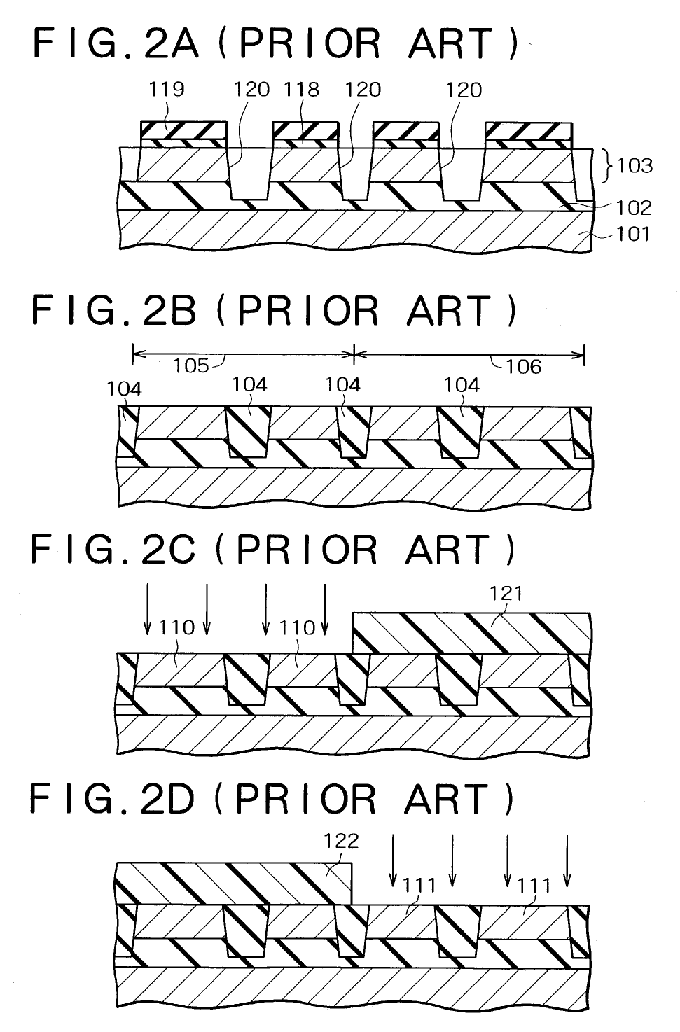

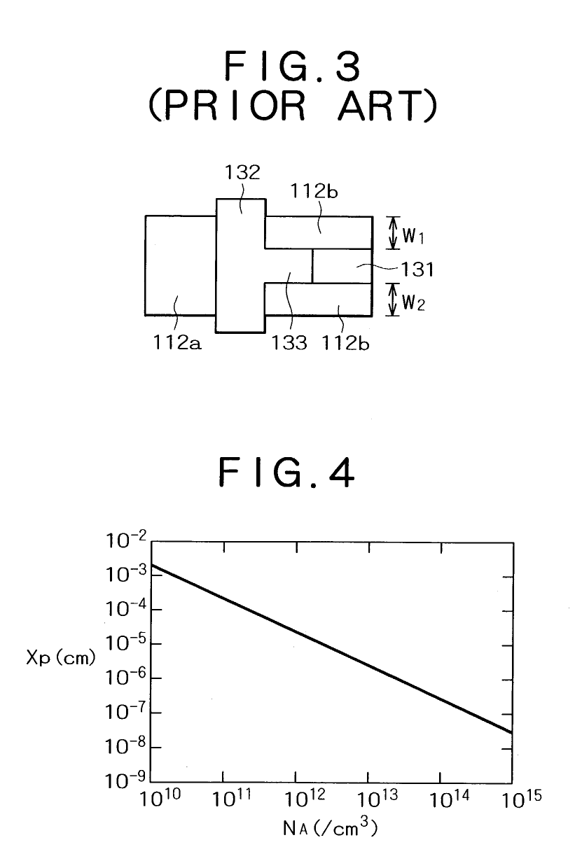

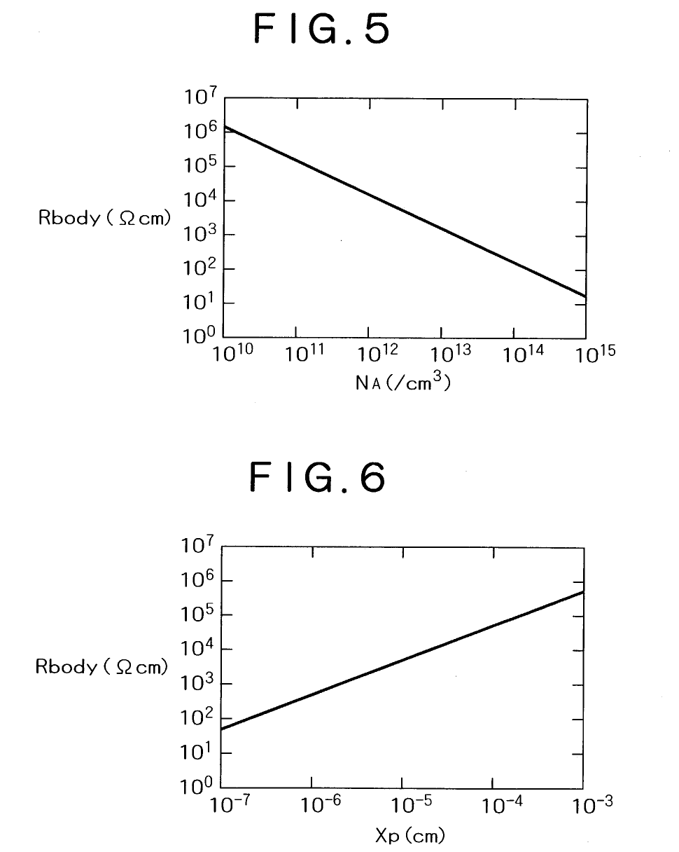

### DETAILED DESCRIPTION OF THE PREFERRED EMBODIMENTS

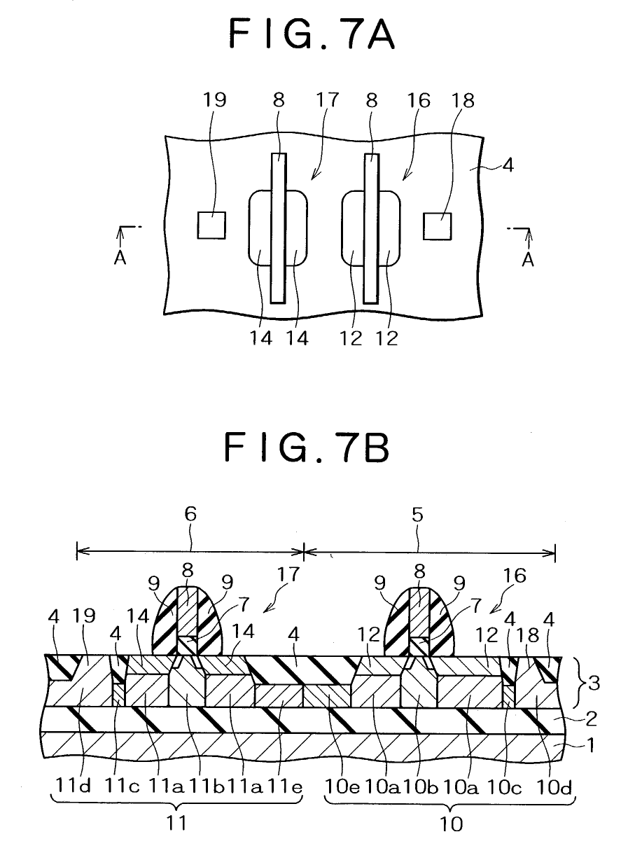

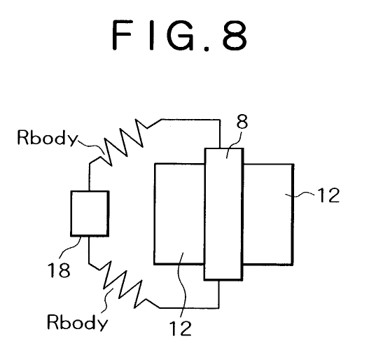

Preferred embodiments of the present invention will be explained in detail below with reference to the attached drawings. First, a first embodiment of the invention will be explained. FIG. 7A is a plan view of a semiconductor device of the embodiment and FIG. 7B is a cross sectional view taken along line A-A shown in FIG. 7A. Furthermore, FIG. 8 is a schematic plan view illustrating body resistors employed in the semiconductor device. Note that in FIGS. 7A and 8, sidewalls 9 are omitted for simplification.

As shown in FIGS. 7A and 7B, in the semiconductor device of the embodiment, a BOX layer 2 is formed on a P type silicon substrate 1 and an SOI layer 3 is formed thereon. The BOX layer 2 is formed to have a thickness of, for example, 100 to 500 nm and the SOI layer 3 is formed to a thickness of, for example, 50 to 300 nm and preferably, 150 to 250 nm. The SOI layer 3 has an STI region 4 made of, for example, SiO₂ and formed in the desired surface portion of the SOI layer 3, and regions partitioned by the STI region 4 constitute an NMOS transistor formation region 5 and a PMOS transistor formation region 6. The STI region 4 is formed such that the upper surface thereof is exposed at the level of the upper surface of the SOI layer 3 and the lower surface thereof is positioned so as not to reach the BOX layer 2, and the SOI layer 3 is disposed between the BOX layer 2 and the STI region 4. The STI region 4 is formed to have a depth of, for example, 50 to 180 nm and a width of, for example, 120 to 1000 nm. Additionally, the thickness of the SOI layer 3 between the STI region 4 and the BOX layer 2 is in the range of, for example, 50 to 100 nm. A gate insulating film 7 is formed on the SOI layer 3 in each of the NMOS transistor formation region 5 and the PMOS transistor formation region 6, and a gate electrode 8 is formed on each of the gate insulating films. Moreover, a set of gate insulating film 7 and gate electrode 8 has its side surfaces covered by sidewalls 9.

Moreover, a body contact 18 is formed so that the body contact 18 and a PMOS transistor 17 interpose an NMOS transistor 16 therebetween, and a body contact 19 is formed so that the body contact 19 and the NMOS transistor 16 interpose the PMOS transistor 17 therebetween. That is, the body contact 18, the NMOS transistor 16, the PMOS transistor 17 and the body contact 19 are arranged in this order in a line. The gate electrode 8 is formed in the shape of a rectangle when viewing the surface of the P type silicon substrate 1 from a direction vertical to the surface and the longitudinal sides of the gate electrode 8 extend in a direction perpendicular to the direction in which the body contact 18, the NMOS transistor 16, the PMOS transistor 17 and the body contact 19 are arranged.

Additionally, the NMOS transistor formation region 5 of the SOI layer 3 has a P well 10 formed therein and the PMOS transistor formation region 6 thereof has an N well 11 formed therein. A pair of n⁺ diffusion regions 12 disposed facing each other are formed in regions which are established by excluding a region directly below the gate electrode 8 from the P well 10. Those n⁺ diffusion regions 12 constitute source/drain regions and a region between the n⁺ diffusion regions 12 constitutes a channel region. The n⁺ diffusion region 12 is formed to have a depth of, for example, 70 to 80 nm. The channel region is formed to have a length of, for example, 30 to 100 nm.

The P well 10 comprises: P type diffusion regions 10a directly underlying the n⁺ diffusion regions 12; a P type diffusion region 10b positioned directly below the gate electrode 8 and constituting a body; a P type diffusion region 10c interposed between the STI region 4 and the BOX layer 2; and a P type diffusion region 10d disposed apart from the NMOS transistor formation region 5 via the STI region 4. The P type diffusion regions 10b and 10c are formed at the same level and to have a dopant concentration higher than that of the P type diffusion region 10a. Furthermore, the P type diffusion region 10d is formed to reach the surface of the SOI layer 3 and have a dopant concentration higher than that of the P type diffusion region 10a, and, for example, the ground potential is applied to the region 10d. The P type diffusion region 10d constitutes a body contact 18. Note that the P type diffusion region 10a has a dopant concentration of, for example, 1×10¹⁵ cm⁻³, the P type diffusion region 10b has a dopant concentration of, for example, 1×10¹⁷ cm⁻³, the P type diffusion region 10c has a dopant concentration of, for example, 1×10¹⁸ cm⁻³, and the P type diffusion region 10d has a dopant concentration of, for example, 1×10¹⁷ cm⁻³. The P well 10, the n⁺ diffusion regions 12, the gate insulating film 7, the gate electrode 8 and the sidewalls 9 constitute an NMOS transistor 16.

On the other hand, a pair of p⁺ diffusion regions 14 disposed facing each other are formed in regions which are established by excluding a region directly below the gate electrode 8 from the N well 11. Those p⁺ diffusion regions 14 constitute source/drain regions and a region between the p⁺ diffusion regions 14 constitutes a channel region. The p⁺ diffusion region 14 is formed to have a depth of, for example, 70 to 80 nm.

The N well 11 comprises: N type diffusion regions 11a directly underlying the p⁺ diffusion regions 14; an N type diffusion region 11b positioned directly below the gate electrode 8 and constituting a body; an N type diffusion region 11c interposed between the STI region 4 and the BOX layer 2; and an N type diffusion region 11d disposed apart from the PMOS transistor formation region 6 via the STI region 4. The N type diffusion regions 11b and 11c are formed at the same level and to have a dopant concentration higher than that of the N type diffusion region 11a. Furthermore, the N type diffusion region 11d is formed to reach the surface of the SOI layer 3 and have a dopant concentration higher than that of the N type diffusion region 11a, and, for example, a power supply potential is applied to the region 11d. The N type diffusion region 11d constitutes a body contact 19. Note that the N type diffusion region 11a has a dopant concentration of, for example, 1×10¹⁵ cm⁻³, the N type diffusion region 11b has a dopant concentration of, for example, 1×10¹⁷ cm⁻³, the N type diffusion region 11c has a dopant concentration of, for example, 1×10¹⁸ cm⁻³, and the N type diffusion region 11d has a dopant concentration of, for example, 1×10¹⁷ cm⁻³. The N well 11, the p⁺ diffusion regions 14, the gate insulating film 7, the gate electrode 8 and the sidewalls 9 constitute a PMOS transistor 17.

Furthermore, a P type diffusion region 10e and an N type diffusion region 11e are formed adjacent each other between the STI region 4 and the BOX layer 2 and further between the NMOS transistor formation region 5 and the PMOS transistor formation region 6.

A ground interconnect line (not shown) and a power supply interconnect line (not shown) are connected respectively to the body contacts 18 and 19, and the potentials of the P well 10 and the N well 11 are fixed respectively to the ground potential and the power supply potential. That is, the P type diffusion region 10b (body) formed directly below the gate electrode 8 within the SOI layer 3 is connected to the body contact 18 via the P type diffusion region 10c formed between the STI region 4 and the BOX layer 2. As a result, the P type diffusion region 10b (body) is connected to the ground interconnect line, allowing the NMOS transistor 16 to suppress the history effect due to electrons and holes injected into the body upon beginning the operation of transistor. Likewise, the N type diffusion region 11b (body) is connected to the power supply interconnect line via the N type diffusion region 11c, allowing the PMOS transistor 17 to suppress the history effect. “Rbody” illustrated in FIG. 8 schematically represents a body resistor residing in a path between the body (P type diffusion region 10b) positioned directly below the gate electrode 8 and the body contact 18. Thus, the P type diffusion region 10b and the N type diffusion region 11b as a body are connected respectively to the P type diffusion region 10c and the N type diffusion region 11c, both being positioned between the STI region 4 and the BOX layer 2, at boundaries between the corresponding transistor formation regions and the STI region 4. The boundary is determined in the plan view shown in FIG. 8 in the following manner. That is, first, a rectangle is determined by combining together the n⁺ diffusion regions 12 and a region between the n⁺ diffusion regions 12. Secondly, portions at which the gate electrode 8 and the two sides extending along the rectangle in a horizontal direction cross each other are determined as a boundary. The resistance of the body resistor Rbody is primarily determined by the electrical resistance of the diffusion region (P type diffusion region 10c, N type diffusion region 11c) formed between the STI region 4 and the BOX layer 2.

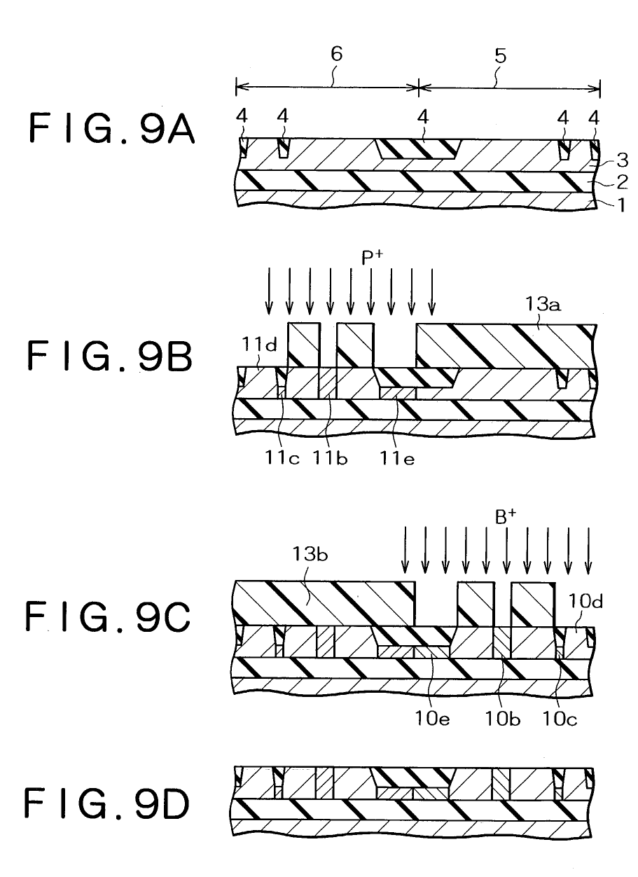

Subsequently, a method for manufacturing a semiconductor device in accordance with the embodiment will be explained. FIGS. 9A through 9D are cross sectional views illustrating a method for manufacturing a semiconductor device in accordance with the embodiment in the order of manufacturing steps. In the embodiment, the semiconductor device is manufactured by a method using a resist mask, the desired portion of which allows dopants to pass therethrough.

First, as shown in FIG. 9A, a BOX layer 2 is formed on a P type silicon substrate 1 and then an SOI layer 3 having a thickness of, for example, 250 nm is formed thereon. Thereafter, dopants are implanted within the SOI layer 3 to form a P well 10 and an N well 11. Thus, an SOI substrate having wells formed therein is prepared.

Subsequently, an STI region 4 is formed in a surface portion of the SOT layer 3 using an STI method. In this case, the STI region 4 is formed to have a depth of, for example, 180 nm and to have its lower surface positioned so as not to reach the BOX layer 2.

Then, as shown in FIG. 9B, dopants are implanted into a region between the STI region 4 and the BOX layer 2, a body contact region, and a region directly underlying a channel region within the SOI layer 3. That is, a resist 13a is formed to cover an entire NMOS transistor formation region 5 and regions used to form N type diffusion regions 11a (refer to FIG. 7B) within a PMOS transistor formation region 6 in a subsequent step. Then, high dose P (phosphorous) dopants (i.e., P⁺ ions) as an N type dopant are implanted using the resist 13a as a mask. In this case, for example, the implantation parameter may be 1×10¹³ cm⁻² dose and 170 keV energy. Thus, the implant creates N type diffusion regions 11b, 11c, 11d and 11e. The N type diffusion region 11d constitutes a body contact 19 (refer to FIGS. 7A and 7B). In this case, a region into which P⁺ ions are not implanted within the N well 11 in the step shown in FIG. 9B constitutes the N type diffusion region 11a. Thereafter, the resist 13a is removed.

Subsequently, as shown in FIG. 9C, a resist 13b is formed to cover an entire PMOS transistor formation region 6 and regions used to form P type diffusion regions 10a (refer to FIG. 7B) within an NMOS transistor formation region 5 in a subsequent step. Then, high dose B (boron) dopants (i.e., B⁺ ions) as a P type dopant are implanted using the resist 13b as a mask. In this case, for example, the implantation parameter may be 1×10¹² cm⁻² dose and 60 keV energy. Thus, the implant creates P type diffusion regions 10b, 10c, 10d and 10e. The P type diffusion region 10d constitutes a body contact 18 (refer to FIGS. 7A and 7B). In this case, a region into which B⁺ ions are not implanted within the P well 10 in the step shown in FIG. 9C constitutes the P type diffusion region 10a.

Thereafter, as shown in FIG. 9D, the resist 13b is removed. Note that the semiconductor device of the embodiment may be manufactured such that prior to implanting P⁺ ions, B⁺ ions are implanted to form the P type diffusion regions 10b, 10c, 10d and 10e and then P⁺ ions are implanted to form the N type diffusion regions 11b, 11c, 11d and 11e.

Subsequently, as shown in FIG. 7B, a set of gate insulating film 7 and gate electrode 8 is formed on the surface of each of the NMOS transistor formation region 5 and the PMOS transistor formation region 6. Then, n⁺ diffusion regions 12 and p⁺ diffusion regions 14 are formed in the corresponding transistor formation regions to constitute the source/drain regions. Thereafter, sidewalls 9 are formed to cover the side surfaces of the set of gate insulating film 7 and gate electrode 8. Thus, the semiconductor device shown in FIGS. 7A and 7B is manufactured.

In the embodiment, the semiconductor device is manufactured such that the dopant concentration of the P type diffusion region 10a and the N type diffusion region 11a directly underlying the n⁺ diffusion region 12 and the p⁺ diffusion region 14 that constitute the S/D regions of the NMOS transistor 16 and the PMOS transistor 17 respectively is made lower than the dopant concentration of the P type diffusion region 10b and the N type diffusion region 11b that constitute the bodies of the corresponding transistor formation regions. This allows a depletion layer formed below the S/D region to reach the BOX layer 2. As a result, the NMOS transistor 16 and the PMOS transistor 17 are able to reduce their parasitic capacitances and then operate at a higher speed, and further, reduce their channel lengths while suppressing the short channel effect. In addition, the S/D regions of the adjacent transistors can securely be isolated from each other.

It should be appreciated that in FIG. 7B illustrating the cross section of the semiconductor device of the embodiment, the SOI layer 3 is grouped into regions depending on the species of dopant ions implanted (N type, P type) and dopant concentrations. The term “body” means a neutral region that is positioned directly below the gate electrode 8 within the SOI layer 3 in the transistor formation region and further does not allow a depletion layer to be formed therein. Note that the individual regions containing dopant ions implanted therein and positioned within the SOI layer 3 each have a depletion layer formed therein so as to vary depending on the potentials of the source/drain and the gate electrode of transistor in addition to the potential of body. Although FIG. 7B does not clearly illustrate the area over which a depletion layer is formed, typically, the P type diffusion region 10a and the N type diffusion region 11a each are occupied by a depletion region. Furthermore, when a transistor is in operation, a depletion layer is also formed directly below the channel region formed between the S/D regions and therefore, the portion positioned in the vicinity of a region directly below the channel region and chosen out of each of the P type diffusion region 10b and the N type diffusion region 11b is also occupied by a depletion region.

Moreover, the P type diffusion region 10b and the N type diffusion region 11b, both serving as a body, are formed at the same level as the P type diffusion region 10c and the N type diffusion region 11c, respectively, and further, formed to have a dopant concentration higher than the dopant concentration of the P type diffusion region 10a and the N type diffusion region 11a. This allows the NMOS transistor 16 to reduce the resistance between the P type diffusion region 10b constituting the body of the NMOS transistor 16 and the P type diffusion region 10d constituting the body contact, and further, allows the POMS transistor 17 to reduce the resistance between the N type diffusion region 11b constituting the body of the PMOS transistor 17 and the N type diffusion region 11d constituting the body contact. Thus, the NMOS transistor 16 and the PMOS transistor 17 are able to have their bodies securely fixed to the corresponding potentials.

Additionally, the semiconductor device of the embodiment is constructed such that the P type diffusion region 10e and the N type diffusion region 11e are disposed between the STI region 4, which is positioned between the NMOS transistor formation region 5 and the PMOS transistor formation region 6, and the BOX layer 2 so as to contact each other. Accordingly, when the ground potential is applied to the P type diffusion region 10d as a body contact and the power supply potential is applied to the N type diffusion region 11d, the P type diffusion region 10e and the N type diffusion region 11e are PN junction isolated from each other. As a result, the NMOS transistor 16 and the PMOS transistor 17 can be isolated from each other.

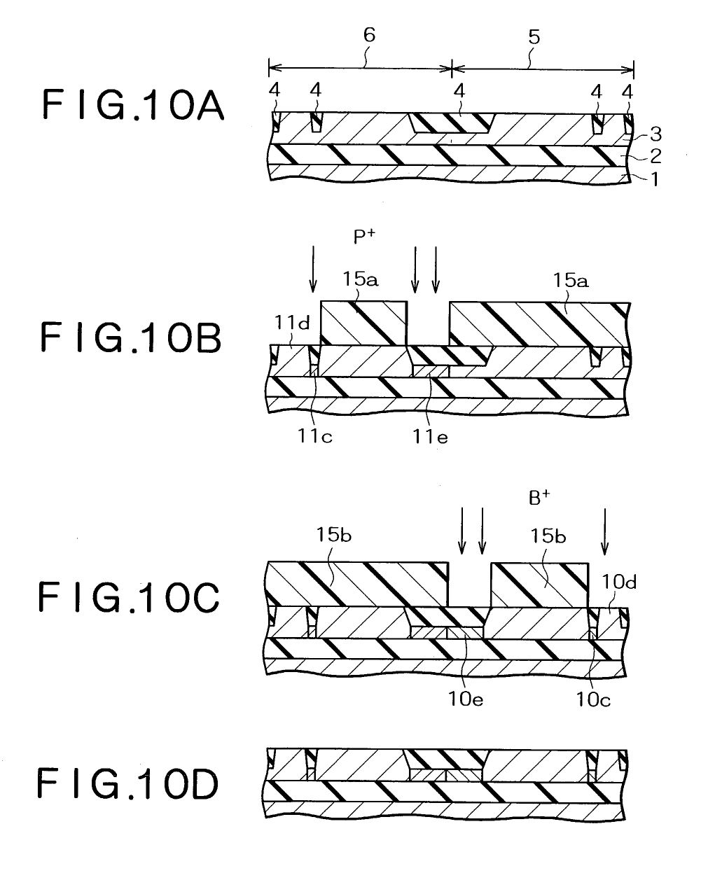

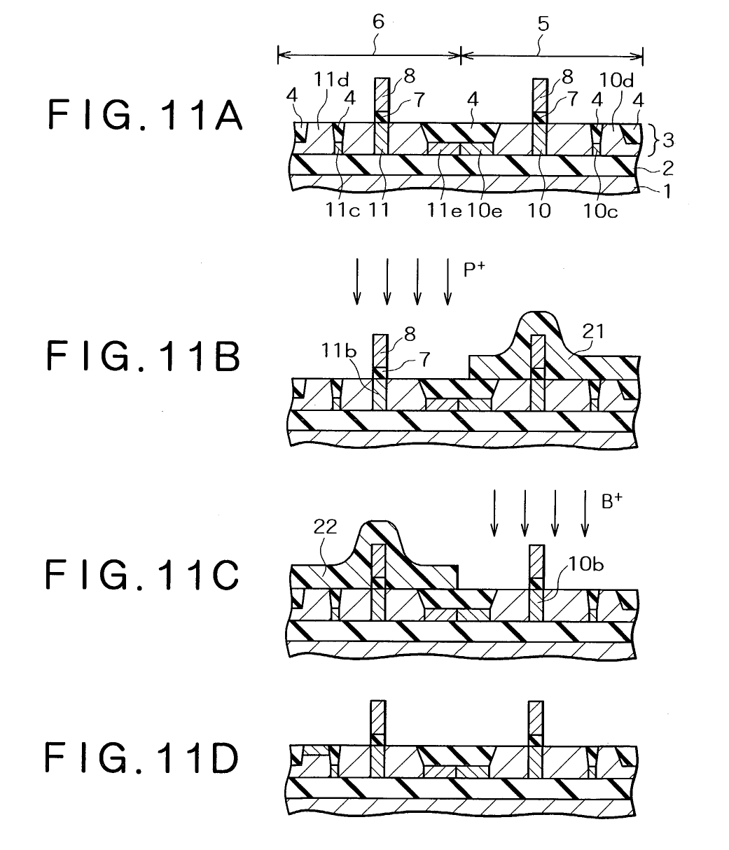

Subsequently, a modification of the aforementioned embodiment will be explained. FIGS. 10A through 10D and FIGS. 11A through 11D are cross sectional views illustrating a method for manufacturing a semiconductor device in accordance with the modification in the order of manufacturing steps. In the modification, the semiconductor device is manufactured using a method for implanting dopant ions through a gate electrode into an associated region. The configuration of the semiconductor device manufactured in accordance with the modification is the same as that of the semiconductor device shown in FIGS. 7A and 7B. First, as shown in FIG. 10A and similarly to the method employed in the aforementioned first embodiment, a BOX layer 2 and an SOI layer 3 are formed on a P type silicon substrate 1 and a P well 10 and an N well 11 are formed within the SOI layer 3, thereby preparing an SOI substrate having wells formed therein. Then, an STI region 4 is formed in the SOI layer 3.

Subsequently, as shown in FIG. 10B, dopants are implanted into a region between the STI region 4 and the BOX layer 2, and a body contact region. First, a resist 15a is formed to cover an entire NMOS transistor formation region 5 and a region used to form a PMOS transistor 17 (refer to FIG. 7B) within a PMOS transistor formation region 6 in a subsequent step. Then, P⁺ ions as an N type dopant are implanted using the resist 15a as a mask. In this case, for example, the implantation parameter may be 1×10¹³ cm⁻² dose and 170 keV energy. Thus, the implant creates N type diffusion regions 11c, 11d and 11e. The N type diffusion region 11d constitutes a body contact 19 (refer to FIGS. 7A and 7B). In this case, P⁺ ions are not implanted into N type diffusion regions 11a and 11b, both of which will be formed in a subsequent step. Thereafter, the resist 15a is removed.

As shown in FIG. 10C, a resist 15b is formed to cover an entire PMOS transistor formation region 6 and a region used to form an NMOS transistor 16 (refer to FIG. 7B) within an NMOS transistor formation region 5 in a subsequent step. Then, B⁺ ions as a P type dopant are implanted using the resist 15b as a mask. In this case, for example, the implantation parameter may be 1×10¹² cm⁻² dose and 60 keV energy. Thus, the implant creates P type diffusion regions 10c, 10d and 10e. The P type diffusion region 10d constitutes a body contact 18 (refer to FIGS. 7A and 7B). Note that B⁺ ions are not implanted into P type diffusion regions 10a and 10b, both of which will be formed in a subsequent step.

Thereafter, as shown in FIG. 10D, the resist 15b is removed. Note that the semiconductor device may be manufactured such that prior to implanting P⁺ ions, B⁺ ions are implanted to form the P type diffusion regions 10c, 10d and 10e and then P⁺ ions are implanted to form the N type diffusion regions 11c, 11d and 11e.

Subsequently, as shown in FIG. 11A, a set of gate insulating film 7 and gate electrode 8 is formed on the surface of each of the transistor formation regions. In this case, the gate insulating film 7 is formed by thermal oxidation and to have a thickness of, for example, 1.5 nm. Furthermore, the gate electrode 8 is formed from polycrystalline silicon and to have a thickness of, for example, 150 nm.

Thereafter, as shown in FIG. 11B, a resist 21 is formed to cover a region excluding the PMOS transistor formation region 6. Then, P⁺ ions are implanted using the resist 21 as a mask. In this case, for example, the implantation parameter may be 1×10¹² cm⁻² dose and 170 keV energy. This allows P⁺ ions implanted into the gate electrode 8 to penetrate the gate electrode 8 and the gate insulating film 7, and be stopped within the N well 11 directly below the gate electrode 8, thereby forming the N type diffusion region 11b. Note that in this case, although P⁺ions directly implanted into the SOI layer 3 pass through the SOI layer 3 and reach within the BOX layer 2, P⁺ ions implanted within the BOX layer 2 never affect the performance of the PMOS transistor 17. Thus, regions in which the N type diffusion regions 11b, 11c, 11d are not formed within the N well 11 constitute the N type diffusion regions 11a.

Thereafter, as shown in FIG. 11C, the resist 21 is removed and a resist 22 is formed to cover a region excluding the NMOS transistor formation region 5. Then, B⁺ions are implanted using the resist 22 as a mask. In this case, B⁺ions are implanted, for example, at a dose of 1×10¹² cm⁻² and an energy of 70 keV. This allows B⁺ ions implanted into the gate electrode 8 to penetrate the gate electrode 8 and the gate insulating film 7, and be stopped within the P well 10 directly below the gate electrode 8, thereby forming the P type diffusion region 10b. Note that in this case, although B⁺ ions directly implanted into the SOI layer 3 pass through the SOI layer 3 and reach within the BOX layer 2, B⁺ ions implanted within the BOX layer 2 never affect the performance of the NMOS transistor 16. Thus, regions in which the P type diffusion regions 10b, 10c, 10d are not formed within the P well 10 constitute the P type diffusion regions 10a. Then, as shown in FIG. 11D, the resist 22 is removed.

Thereafter, as shown in FIG. 7B, n⁺ diffusion regions 12 and p⁺ diffusion regions 14 are formed to constitute the source/drain regions. Then, sidewalls 9 are formed to cover the side surfaces of a set of gate insulating film 7 and gate electrode 8. Thus, the semiconductor device incorporating therein the NMOS transistor 16 and the PMOS transistor 17 is manufactured.

In the modification, since the dopant ions are implanted using the set of gate electrode 8 and gate insulating film 7 as a mask to form the P type diffusion region 10b and the N type diffusion region 11b, both serving as a body, the gate electrode and the body can be positioned in a self-aligned manner.

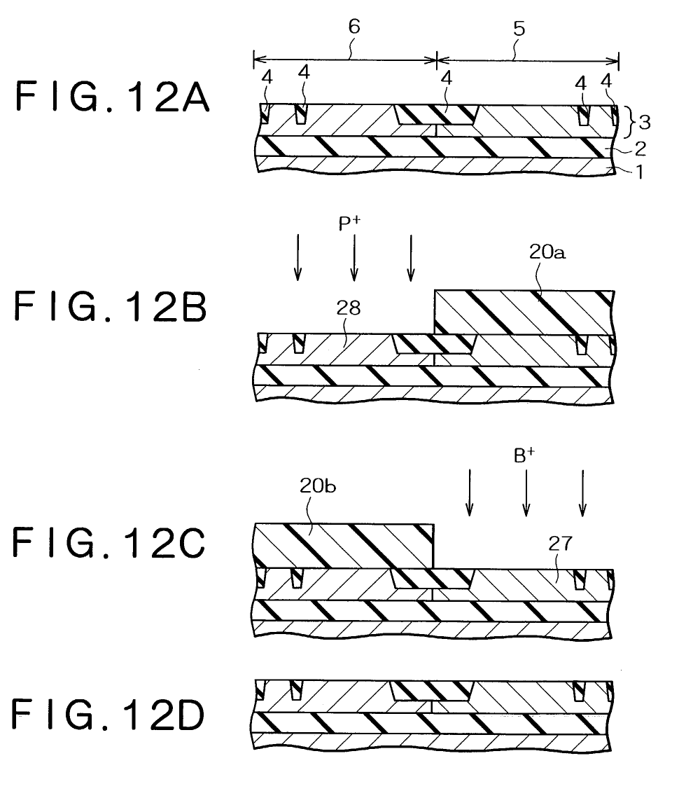

Subsequently, an alternative modification of the aforementioned first embodiment will be explained. FIGS. 12A through 12D, FIGS. 13A and 13B, and FIGS. 14A and 14B are cross sectional views illustrating a method for manufacturing a semiconductor device in accordance with the modification in the order of manufacturing steps. The configuration of the semiconductor device manufactured in accordance with the modification is the same as that of the semiconductor device shown in FIGS. 7A and 7B. In the modification, the semiconductor device is manufactured using a method for implanting dopant ions through a gate electrode into a specific region so that the dopants ions are counter-implanted into the specific region to substantially cancel the doping level of the specific region.

First, as shown in FIG. 12A and similarly to the method employed in the aforementioned first embodiment, a BOX layer 2, an SOI layer 3 and an STI region 4 are formed on a P type silicon substrate 1. Then, as shown in FIG. 12B, a resist 20a is formed to cover an entire NMOS transistor formation region 5. Thereafter, P⁺ ions as an N type dopant are implanted into the entire surface of a PMOS transistor formation region 6 using the resist 20a as a mask. In this case, for example, the implantation parameter may be 1×10¹² cm⁻² dose and 130 keV energy. Thus, the implant creates an N well 28 in the PMOS transistor formation region 6. Thereafter, the resist 20a is removed.

Subsequently, as shown in FIG. 12C, a resist 20b is formed to cover the entire PMOS transistor formation region 6. Then, B⁺ ions as a P type dopant are implanted into the entire surface of an NMOS transistor formation region 5 using the resist 20b as a mask. In this case, for example, the implantation parameter may be 1×10¹² cm⁻² dose and 60 keV energy. Thus, the implant creates a P well 27 in the NMOS transistor formation region 5. Thereafter, as shown in FIG. 12D, the resist 20b is removed. Note that the semiconductor device may be manufactured such that prior to implanting P⁺ ions, B⁺ ions are implanted to form the P well 27 in the NMOS transistor formation region 5 and then P⁺ ions are implanted to form the N well 28 in the PMOS transistor formation region 6.

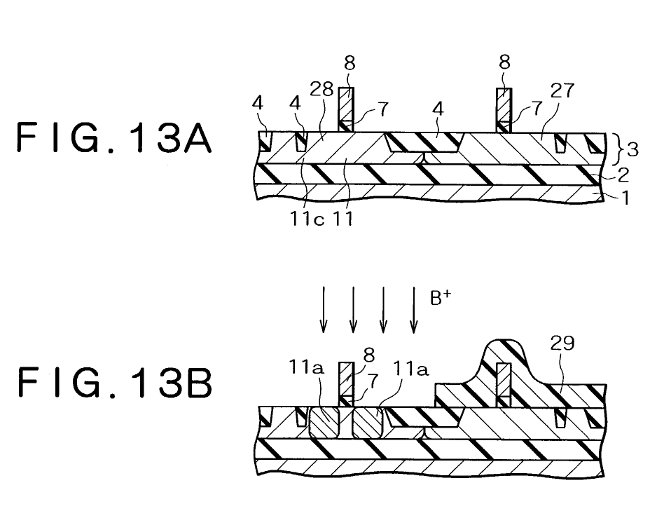

Subsequently, as shown in FIG. 13A, a set of gate insulating film 7 and gate electrode 8 is formed on the surface of each of the transistor formation regions. Thereafter, as shown in FIG. 13B, a resist 29 is formed to cover a region excluding the PMOS transistor formation region 6. Then, B⁺ ions are implanted using the resist 29, the gate electrode 8 and the gate insulating film 7 as a mask. In this case, B⁺ ions are implanted, for example, at a dose of 1×10¹² cm⁻² and an energy of 30 keV. This allows B⁺ ions implanted into regions, which are established by excluding a region covered by the gate electrode 8 from the N well 28, to be counter-implanted into the N well 28, so that the doping level of the N well 28 doped with the N type dopants (P: phosphorous) is substantially cancelled. That is, B⁺ ions cancel the effect produced by the N type dopants previously implanted into the N well 28. Thus, N type diffusion regions 11a having a net dopant concentration lower than that of a region surrounding the N type diffusion regions 11a are formed in regions, which are established by excluding a region covered by the gate electrode 8 from the N well 28, i.e., regions directly underlying the S/D regions. Accordingly, regions of the N well 28, into which regions B⁺ ions are not counter-implanted, constitute the N type diffusion regions 11b, 11c, 11d and 11e, all of which are formed to have a net dopant concentration higher than that of the N type diffusion region 11a.

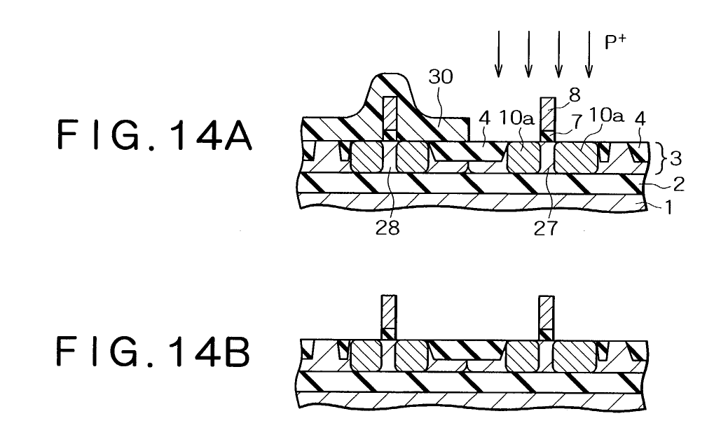

Thereafter, as shown in FIG. 14A, the resist 29 is removed and a resist 30 is formed to cover a region excluding the NMOS transistor formation region 5. Then, P⁺ ions are implanted using the resist 30, the gate electrode 8 and the gate insulating film 7 as a mask. In this case, P⁺ ions are implanted, for example, at a dose of 1×10¹³ cm⁻² and an energy of 80 keV. This allows P⁺ ions implanted into regions, which are established by excluding a region covered by the gate electrode 8 from the P well 27, to be counter-implanted into the P well 27, so that the doping level of the P well 27 doped with the P type dopants (B: boron) is substantially cancelled. Thus, P type diffusion regions 10a having a net dopant concentration lower than that of a region surrounding the P type diffusion regions 10a are formed in regions of the P well 27, which regions are not covered by the gate electrode 8, i.e., regions directly underlying the S/D regions. Accordingly, regions of the P well 27, into which regions P⁺ ions are not counter-implanted, constitute the P type diffusion regions 10b, 10c, 10d and 10e, all of which are formed to have a net dopant concentration higher than that of the P type diffusion region 10a. Thereafter, as shown in FIG. 14B, the resist 30 is removed.

Thereafter, as shown in FIG. 7B and similarly to the method employed in the aforementioned first embodiment, n⁺ diffusion regions 12 and p⁺ diffusion regions 14 are formed to constitute source/drain regions. Then, sidewalls 9 are formed to cover the side surfaces of a set of gate insulating film 7 and gate electrode 8. Thus, the semiconductor device incorporating therein the NMOS transistor 16 and the PMOS transistor 17 is manufactured.

In the modification, since the dopant ions are implanted using a set of gate electrode 8 and gate insulating film 7 as a mask to form the P type diffusion region 10a and the N type diffusion region 11a in regions directly underlying the S/D regions, the gate electrode 8, the P type diffusion regions 10a and the N type diffusion regions 11a can be positioned in a self-aligned manner.

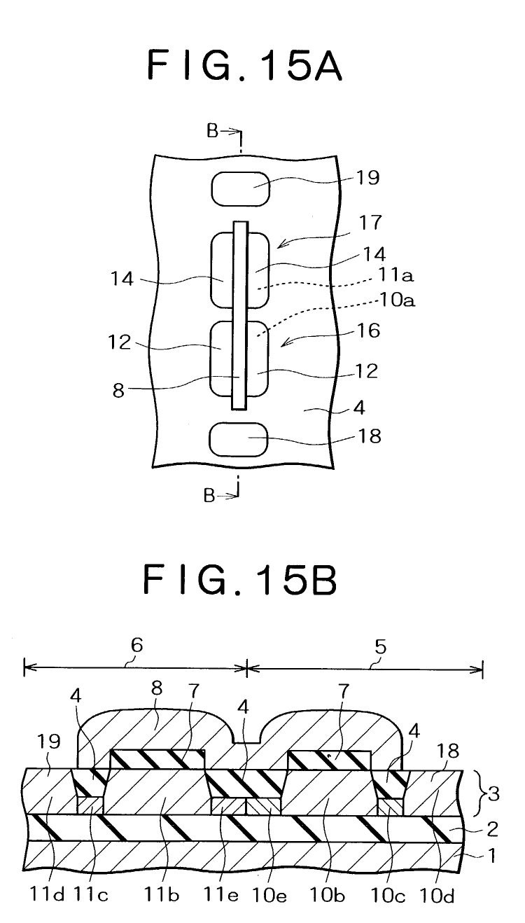

A second embodiment of the invention will be explained. FIG. 15A is a plan view of a semiconductor device according to the embodiment and FIG. 15B is a cross sectional view taken along line B-B shown in FIG. 15A. Note that in FIG. 15A, sidewalls are omitted for simplification.

As shown in FIGS. 15A and 15B, in the semiconductor device of the embodiment, a BOX layer 2 is formed on a P type silicon substrate 1 and an SOI layer 3 is formed thereon. The SOI layer 3 has an STI region 4 formed in the desired surface portion of the SOI layer 3, and regions partitioned by the STI region 4 constitute an NMOS transistor formation region 5 and a PMOS transistor formation region 6. The STI region 4 is formed such that the upper surface thereof is exposed at the level of the upper surface of the SOI layer 3-and the lower surface thereof is positioned so as not to reach the BOX layer 2, and the Sol layer 3 is disposed between the BOX layer 2 and the STI region 4. The BOX layer 2, the SOI layer 3 and the STI region 4 are formed to have, for example, the same thicknesses as those of the corresponding components employed in the aforementioned first embodiment.

The NMOS transistor formation region 5 and the PMOS transistor formation region 6 each have a gate insulating film 7 formed on the SOI layer 3 and share one gate electrode 8 that is formed on the gate insulating films of both transistor formation regions. Moreover, a body contact 18 is formed so that the body contact 18 and a PMOS transistor 17 interpose an NMOS transistor 16 therebetween, and a body contact 19 is formed so that the body contact 19 and the NMOS transistor 16 interpose the PMOS transistor 17 therebetween. That is, the body contact 18, the NMOS transistor 16, the PMOS transistor 17 and the body contact 19 are arranged in this order in a line and the gate electrode 8 lies on the NMOS transistor formation region 5 and the PMOS transistor formation region 6 so that one gate electrode 8 is shared by both transistor formation regions. The gate electrode 8 is formed in the shape of a rectangle when viewing the surface of the P type silicon substrate 1 from a direction vertical to the surface and the longitudinal sides of the gate electrode 8 extend in a direction parallel to the direction in which the body contact 18, the NMOS transistor 16, the PMOS transistor 17 and the body contact 19 are arranged.

Furthermore, a set of gate insulating film 7 and gate electrode 8 has sidewalls (not shown) formed so as to cover the side surfaces thereof. Moreover, a P well 10 is formed in the NMOS transistor formation region 5 within the SOI layer 3 and an N well 11 is formed in the PMOS transistor formation region 6 within the SOI layer 3.

A pair of n⁺ diffusion regions 12 disposed facing each other are formed in regions which are established by excluding a region covered by the gate electrode 8 from the P well 10. Those n⁺ diffusion regions 12 constitute source/drain regions and a region between the n⁺ diffusion regions 12 constitutes a channel region.

The P well 10 comprises: P type diffusion regions 10a directly underlying the n⁺ diffusion regions 12; a P type diffusion region 10b directly below the gate electrode 8; a P type diffusion region 10c interposed between the STI region 4 and the BOX layer 2; and a P type diffusion region 10d disposed apart from the NMOS transistor formation region 5 via the STI region 4. The P type diffusion regions 10b and 10c are formed at the same level and to have a dopant concentration higher than that of the P type diffusion region 10a. Furthermore, the P type diffusion region 10d is formed to reach the surface of the SOI layer 3, constituting a body contact 18. The P type diffusion region 10d is formed to have a dopant concentration higher than that of the P type diffusion region 10a, and, for example, the ground potential is applied to the region 10d. The P well 10, the n⁺ diffusion regions 12, the gate insulating film 7, the gate electrode 8 and the sidewalls 9 constitute an NMOS transistor 16.

On the other hand, a pair of p⁺ diffusion regions 14 disposed facing each other are formed in regions which are established by excluding a region covered by the gate electrode 8 from the N well 11. Those p⁺ diffusion regions 14 constitute source/drain regions and a region between the p⁺ diffusion regions 14 constitutes a channel region.

The N well 11 comprises: N type diffusion regions 11a directly underlying the p⁺ diffusion regions 14; an N type diffusion region 11b directly below the gate electrode 8; an N type diffusion region 11c interposed between the STI region 4 and the BOX layer 2; and an N type diffusion region lid disposed apart from the PMOS transistor formation region 6 via the STI region 4. The N type diffusion regions 11b and 11c are formed at the same level and to have a dopant concentration higher than that of the N type diffusion region 11a. Furthermore, the N type diffusion region 11d is formed to reach the surface of the SOI layer 3, constituting a body contact 19. The N type diffusion region 11d is formed to have a dopant concentration higher than that of the N type diffusion region 11a, and, for example, the power supply potential is applied to the region 11d. The N well 11, the p⁺ diffusion regions 14, the gate insulating film 7, the gate electrode 8 and the sidewalls 9 constitute a PMOS transistor 17.

Furthermore, a P type diffusion region 10e and an N type diffusion region 11e are formed adjacent each other between the STI region 4 and the BOX layer 2 and further between the NMOS transistor formation region 5 and the PMOS transistor formation region 6.

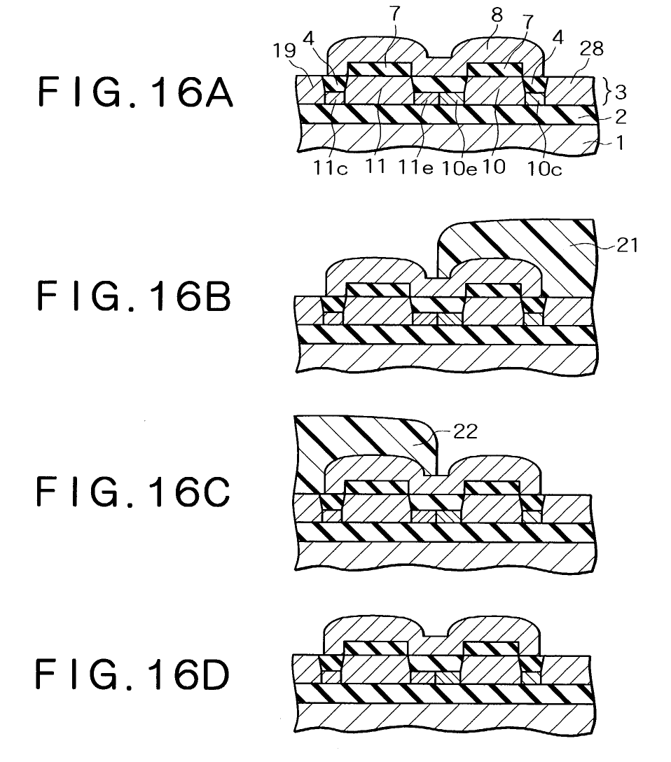

Subsequently, a method for manufacturing a semiconductor device in accordance with the embodiment will be explained. FIGS. 16A through 16D are cross sectional views illustrating a method for manufacturing a semiconductor device in accordance with the embodiment in the order of manufacturing steps. In the embodiment, the semiconductor device is manufactured using a method for implanting dopant ions through a gate electrode into an associated region. First, as shown in FIG. 16A, a BOX layer 2 is formed on a P type silicon substrate 1 and then an SOI layer 3 is formed thereon. Thereafter, an STI region 4 is formed in a surface portion of the SOI layer 3 using an STI method. In this case, the STI region 4 is formed such that the lower surface thereof never reaches the BOX layer 2. Then, a P well 10 is formed in the NMOS transistor formation region 5 within the SOI layer 3 and an N well 11 is formed in the PMOS transistor formation region 6 within the SOI layer 3. A method for forming the P well 10 and the N well 11 is similar to that employed in the aforementioned first embodiment.

Subsequently, dopants are implanted into a region between the STI region 4 and the BOX layer 2, and the region used to form a body contact in a subsequent step. In this case, for example, B⁺ ions as a P type dopant are implanted into the NMOS transistor formation region 5 at a dose of 1×10¹³ cm⁻² and an energy of 50 keV, and further, for example, P⁺ ions as an N type dopant are implanted into the PMOS transistor formation region 6 at a dose of 1×10¹³ cm⁻² and an energy of 150 keV. Thus, those implants create P type diffusion regions 10c, 10d and 10e, and further, N type diffusion regions 11c, 1d and 11e. Subsequently, a gate insulating film 7 is formed on the surface of each of the NMOS transistor formation region 5 and the PMOS transistor formation region 6. Then, a gate electrode 8 is formed on the NMOS transistor formation region 5 and the PMOS transistor formation region 6 so that those transistor formation regions share one gate electrode 8.

Thereafter, as shown in FIG. 16B, a resist 21 is formed to cover a region excluding the PMOS transistor formation region 6. Then, P⁺ ions are implanted using the resist 21 as a mask. In this case, P⁺ ions are implanted, for example, at a dose of 1×10¹² cm⁻² and an energy of 170 keV. This allows P⁺ ions implanted into the gate electrode 8 to penetrate the gate electrode 8 and the gate insulating film 7, and be stopped within the N well 11 directly below the gate electrode 8, thereby forming the N type diffusion region 11b (refer to FIG. 15A). Note that in this case, although P⁺ ions directly implanted into the SOI layer 3 pass through the SOI layer 3 and reach within the BOX layer 2, P⁺ ions implanted within the BOX layer 2 never affects the performance of the PMOS transistor 17. Thus, regions which are established by excluding the N type diffusion regions 11b, 11c, 11d, 11e from the N well 11 constitute the N type diffusion region 11a.

Thereafter, as shown in FIG. 16C, the resist 21 is removed and a resist 22 is formed to cover a region excluding the NMOS transistor formation region 5. Then, B⁺ ions are implanted using the resist 22 as a mask. In this case, B⁺ ions are implanted, for example, at a dose of 1×10¹² cm⁻² and an energy of 70 keV. This allows B⁺ ions implanted into the gate electrode 8 to penetrate the gate electrode 8 and the gate insulating film 7, and be stopped within the P well 10 directly below the gate electrode 8, thereby forming the P type diffusion region 10b (refer to FIG. 15A). Note that in this case, although B⁺ ions directly implanted into the SOI layer 3 pass through the SOI layer 3 and reach within the BOX layer 2, B⁺ ions implanted within the BOX layer 2 never affects the performance of the NMOS transistor 16. Thus, regions which are established by excluding the P type diffusion regions 10b, 10c, 10d, 10e from the P well 10 constitute the P type diffusion region 10a. Then, as shown in FIG. 16D, the resist 22 is removed.

Thereafter, as shown in FIG. 15A, n⁺ diffusion regions 12 and p⁺ diffusion regions 14 are formed to constitute source/drain regions. Then, sidewalls (not shown) are formed to cover the side surfaces of a set of the gate insulating film 7 and the gate electrode 8. Thus, the semiconductor device incorporating therein the NMOS transistor 16 and the PMOS transistor 17 is manufactured.

In addition to the beneficial effects produced by employment of the aforementioned first embodiment, employment of the embodiment makes it possible to reduce a distance between the P type diffusion region 10b as the body of the NMOS transistor 16 and the body contact 18 (P type diffusion region 10d). The resistance of a body resistor Rbody (refer to FIG. 8) between the body and the body contact depends on the length of a connection path along which the body is connected to the body contact. As shown in FIGS. 7A and 7B, in the semiconductor device of the aforementioned first embodiment, the direction in which the body contact 18, the NMOS transistor 16, the PMOS transistor 17 and the body contact 19 are arranged and the longitudinal direction of the gate electrode 8 are perpendicular to each other. Furthermore, depletion layers extend downward from the n⁺ diffusion regions 12 chosen out of the regions within the SOI layer and reach the BOX layer. Therefore, the region under the n⁺ diffusion regions 12 within the SOI layer 3 comes to exhibit a high electrical resistance value. So, the connection path along which the body (i.e., the diffusion region directly below the gate electrode 8) and the body contact are connected to each other needs to avoid the n⁺ diffusion regions 12 and the depletion layers formed thereunder, and the body resistor Rbody comes to exhibit a high electrical resistance value. In contrast, as shown in FIG. 15A, the semiconductor device of the embodiment is constructed such that the body contact 18 is formed so as to face the outermost side out of two sides at which the gate electrode 8 and a rectangular transistor component formation region consisting of the n⁺ diffusion regions 12 and the region sandwiched therebetween cross each other, and likewise, the body contact 19 is formed so as to face the outermost side out of two sides at which the gate electrode 8 and a rectangular transistor component formation region consisting of the p⁺ diffusion regions 14 and the region sandwiched therebetween cross each other. That is, the direction in which the body contact 18, the NMOS transistor 16, the PMOS transistor 17 and the body contact 19 are arranged and the longitudinal direction of the gate electrode 8 are parallel to each other. Accordingly, the body is connected to the corresponding body contact without avoiding the source/drain regions of the corresponding transistor, thereby making the aforementioned connection path shorter than that formed in the aforementioned first embodiment and reducing the resistance of the body resistor. As a result, employment of the semiconductor device of the embodiment makes it possible to more effectively suppress variations in the potential of body.

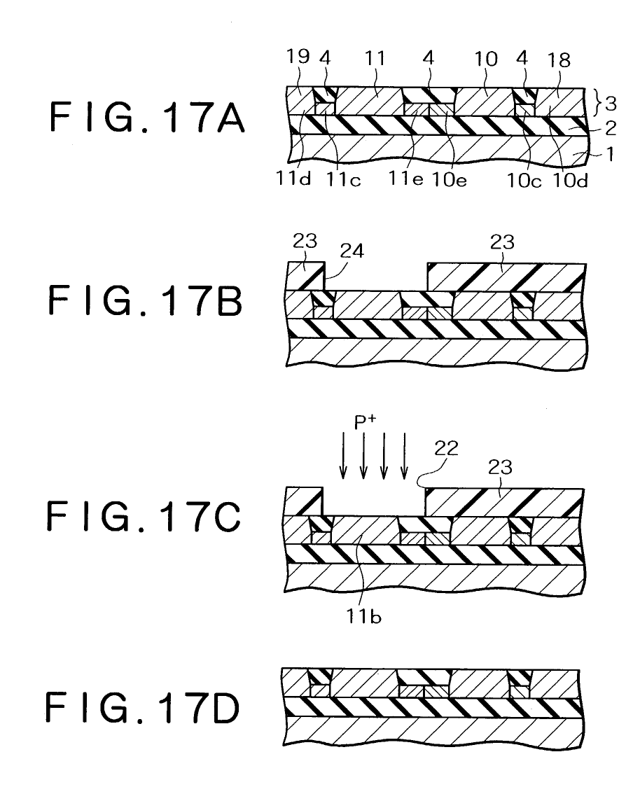

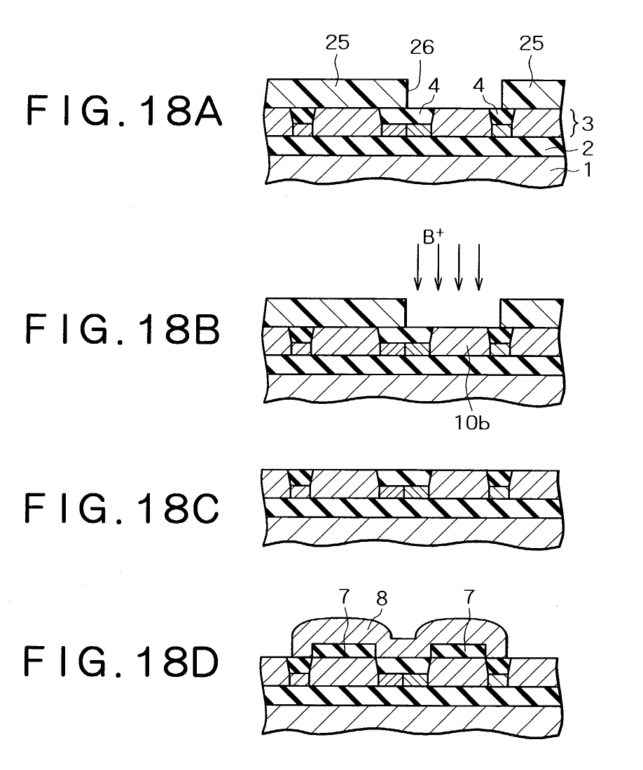

Subsequently, a modification of the aforementioned second embodiment will be explained. FIGS. 17A through 17D and FIGS. 18A through 18D are cross sectional views illustrating a method for manufacturing a semiconductor device in accordance with the modification in the order of manufacturing steps. The configuration of the semiconductor device manufactured in accordance with the modification is the same as that of the semiconductor device shown in FIGS. 15A and 15B. In the modification, the semiconductor device is manufactured by a method using a resist mask, the desired portion of which allows dopants to pass therethrough.

First, as shown in FIG. 17A and similarly to the method employed in the aforementioned second embodiment, a BOX layer 2, an SOI layer 3 and an STI region 4 are formed on a P type silicon substrate 1. Then, a P well 10 is formed in an NMOS transistor formation region 5 within the SOI layer 3 and an N well 11 is formed in a PMOS transistor formation region 6 within the SOI layer 3. Subsequently, dopants are implanted into regions between the STI region 4 and the BOX layer 2 within the SOI layer 3 to form P type diffusion regions 10c, 10d and 10e, and N type diffusion regions 11c, 11d and 11e.

Thereafter, as shown in FIG. 17B, a resist 23 is formed such that the resist 23 has an opening 24 positioned so as to correspond to a region used to form a gate electrode within the PMOS transistor formation region 6 in a subsequent step. Then, as shown in FIG. 17C, p⁺ ions are implanted using the resist 23 as a mask to form an N type diffusion region 11b in the N well 11. In this case, for example, the implantation parameter may be 1×10¹³ cm⁻² dose and 150 keV energy. Note that regions which are established by excluding the N type diffusion regions 11b, 11c, 11d, 11e from the N well 11 constitute N type diffusion regions 11a. Thereafter, as shown in FIG. 17D, the resist 23 is removed.

Subsequently, as shown in FIG. 18A, a resist 25 is formed such that the resist 25 has an opening 26 positioned so as to correspond to a region used to form a gate electrode within the NMOS transistor formation region 5 in a subsequent step. Then, as shown in FIG. 18B, B⁺ ions are implanted using the resist 25 as a mask to form a P type diffusion region 10b in the P well 10. In this case, for example, the implantation parameter may be 1×10¹³ cm⁻² dose and 50 keV energy. Note that regions which are established by excluding the P type diffusion regions 10b, 10c, 10d, 10e from the P well 10 constitute P type diffusion regions 10a. Thereafter, as shown in FIG. 18C, the resist 25 is removed.

Subsequently, as shown in FIG. 18D, gate insulating films 7 and a gate electrode 8 are formed. Then, n⁺ diffusion regions 12 and p⁺ diffusion regions 14 are formed to constitute source/drain regions and sidewalls are formed to cover the side surfaces of a set of gate insulating film 7 and gate electrode 8. Thus, the semiconductor device shown in FIGS. 15A and 15B is manufactured.

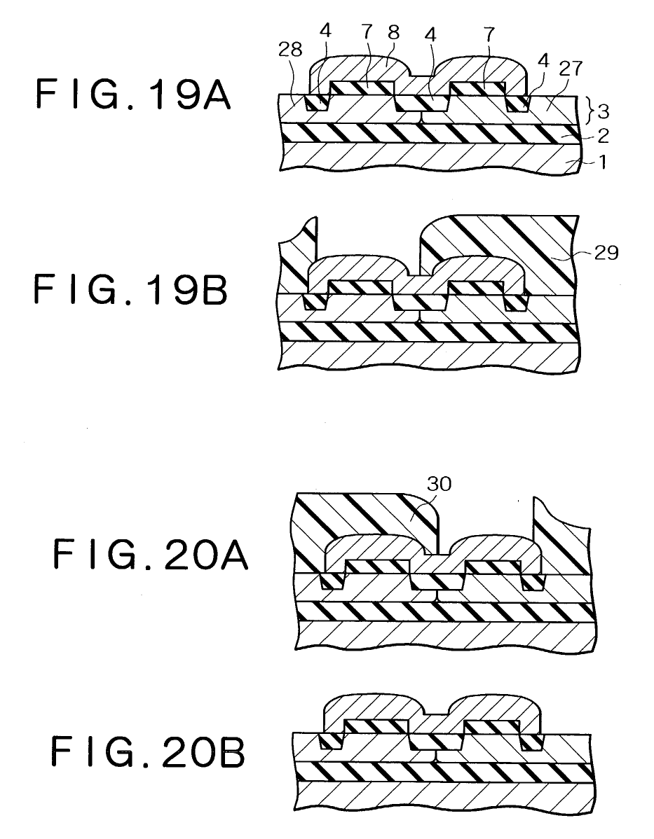

Subsequently, an alternative modification of the aforementioned second embodiment will be explained. FIGS. 19A, 19B and FIGS. 20A, 20B are cross sectional views illustrating a method for manufacturing a semiconductor device in accordance with the modification in the order of manufacturing steps. The configuration of the semiconductor device manufactured in accordance with the modification is the same as that of the semiconductor device shown in FIGS. 15A and 15B. In the modification, the semiconductor device is manufactured using a method for implanting dopant ions through a gate electrode into a specific region so that the dopants ions are counter-implanted into the specific region to substantially cancel the doping level of the specific region.

First, as shown in FIG. 19A and similarly to the method employed in the aforementioned second embodiment, a BOX layer 2, an SOI layer 3 and an STI region 4 are formed on a P type silicon substrate 1. Then, a P well 27 is formed in an NMOS transistor formation region 5 within the SOI layer 3 and an N well 28 is formed in a PMOS transistor formation region 6 within the SOI layer 3. After that, gate insulating films 7 and a gate electrode 8 are formed.

Subsequently, as shown in FIG. 19B, a resist 29 is formed to cover a region excluding the PMOS transistor formation region 6. Then, B⁺ ions are implanted using the resist 29, the gate electrode 8 and the gate insulating film 7 as a mask. In this case, B⁺ ions are implanted, for example, at a dose of 1×10¹³ cm⁻² and an energy of 30 keV. This allows B⁺ ions implanted into regions, which are established by excluding a region covered by the gate electrode 8 from the N well 28, to be counter-implanted into the N well 28, so that the doping level of the N well 28 doped with the N type dopants (e. g., P: phosphorous) is substantially cancelled. Thus, N type diffusion regions 11a (refer to FIG. 15A) having a net dopant concentration lower than that of a region surrounding the N type diffusion regions 11a are formed in regions, which are established-by excluding a region covered by the gate electrode 8 from the N well 28, i.e., regions directly underlying the S/D regions. Accordingly, regions of the N well 28, into which regions B⁺ ions are not counter-implanted, constitute the N type diffusion regions 11b, 11c, 11d and 11e, all of which are formed to have a net dopant concentration higher than that of the N type diffusion region 11a.

Thereafter, as shown in FIG. 20A, the resist 29 is removed and a resist 30 is formed to cover a region excluding the NMOS transistor formation region 5. Then, P⁺ ions are implanted using the resist 30, the gate electrode 8 and the gate insulating film 7 as a mask. In this case, P⁺ ions are implanted, for example, at a dose of 1×10¹³ cm⁻² and an energy of 80 keV. This allows P⁺ ions implanted into regions, which are established by excluding a region covered by the gate electrode 8 from the P well 27, to be counter-implanted into the P well 27, so that the doping level of the P well 27 doped with the P type dopants (B: boron) is substantially cancelled. Thus, P type diffusion regions 10a (refer to FIG. 15A) having a net dopant concentration lower than that of a region surrounding the P type diffusion regions 10a are formed in regions, which are established by excluding a region covered by the gate electrode 8 from the P well 27, i.e., regions directly underlying the S/D regions. Accordingly, regions of the P well 27, into which regions P⁺ ions are not counter-implanted, constitute the P type diffusion regions 10b, 10c, 10d and 10e, all of which are formed to have a net dopant concentration higher than that of the P type diffusion region 10a. Thereafter, as shown in FIG. 20B, the resist 30 is removed.

Thereafter, as shown in FIG. 15B and similarly to the method employed in the aforementioned second embodiment, n⁺ diffusion regions 12 and p⁺ diffusion regions 14 are formed to constitute source/drain regions. Then, sidewalls are formed to cover the side surfaces of a set of gate insulating film 7 and gate electrode 8. Thus, the semiconductor device incorporating therein the NMOS transistor 16 and the PMOS transistor 17 is manufactured.

In the modification, since the dopant ions are implanted using a set of gate electrode 8 and gate insulating film 7 as a mask to form the P type diffusion regions 10a and the N type diffusion regions 11a in regions directly underlying the S/D regions, the gate electrode 8, the P type diffusion regions 10a and the N type diffusion regions 11a can be positioned in a self-aligned manner.

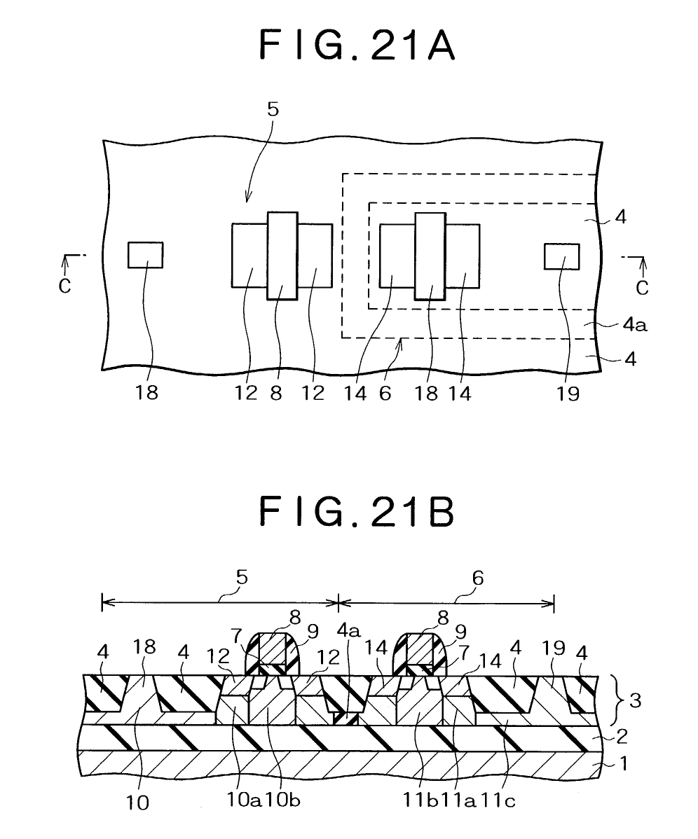

A third embodiment of the invention will be explained. FIG. 21A is a plan view of a semiconductor device according to the embodiment and FIG. 21B is a cross sectional view taken along line C-C shown in FIG. 21A. As shown in FIGS. 21A and 21B, the semiconductor device of the embodiment is constructed such that an STI region 4a serving as a completely isolating oxide film is formed so as to surround a PMOS transistor formation region 6. Since the STI region 4a is formed so that the lower end thereof reaches the BOX layer 2, it completely isolates an NMOS transistor formation region 5 and the PMOS transistor formation region 6 from each other. The configuration of the semiconductor device manufactured in accordance with the embodiment is the same as that of the semiconductor device manufactured in accordance with the first embodiment shown in FIGS. 7A and 7B. Note that when comparing the configuration shown in FIGS. 21A, 21B to that shown in FIGS. 7A, 7B, the NMOS transistor formation region 5 and the PMOS transistor formation region 6 illustrated in FIGS. 21A, 21B are shown as being opposite to those corresponding transistor formation regions illustrated in FIGS. 7A, 7B.

The semiconductor device of the embodiment is configured to have the STI region 4a as a completely isolating oxide film formed so as to surround the PMOS transistor formation region 6. This allows the semiconductor device of the embodiment to isolate components to be isolated from one another in a more complete manner compared to the case where the NMOS transistor formation region 5 and the PMOS transistor formation region 6 are PN junction isolated from each other. Particularly, since the STI region 4a is formed in a boundary between the NMOS transistor formation region 5 and the PMOS transistor formation region 6, a PN junction formed by diffusion regions of different conductivity types is eliminated from the device, allowing the semiconductor device to become more resistive to latch-up. Beneficial effects produced by employment of the semiconductor device of the embodiment and excluding the above-described effects are the same as those produced by employment of the semiconductor device of the aforementioned first embodiment.

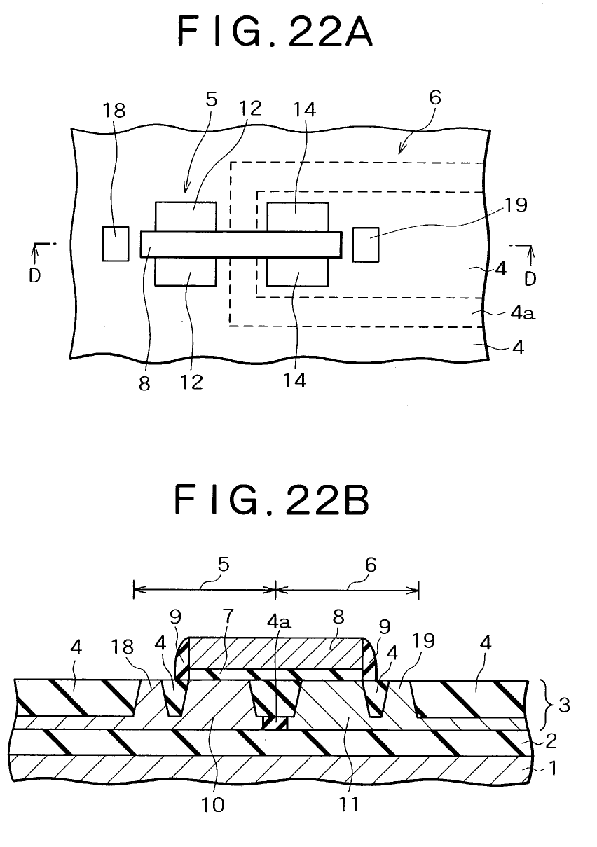

Subsequently, a fourth embodiment of the invention will be explained. FIG. 22A is a plan view of a semiconductor device according to the embodiment and FIG. 22B is a cross sectional view taken along line D-D shown in FIG. 22A. As shown in FIGS. 22A and 22B, the semiconductor device of the embodiment is constructed by combining the semiconductor device of the aforementioned second embodiment (refer to FIGS. 15A and 15B) and the semiconductor device of the aforementioned third embodiment (refer to FIGS. 21A and 21B). That is, an NMOS transistor 16 and a PMOS transistor 17 are formed to share one gate electrode, and an STI region 4a serving as a completely isolating oxide film is formed so as to surround the PMOS transistor formation region 6. The configuration, excluding the above-described configuration, of the semiconductor device manufactured in accordance with the embodiment is the same as that of the semiconductor device manufactured in accordance with the second embodiment shown in FIGS. 15A and 15B. Note that when comparing the configuration shown in FIGS. 22A, 22B to that shown in FIGS. 15A, 15B, the NMOS transistor formation region 5 and the PMOS transistor formation region 6 illustrated in FIGS. 22A, 22B are shown as being opposite to those corresponding transistor formation regions illustrated in FIGS. 15A, 15B.

The semiconductor device according to each of the aforementioned first through fourth embodiments is constructed such that the region having a dopant concentration higher than that of the SOI layer directly underlying the S/D regions is formed in the SOI layer directly below the gate electrode so as to reach the BOX layer. However, even in the case where the P type or N type diffusion region (body) positioned directly below the gate electrode is not formed so as to reach the BOX layer, it is possible to apply a power supply potential or ground potential to the body. That is, when forming a body, the body is formed to have a depth equal to or deeper than the depth of the STI region that isolates from each other the adjacent source/drain regions of transistors adjacent to each other. This allows the lower portion of the body to be connected to the diffusion region formed between the STI region and the BOX layer, thereby permitting the body to be connected to the body contact.

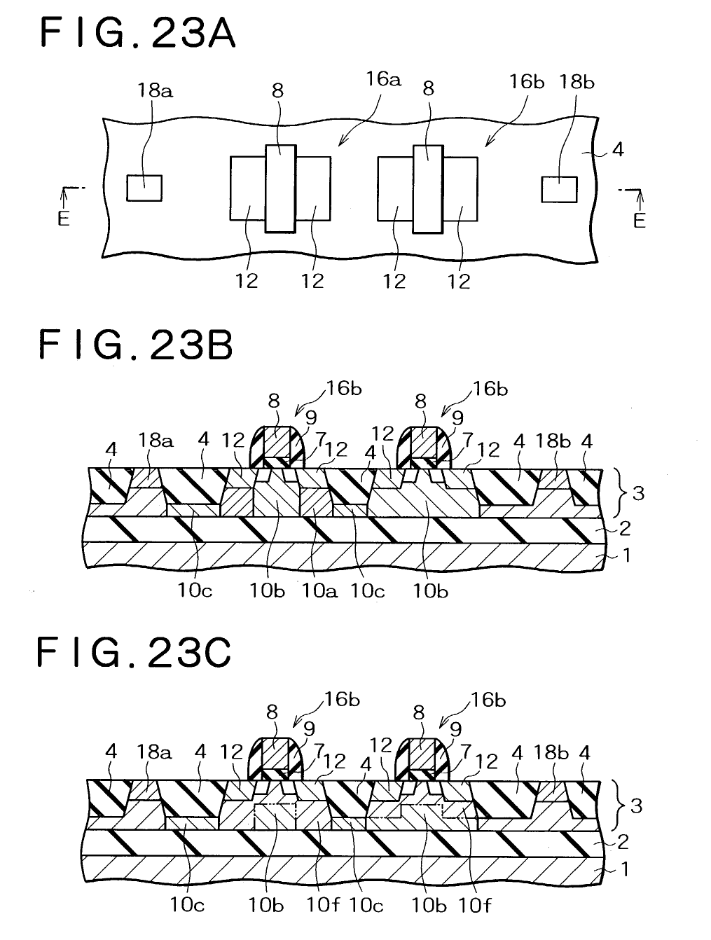

Subsequently, a fifth embodiment of the invention will be explained. FIG. 23A is a plan view of a semiconductor device according to the embodiment and FIG. 23B is a cross sectional view taken along line E-E shown in FIG. 23A, and FIG. 23C is a cross sectional view taken along line E-E shown in FIG. 23A and schematically illustrating regions over which a depletion layer is formed. As shown in FIGS. 23A through 23C, the semiconductor device of the embodiment is constructed such that a BOX layer 2 is formed on a P type silicon substrate 1 and an SOI layer 3 is formed thereon. The SOI layer 3 has an STI region 4 formed in the desired surface portion of the SOI layer 3, and regions partitioned by the STI region 4 are used to form NMOS transistors 16a and 16b and body contacts 18a and 18b. The body contact 18a, the NMOS transistor 16a, the NMOS transistor 16b and the body contact 18b are arranged in this order in a line.

The configuration of the NMOS transistor 16a is the same as that of the NMOS transistor 16 shown in FIG. 7B. That is, referring to FIG. 23B, a P type diffusion region 10b is formed in a region that is positioned directly below a gate electrode 8 of the NMOS transistor 16a within the SOI layer 3. P type diffusion regions 10a are formed in specific regions that directly underlies n⁺ diffusion regions 12 within the SOI layer 3 and depletion layers 10f are formed in the specific regions so as to reach the BOX layer 2. On the other hand, the NMOS transistor 16b is constructed such that regions corresponding to the P type diffusion regions 10a of the NMOS transistor 16a are formed to have the same dopant concentration as that of the P type diffusion regions 10b, i.e., the entire region constructed by combining the P type diffusion regions 10a and the P type diffusion region 10b of the NMOS transistor 16 shown in FIG. 7B is formed as a P type diffusion region 10b.

The NMOS transistor 16a can, for example, be formed by the same method as that employed in the aforementioned first embodiment. The NMOS transistor 16b can be formed by changing a part of a resist pattern used to form the P type diffusion region 10b in the step of forming the NMOS transistor 16a. That is, while a resist pattern used to form the P type diffusion region 10b in a desired region is formed on a region used to form the NMOS transistor 16a within the SOI layer 3 in a subsequent step, a resist pattern used to form the P type diffusion region 10b over a region surrounded by the STI region 4 is formed on a region used to form the NMOS transistor 16b within the SOI layer 3 in a subsequent step.

As shown in FIGS. 23B and 23C, an area occupied by a depletion layer 10f within the NMOS transistor 16a is approximately equal to an area occupied by the P type diffusion region 10a. That is, the lower face of the depletion layer 10f reaches the BOX layer 2. When the transistor is in operation, since a channel region is formed in a region, which is positioned near the surface within the SOI layer 3 while contacting a gate insulating film 7, the lower face of the depletion layer 10f underlying the channel region is positioned slightly lower than the upper face of the P type diffusion region 10b. In contrast, the depletion layer 10f within the NMOS transistor 16b never reaches the BOX layer 2. This is because a region (transistor component formation region), surrounded by the STI region 4, of the SOI layer 3 is the P type diffusion region 10b having a dopant concentration higher than that of the P type diffusion region 10a and therefore, the depletion layer 10f formed between the n⁺ diffusion regions 12 and the P type diffusion region 10b cannot expand. As a result, the body of the NMOS transistor 16b is formed in a region directly below the gate electrode 8, as well as regions directly below the n⁺ diffusion regions 12. The body, i.e., a neutral region in which a depletion layer is not formed comes to be connected to the P type diffusion region 10c, formed between the STI region 4 and the BOX layer 2, at four sides. In this case, the term “four sides” indicates individual sides of a rectangle region partitioned by the STI region 4 shown in FIG. 23A and occupied by the NMOS transistor 16b. Note that the body has P type dopants diffused thereinto and exhibits a suitable electrical conductivity.

Since the NMOS transistor 16b has the depletion layer 10f formed so as not to reach the BOX layer 2, it has a larger parasitic and capacitive coupling between the source/drain region and the associated components compared to that observed in the NMOS transistor 16a. Accordingly, the NMOS transistor 16b operates at a speed lower than the speed at which the NMOS transistor 16a operates. However, the resistance between the P type diffusion region 10b as the body of the NMOS transistor 16b and the body contact 18b becomes lower than the resistance between the P type diffusion region 10b as the body of the NMOS transistor 16a and the body contact 18a, and therefore, the NMOS transistor 16b is able to more effectively suppress variations in the potential of the body and further stabilize its threshold voltage. Accordingly, the semiconductor device of the embodiment can be employed in such a manner that the NMOS transistor 16a is used in a digital circuit in which operating speed takes priority over stability of threshold voltage and the NMOS transistor 16b is used in an analog circuit in which stability of threshold voltage takes priority over operating speed. As described above, the semiconductor device of the embodiment is able to include NMOS transistors having performances different from each other formed together in the device. Note that although in the embodiment, explanation has been made to an NMOS transistor, needless to say, the technique disclosed in the embodiment can be applied to a PMOS transistor and further, to both an NMOS transistor and a PMOS transistor simultaneously.

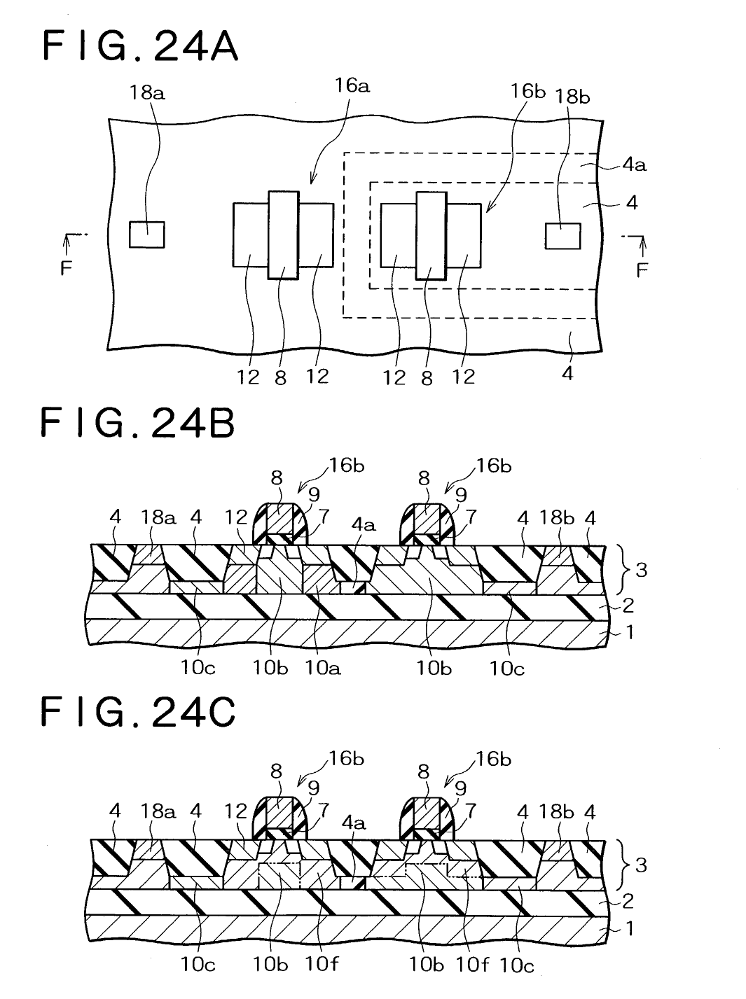

Subsequently, a sixth embodiment of the invention will be explained. FIG. 24A is a plan view of a semiconductor device according to the embodiment and FIG. 24B is a cross sectional view taken along line F-F shown in FIG. 24A, and FIG. 24C is a cross sectional view taken along line F-F shown in FIG. 24A and schematically illustrating regions over which a depletion layer is formed. As shown in FIGS. 24A through 24C, the semiconductor device of the embodiment is constructed such that an STI region 4a as a completely isolating oxide film is formed so as to surround a region in which the NMOS transistor 16b and the body contact 18b of the semiconductor device (refer to FIGS. 23A and 23B) according to the aforementioned fifth embodiment are formed. The configuration, excluding the above-described configuration, of the semiconductor device manufactured in accordance with the embodiment is the same as that of the semiconductor device manufactured in accordance with the fifth embodiment shown in FIGS. 23A and 23B. The semiconductor device of the embodiment is configured to more securely isolate the NMOS transistor 16b and the body contact 18b from other transistor components compared to the semiconductor device of the aforementioned fifth embodiment. This securely prevents noise generated by the NMOS transistor 16a and the like from entering the NMOS transistor 16b.

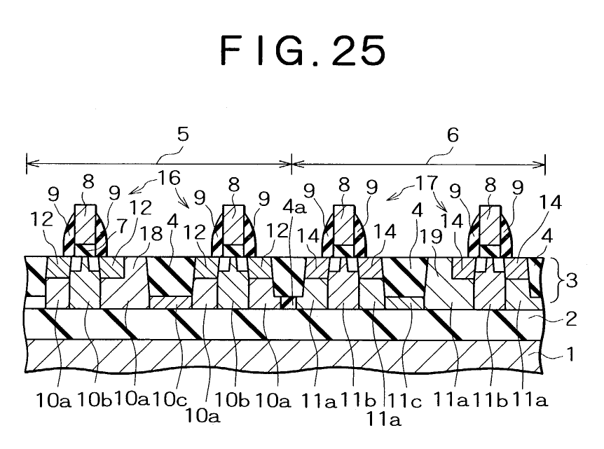

Subsequently, a seventh embodiment of the invention will be explained. FIG. 25 is a cross sectional view of a semiconductor device according to the embodiment. Note that a schematic plan view illustrating a body resistor of the semiconductor device shown in FIG. 25 is similar to that shown in FIG. 8. As shown in FIG. 25, the semiconductor device of the embodiment is constructed such that NMOS transistors 16 and PMOS transistors 17 each are formed of a plural number of, for example, two individual transistors and a body contact 18 is formed so as to contact an n⁺ diffusion region 12 of one NMOS transistor 16, and a body contact 19 is formed so as to contact a p⁺ diffusion region 14 of one NMOS transistor 17. The configuration, excluding the above-described configuration, of the semiconductor device manufactured in accordance with the embodiment is the same as that of the semiconductor device manufactured in accordance with the aforementioned third embodiment.

In the aforementioned third embodiment, the ground potential is applied to the body of the NMOS transistor via the n⁺ diffusion region 12 as a source/drain region of the NMOS transistor and the body contact 18 isolated by the STI layer 4. In this case, the resistance of a body resistor Rbody shown in FIG. 8 exists in a connection path between the body contact 18 and the body (P type diffusion region 10b). In contrast, the semiconductor device of the embodiment is constructed such that the body contact 18 is formed within a region used to form the source/drain region of the transistor within the SOI layer 3, so as to be positioned adjacent the source/drain region. This configuration makes it possible to largely reduce the resistance of the body and then solve a variety of problems due to variations in the potential of the body. The body contact 18 does not necessarily need to be formed in individual transistors. As shown in FIG. 25, for example, the body contact 18 is formed in the NMOS transistor 16 positioned on the left in the figure and chosen out of the two NMOS transistors 16 formed in the NMOS transistor formation region 5, thereby allowing the NMOS transistor 16 positioned on the right in the figure to exclude the need for formation of body contact. This is because an advantageous mechanism similar to the mechanism observed when a voltage is applied to the body via the body contact in the aforementioned third embodiment takes place between the body of the NMOS transistor 16 on the right in the figure and the body contact 18 formed in the NMOS transistor 16 on the left in the figure.

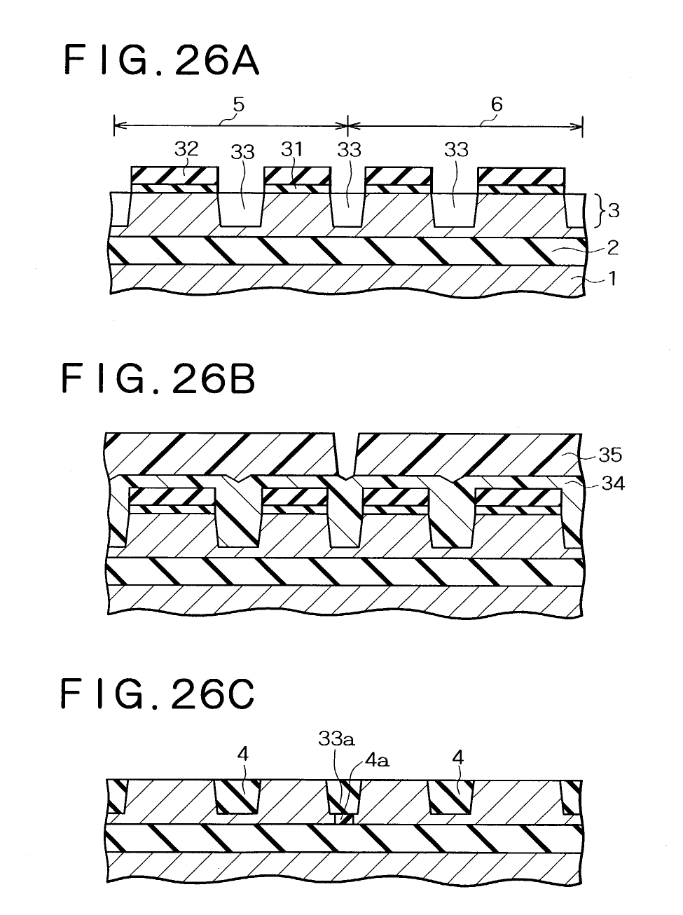

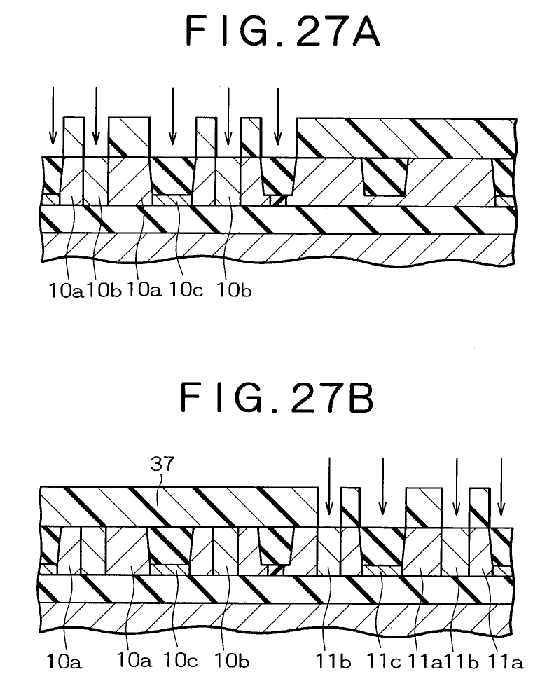

Subsequently, a method for manufacturing a semiconductor device in accordance with the embodiment will be explained. FIGS. 26A through 26C and FIGS. 27A and 27B are cross sectional views illustrating a method for manufacturing a semiconductor device in accordance with the embodiment in the order of manufacturing steps. First, as shown in FIG. 26A, a BOX layer 2 is formed on a P type silicon substrate 1 and an SOI layer 3 is formed thereon to have a thickness of, for example, 250 nm. Then, an SiO₂ film 31 is deposited on the surface of the SOI layer 3 and an Si₃N₄ film 32 is deposited on the SiO₂ film 31. Thereafter, the SiO₂ film 31 and the Si₃N₄ film 32 are patterned to form an opening in a region used to form an STI region 4 in a subsequent step. Then, the SOI layer 3 is etched using the SiO₂ film 31 and the Si₃N₄ film 32 as a mask to remove the desired portion of the SOI layer 3 and then form a trench 33 having a depth of, for example, 200 nm in the SOI layer 3. Subsequently, the silicon substrate is subjected to oxidation treatment to round the inner surface of the trench 33. This eliminates disorder created by the etching and left in the inner surface of the trench 33 and rounds the inner surface profile of the trench 33 in order for a transistor, which will be formed in the SOI layer 3 in a subsequent step, to be able to avoid formation of electrical concentration.

Subsequently, as shown in FIG. 26B, an Anti-Reflection Coating (ARC) 34 is formed over the surface of the substrate and a resist 35 is coated on the ARC 34. Then, the resist 35 is patterned to form an opening in a region used to form an STI region 4a (refer to FIG. 25) in a subsequent step.

Thereafter, as shown in FIG. 26C, the ARC 34 and the SOI layer 3 are etched using the resist 35 as a mask so that a desired portion of the bottom of the trench 33, in which desired portion the STI region 4a will be formed in a subsequent step, is removed to expose the BOX layer 2. Hereinafter, the trench 33 reaching the BOX layer 2 is referred to as a trench 33a. Then, the resist 35 and the ARC 34 are removed. Thereafter, an SiO₂ film is deposited over the entire surface of the P type silicon substrate 1 by High Density Plasma Chemical Vapor Deposition (HDP-CVD) processes to form the SiO₂ film within the trenches 33 and 33a. Then, the SiO₂ film is polished by Chemical Mechanical Polishing (CMP) to expose the Si₃N₄ film 32 and flatten the surface of the substrate, and further, the Si₃N₄ film 32 and the SiO₂ film 31 are removed to form the STI regions 4 and 4a filled with the SiO₂ film. The STI region 4a is formed to have the same thickness as that of the SOI layer 3 and have a thickness of, for example, 250 nm.

Subsequently, as shown in FIG. 27A, a resist 36 is coated on the STI layer 3 and is patterned to have openings through which a channel region formed in a subsequent step and the STI region 4 of the NMOS transistor formation region 5 are exposed. Then, B⁺ ions as a P type dopant are implanted using the resist 36 as a mask. Thus, the dopant ions are implanted into desired portions of the SOI layer to form P wells. In this case, for example, the implantation parameter may be 1×10¹² cm⁻² dose and 70 keV energy. Thus, P type diffusion regions 10b are formed directly below the channel regions of the NMOS transistor formation region 5 within the SOI layer 3 and at the same time, a P type diffusion region 10c is formed in the SOI layer 3 between the STI region 4 and the BOX layer 2 within the NMOS transistor formation region 5. In this case, regions of the P well 10, into which regions B⁺ ions are not implanted in the step shown in FIG. 27A, becomes P type diffusion regions 10a.

Subsequently, as shown in FIG. 27B, the resist 36 is removed and a resist 37 is coated on the SOI layer 3, and the resist 37 is patterned to have openings through which the channel region formed in a subsequent step and the STI region 4 of the PMOS transistor formation region 6 are exposed. Then, N type dopants, for example, P⁺ ions are implanted using the resist 37 as a mask. Thus, the dopant ions are implanted into desired portions of the SOI layer to form N wells. In this case, for example, the implantation parameter may be 1×10¹³ cm⁻² dose and 170 keV energy. Thus, N type diffusion regions 11b are formed directly below the channel regions of the PMOS transistor formation region 6 within the SOI layer 3 and at the same time, an N type diffusion region 11c is formed in the SOI layer 3 between the STI region 4 and the BOX layer 2 within the PMOS transistor formation region 6. In this case, regions of the N well 11, into which regions P⁺ ions are not implanted in the step shown in FIG. 27B, becomes N type diffusion regions 11a.

Thereafter, as shown in FIG. 25, the resist 37 (refer to FIG. 27B) is removed and gate insulating films 7, gate electrodes 8 and sidewalls 9 are formed, and further, n⁺ diffusion regions 12 and p⁺ diffusion regions 14 as a source/drain region are formed within the SOI layer 3, resulting in formation of a semiconductor device incorporating therein an NMOS transistor 16 and a PMOS transistor 17.

In the embodiment, the STI region 4a as a completely isolating oxide film is formed between the NMOS transistor formation region 5 and the PMOS transistor formation region 6. This allows the STI region 4a to have a width smaller than that of the STI region that is formed when the NMOS transistor formation region 5 and the PMOS transistor formation region 6 are PN junction isolated from each other. In addition, forming the body contact 18 within a region used to form the source/drain diffusion region of the transistor within the SOI layer 3, so that the body contact is positioned adjacent the source/drain region makes it possible to reduce the resistance of the body and more effectively suppress variations in the potential of the body. Beneficial effects produced by employment of the semiconductor device of the embodiment and excluding the above-described effects are the same as those produced by employment of the semiconductor device of the aforementioned first embodiment.

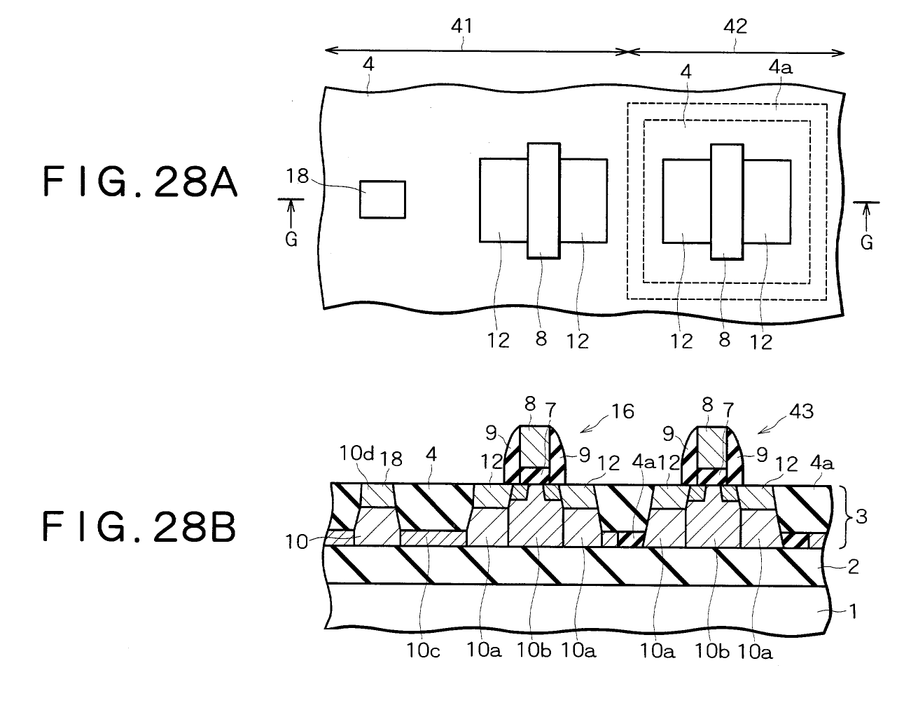

Subsequently, an eighth embodiment of the invention will be explained. FIG. 28A is a plan view of a semiconductor device according to the embodiment and FIG. 28B is a cross sectional view taken along line G-G shown in FIG. 28A. As shown in FIGS. 28A and 28B, the semiconductor device of the embodiment is constructed such that a P type silicon substrate 1 is provided and a BOX layer 2 is formed on the substrate, and an SOI layer 3 is formed thereon. The SOI layer 3 is formed to have a thickness of, for example, 150 nm. The SOI layer 3 has a BST type SOI region 41 and a Body-Floating type SO region 42 formed therein. Furthermore, the BST type SOI region 41 has an NMOS transistor 16 and a body contact 18 formed therein, and an STI region 4 as a partially isolating film is formed between the NMOS transistor 16 and the body contact 18. The STI region 4 is formed to have a thickness of, for example, 100 nm and have its upper surface exposed at the surface of the SOI layer 3 and its lower surface positioned so as not to contact the BOX layer 2, in other words, positioned so as to face the BOX layer 2 via the SOI layer 3 that has a thickness of, for example 50 nm and is formed as a P type diffusion region 10c. On the other hand, the Body-Floating type SOI region 42 has an NMOS transistor 43 formed therein and the NMOS transistor 43 is surrounded by an STI region 4a as a completely isolating film. The STI region 4a is formed to have its lower surface positioned so as to contact the BOX layer 2. Note that the term “BSTSOI” is the trademark registered by this applicant.

The configuration of the NMOS transistor 16 is the same as that of the NMOS transistor 16 of the aforementioned first embodiment. That is, the P type diffusion regions 10a underlying the S/D regions within the P well 10 have a dopant concentration lower than those of the P type diffusion region 10b formed below the channel region and the P type diffusion region 10c formed below the STI region. Furthermore, the body that is formed below the channel region upon turning-on of the NMOS transistor 16 is connected to the P type diffusion region 10d serving as the body contact 18 via the P type diffusion region 10c formed between the BOX layer 2 and the STI region 4. Note that the P type diffusion region 10a is formed to have a dopant concentration of, for example, from 1×10¹⁵ to 1×10¹⁶ cm⁻³ and the P type diffusion region 10b is formed to have a dopant concentration of, for example, from 1×10¹⁷ to 1×10¹⁸ cm⁻³, the P type diffusion region 10c is formed to have a dopant concentration of, for example, from 1×10¹⁷ to 1×10¹⁸ cm⁻³, and the P type diffusion region 10d is formed to have a dopant concentration of, for example, from 1×10¹⁷ to 1×10¹⁸ cm⁻³. For example, a ground potential is applied to the body contact 18.

On the other hand, the NMOS transistor 43 is surrounded by the STI region 4a that reaches the BOX layer 2. Accordingly, the body formed below the channel region of the NMOS transistor 43 within the P well 10 is not connected to the outside and is completely “floating.” Furthermore, P type diffusion regions 10a are formed below the S/D regions of the NMOS transistor 43 within the P well 10 and a P type diffusion region 10b is formed below the channel region thereof within the P well 10. That is, also in the NMOS transistor 43, the dopant concentration of a region underlying the S/D region is lower than that of a region underlying the channel region.

Subsequently, how the semiconductor device of the embodiment operates will be explained. Hereinafter, the transistor (NMOS transistor 16) formed in the BST type SOI region 41 is referred also to as a BST type SOI transistor and the transistor (NMOS transistor 43) formed in the Body-Floating type SOI region 42 is referred also to as a BF type SOI transistor. When the NMOS transistor 16 is turned on, depletion layers are formed below the S/D regions within the P well 10. In this case, since the dopant concentration of the P type diffusion region 10a is lower than those of the remaining regions within the P well 10, the depletion layer formed below each of the S/D regions reaches the BOX layer 2. Moreover, since the P type diffusion region 10b positioned below the channel region of the NMOS transistor 16 is formed to have a dopant concentration higher than that of the P type diffusion region 10a, the body as a neutral region is formed in the P type diffusion region 10b. Then, electrical charges accumulated within the body are discharged to the outside via the P type diffusion regions 10c and 10d. On the other hand, when the NMOS transistor 43 is turned on, depletion layers are formed below the S/D regions and reach the BOX layer 2. Furthermore, the body is formed below the channel region of the NMOS transistor 43. Since the body is floating, the potential of the body changes upon turning-on of the NMOS transistor 43.

The semiconductor device of the embodiment is configured to have the BST type SO transistor (NMOS transistor 16) and the BF type SO transistor (NMOS transistor 43) formed on a single chip. As described above, in the BST type SOI transistor, since the P wells underlying the S/D regions are formed to have a low dopant concentration, depletion layers are created upon turning-on of transistor and then reach the BOX layer. This reduces the capacitance across the junction. In addition, since sufficient amount of dopants are implanted into the P well underlying the channel region, the body is formed below the channel region. This allows the transistor to increase the current (on-current) conducted through its source-drain path. Moreover, even in a case where electrical charges flows into the body upon turning-on of transistor and change the potential of the body, since the body is connected to the body contact, the potential of the body returns to a reference potential before subsequent turning-on of transistor. The advantageous mechanism described above allows the NMOS transistor 16 to operate at a high speed while stabilizing its threshold voltage.

On the other hand, in the BF type SOI transistor, since the body becomes floating, electrical charges accumulated within the body cannot be discharged. Accordingly, although the threshold voltage of the BF type SOI transistor changes more easily compared to that of the BST type SOI transistor, the BF type SOI transistor is able to further increase the current (on-current) conducted through its source-drain path and operate at a higher speed. Furthermore, in the embodiment, since the SOI layer 3 is formed thin, i.e., having a thickness of, for example, 150 nm, the body is made smaller and the influence of the potential of back-gate on transistor performance becomes smaller. Accordingly, even in a case where a power supply voltage is not greater than 1 volt, individual logic gates stacked together can be realized.

Therefore, the BST type SOI transistor is suitable for use in a circuit, in which stability of threshold voltage takes priority over operating speed, such as an analog circuit, a Phase-Locked Loop (PLL) circuit and a Static Random Access Memory (SRAM). Furthermore, since the BST type SOI transistor is configured to have a connection path, along which electrical charges are discharged, between the body and the body contact, it is also suitable for use as a protection device for protecting internal circuits from damage due to Electro Static Discharge (ESD). On the other hand, the BF type SOI transistor is suitable for use in a circuit, in which operating speed takes priority over stability of threshold voltage, such as a digital circuit. Thus, fabricating together the BST type SOI transistor and the BF type SOI transistor on a single chip allows a semiconductor device to include individual circuits each having optimal transistor configuration, maximizing the performance of semiconductor device.

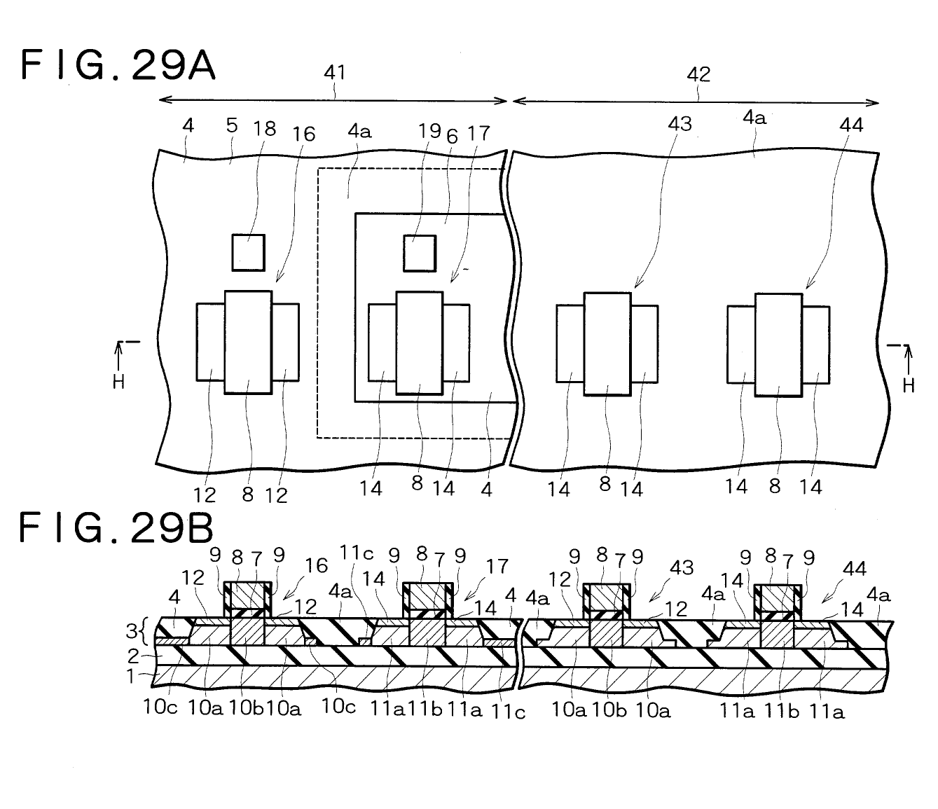

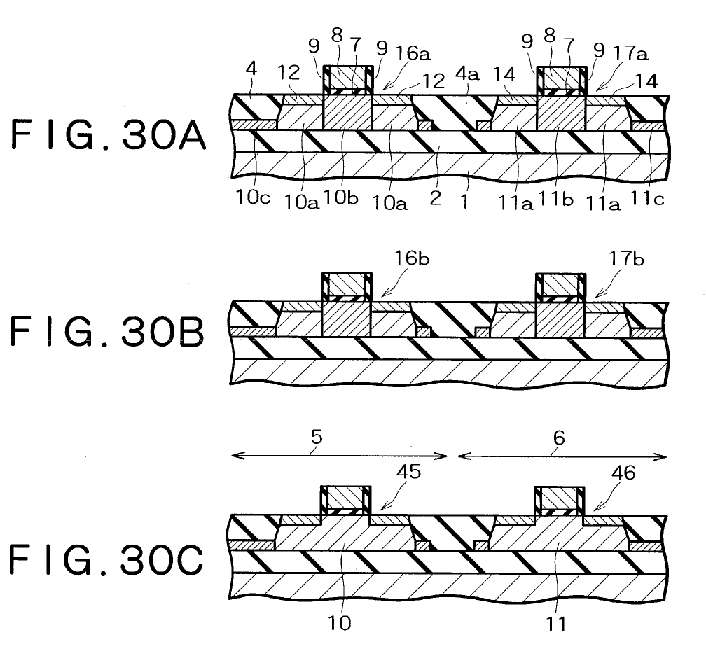

Subsequently, a ninth embodiment of the invention will be explained. FIG. 29A is a plan view of a semiconductor device according to the embodiment and FIG. 29B is a cross sectional view taken along line H-H shown in FIG. 29A. Moreover, FIGS. 30A through 30C are cross sectional views of a BST type SOI transistor according to the embodiment and FIG. 30A illustrates core transistors formed in a core section of the semiconductor device, and FIG. 30B illustrates I/O transistors formed in an I/O section, and FIG. 30C illustrates SRAM transistors formed in an SRAM section.

As shown in FIGS. 29A and 29B, the semiconductor device of the embodiment is configured to have a BST type SOI region 41 and a Body-Floating type SOI region 42 provided therein and the BST type SOI region 41 is configured to have an NMOS transistor formation region 5 and a PMOS transistor formation region 6 provided therein. Furthermore, the NMOS transistor formation region 5 is configured to have an NMOS transistor 16 and a body contact 18 formed therein, and the PMOS transistor formation region 6 is configured to have a PMOS transistor 17 and a body contact 19 formed therein. The configuration of the NMOS transistor formation region 5 and the PMOS transistor formation region 6 is the same as that employed in the aforementioned third embodiment (refer to FIG. 21). That is, an STI region 4a as a completely isolating film surrounds the PMOS transistor formation region 6. Moreover, the body of the NMOS transistor 16 is connected to the body contact 18 and the body of the PMOS transistor 17 is connected to the body contact 19. Note that in FIG. 29A, sidewalls 9 (refer to FIG. 29B) are omitted for simplification.

Additionally, as shown in FIGS. 30A and 30B, the NMOS transistor 16 and the PMOS transistor 17 each are grouped into two types of transistors. That is, the NMOS transistor 16 is grouped into an NMOS transistor 16a formed in the core section and an NMOS transistor 16b formed in the I/O section, and the PMOS transistor 17 is grouped into a PMOS transistor 17a formed in the core section and a PMOS transistor 17b formed in the I/O section. The core transistor and the I/O transistor are formed such that individual transistor components of one of those two transistors and individual transistor components of the other of those two transistors have dimensions different from each other. For example, the thickness of a gate insulating film 7 of the core transistor ranges from 1.6 to 1.9 nm and the thickness of a gate insulating film 7 of the I/O transistor ranges from 3 to 5 nm. Furthermore, as shown in FIG. 30C, the NMOS transistor formation region 5 and the PMOS transistor formation region 6 of the SRAM section have an NMOS transistor 45 and a PMOS transistor 46 formed therein respectively. The NMOS transistor 45 and the PMOS transistor 46 are a BST type SOI transistor and further an SRAM transistor. The NMOS transistor 45 is constructed such that a P type diffusion region 10g is formed below S/D regions and a channel region within a P well 10, and the PMOS transistor 46 is constructed such that an N type diffusion region 11g is formed below S/D regions and a channel region within an N well 11. That is, the SRAM transistor is configured so that dopant concentration is uniform throughout the well including a region underlying the S/D regions. The configurations, excluding the above-described configuration, of the NMOS transistor 45 and the PMOS transistor 46 are the same as those of the NMOS transistor 16 and the PMOS transistor 17.

On the other hand, the Body-Floating type SOI region 42 is configured to have an NMOS transistor 43 and a PMOS transistor 44 provided therein. An STI region 4a as a completely isolating film surrounds each of the NMOS transistor 43 and the PMOS transistor 44. The NMOS transistor 43 and the PMOS transistor 44 are configured in the same manner as those employed to form the NMOS transistor 16 and the PMOS transistor 17, respectively, and used as a core transistor. Note that the Body-Floating type SOI transistor 42 does not include a body contact. How the semiconductor device of the embodiment operates is similar to that explained in the description of the aforementioned eighth embodiment.

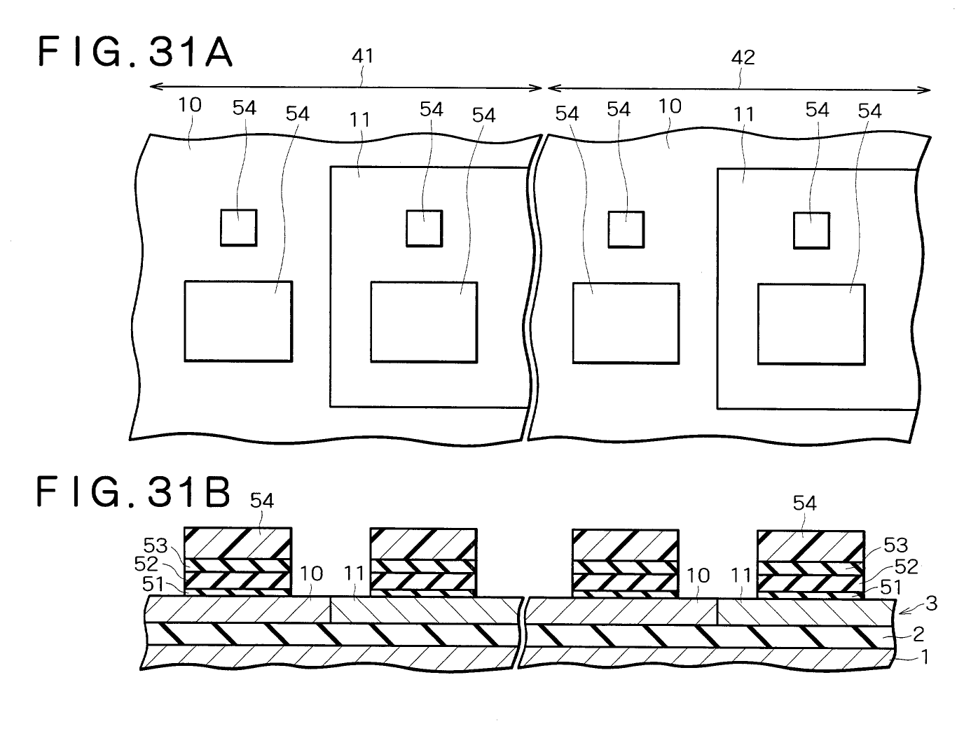

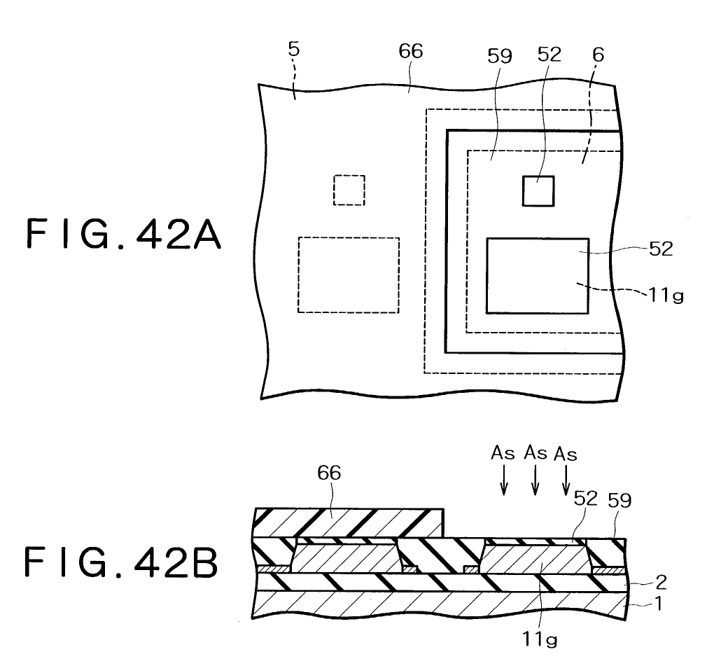

Subsequently, a method for manufacturing a semiconductor device according to the embodiment will be explained. FIGS. 31A, 31B through 42A, 42B are views illustrating a method for manufacturing a semiconductor device according to the embodiment in the order of manufacturing steps, and FIGS. 31A through 42A are plan views, and FIGS. 31B and 42B are cross sectional views.

First, as shown in FIGS. 31A and 31B, a BOX layer 2 is formed on a P type silicon substrate 1. Then, an SOI layer 3 is formed on the BOX layer 2. The SOI layer 3 is formed to have a thickness of, for example, 150 nm. Thereafter, boron (B) dopants are implanted within the SOI layer 3 to form P wells 10 and arsenic (As) dopants are implanted within the SOI layer 3 to form N wells 11. Thus, an SOI substrate having wells formed therein is prepared.

Subsequently, a pad oxide film 51 of SiO₂ is deposited on the surface of the SOI substrate to have a thickness of, for example, 9 nm and an SiN film 52 is deposited on the film 51 to have a thickness of, for example, 120 nm, and further, an NSG film 53 of Non-doped Silicon Glass (NSG) is deposited on the film 52 to have a thickness of, for example, 100 nm. Then, a resist 54 is coated on the NSG film 53 and patterned. In this case, the resist 54 is formed to have an opening through which an STI region will be formed in a subsequent step. That is, the resist 54 is formed to cover regions used to form transistors (NOMS transistors 16 and 43, and PMOS transistors 17 and 44) and body contacts in subsequent steps. Thereafter, the NSG film 53, the SiN film 52 and the pad oxide film 51 are etched to remove desired portions of those films. Then, the resist 54 is removed.

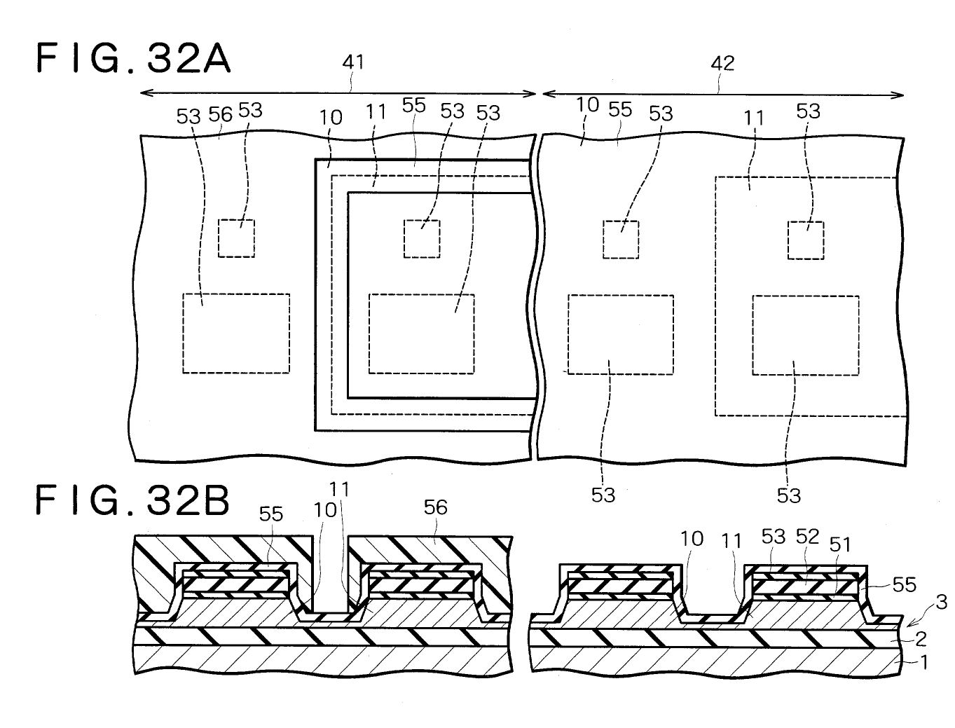

Subsequently, as shown in FIGS. 32A and 32B, the SOI layer 3 is etched to a depth of, for example, 100 nm using a laminated film consisting of the pad oxide film 51, the SiN film 52 and the NSG film 53 as a mask to remove a desired portion of the SOI layer 3. In this case, the SOI layer 3 having a thickness of, for example, 50 nm is left under the desired portion (i.e., etched portion) of the SOI layer. Then, an SiN film 55 is formed over the surface of the substrate. Thereafter, a resist 56 is formed on the SiN film 55 by coating. In this case, the resist 56 is formed so as to cover a region, excluding the region that is used to form an STI region 4a as a completely isolating film in a subsequent step, within the BST type SOI region 41 and so as not to cover the Body-Floating type SOI region 42.

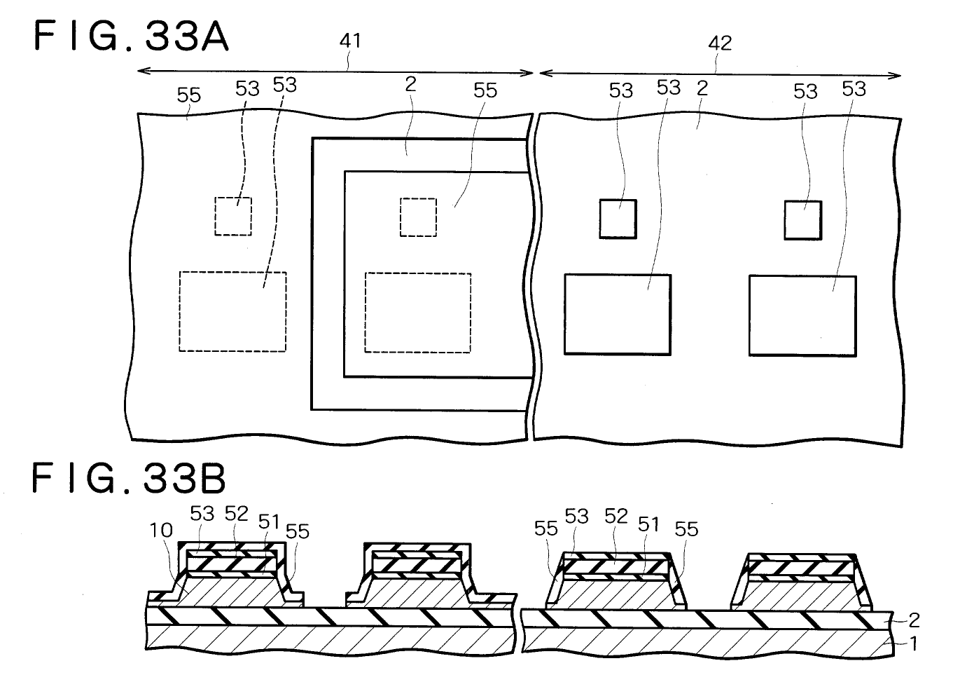

Subsequently, as shown in FIGS. 33A and 33B, the SOI layer 3 and the SiN film 55 are etched using the resist 56 (refer to FIG. 32A) and the NSG film 53 as a mask to remove desired portions of the SOI layer 3 and the SiN film 55. In this case, the BOX layer 2 is exposed through the opening of the resist 56 within the BST type SOI region 41. In the Body-Floating type SOI region 42, although the SiN film 55 formed on horizontal planes of the SOI layer 3 and the NSG film 53 is removed, the SiN film 55 formed on side surfaces of a laminated film consisting of the SOI layer 3, the pad oxide film 51, the SiN film 52 and the NSG film 53 remains even after completion of the etching because the SiN film 55 on the side surfaces before the etching is thick.

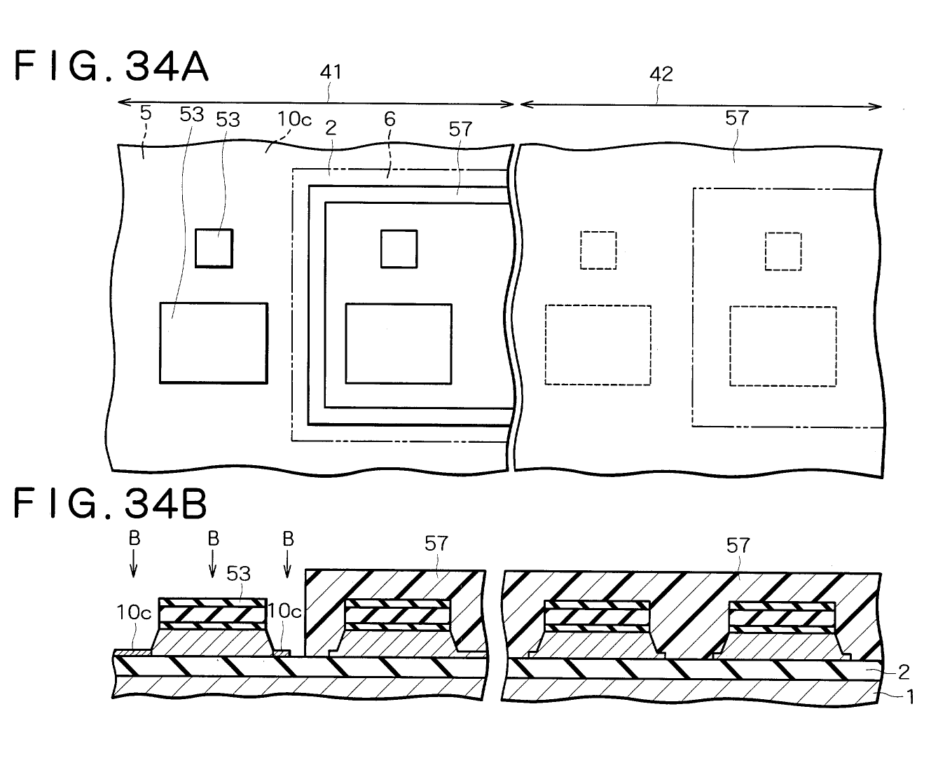

Subsequently, as shown in FIGS. 34A and 34B, a resist 57 is formed to cover the entire Body-Floating type SOI region 42 and the PMOS transistor formation region 6 of the BST type SOI region 41. Then, boron (B) dopants are implanted using the resist 57 and a laminated film consisting of the pad oxide film 51, the SiN film 52 and the NSG film 53 and formed in the NMOS transistor formation region 5 as a mask. In this case, for example, the implantation parameter may be 1×10¹³ cm⁻² dose and 7 keV energy. Thus, a region of the P well 10, which region will become a region underlying the STI region 4 in a subsequent step, is doped with boron dopants, forming a P type diffusion region 10c. Then, the resist 57 is removed.

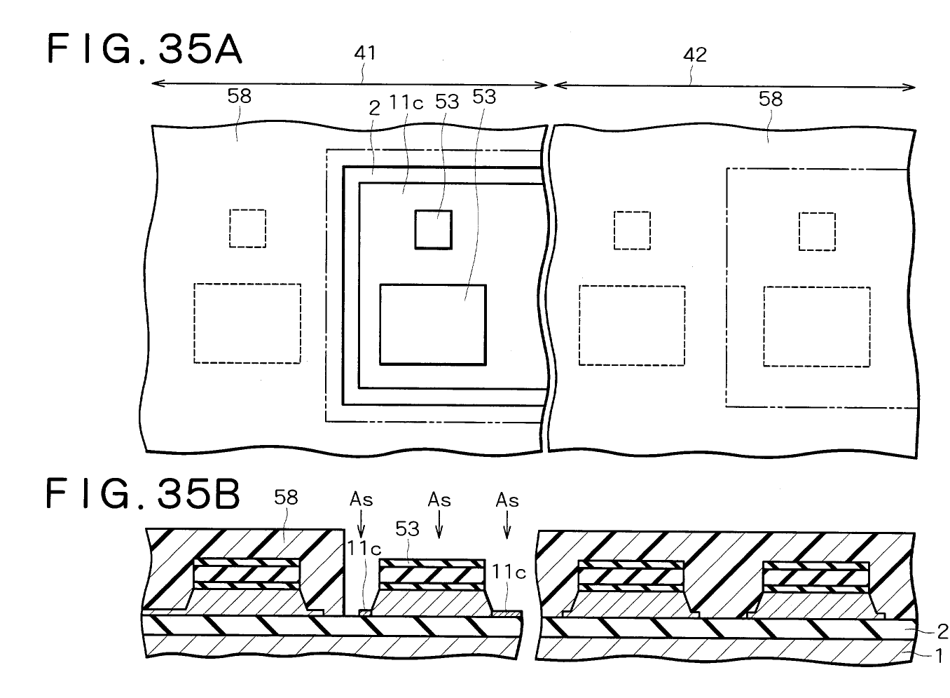

Thereafter, as shown in FIGS. 35A and 35B, a resist 58 is formed to cover the entire Body-Floating type SOI region 42 and the NMOS transistor formation region 5 of the BST type SOI region 41. Then, arsenic (As) dopants are implanted using the resist 58 and a laminated film consisting of the pad oxide film 51, the SiN film 52 and the NSG film 53 and formed in the PMOS transistor formation region 6 as a mask. In this case, for example, the implantation parameter may be 5×10¹² cm⁻² dose and 50 keV energy. Thus, a region of the N well 11, which region will become a region underlying the STI region 4 in a subsequent step, is doped with arsenic dopants, forming an N type diffusion region 11c. Then, the resist 58 is removed.

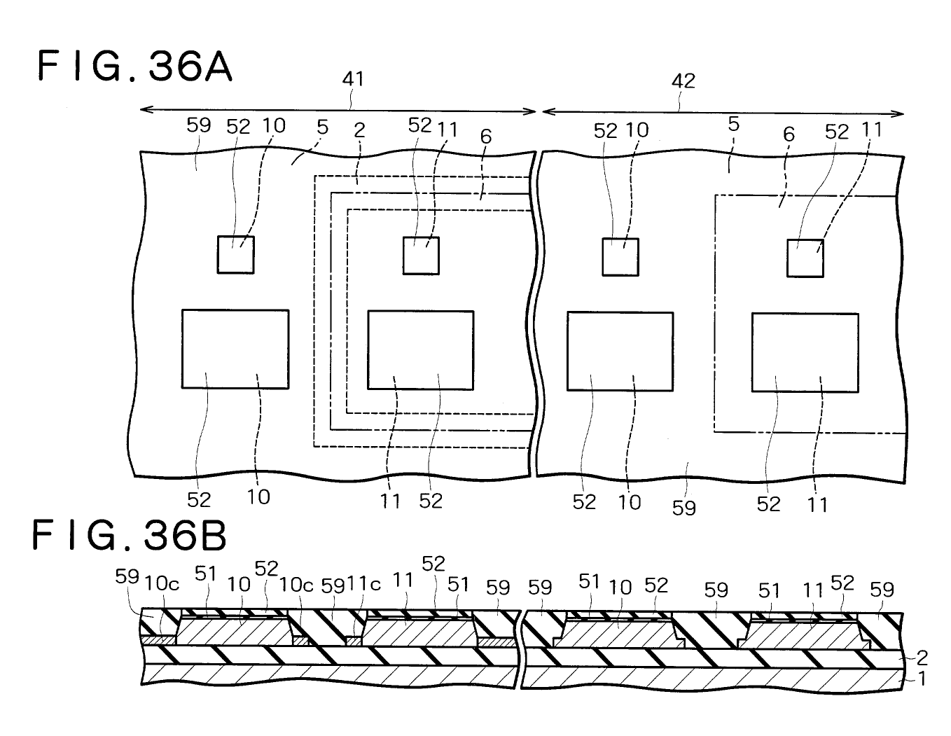

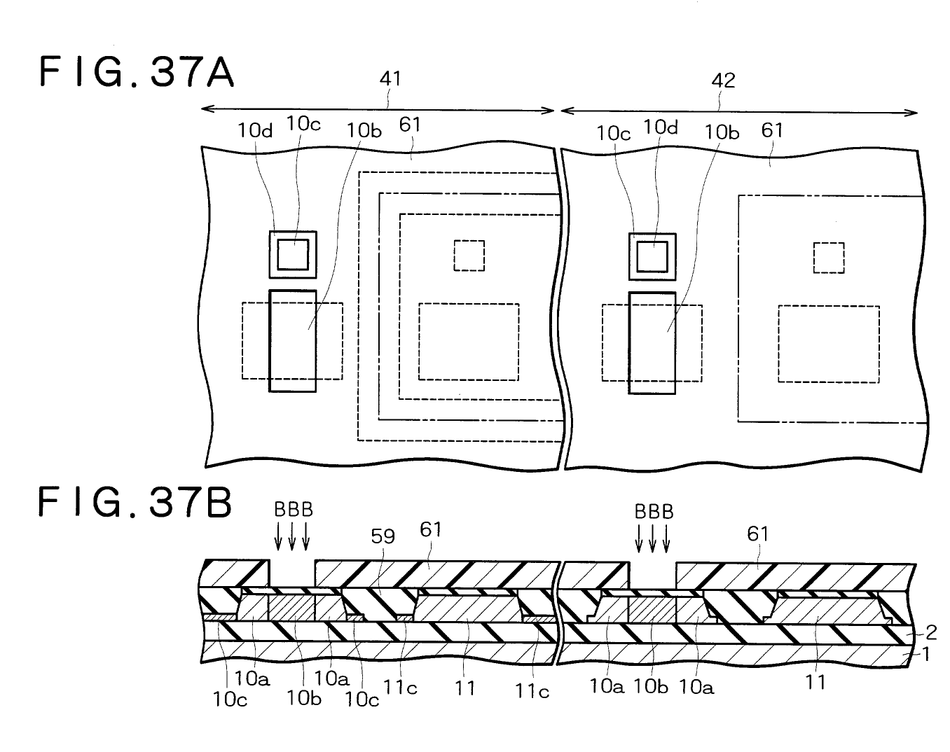

Thereafter, as shown in FIGS. 36A and 36B, a silicon oxide film 59 is deposited by High Density Plasma Chemical Vapor Deposition (HDP-CVD) processes to form a silicon oxide film 59 within a region, from which the desired portion of the SOI layer 3 is removed by etching, and is polished by Chemical Mechanical Polishing (CMP) to flatten the surface of the substrate. In this case, CMP is stopped on the SiN film 52. Thus, the NSG film 53 is removed and the SiN film 52 and the pad oxide film 51 remain. Note that in FIGS. 37 through 42, which will be later referred, the pad oxide film 51 is omitted for simplification.

Subsequently, as shown in FIGS. 37A and 37B, a resist 61 is formed. The resist 61 is formed to have openings through which the channel region of an NMOS transistor 16 (refer to FIG. 29A) and the body contact 18 (refer to FIG. 29A) will be formed in the core section of the BST type SOI region 41 and the channel region of an NMOS transistor 43 (refer to FIG. 29A) will be formed in the core section of the Body-Floating type SOI region 42. Note that the resist 61 covers the entire I/O section and the entire SRAM section. Then, boron (B) dopants are implanted using the resist 61 as a mask. In this case, for example, the implantation parameter may be 1.5×10¹² cm⁻² dose and 40 keV energy. Thus, a P type diffusion region 10b is formed in a region, which is to be positioned below the channel region of each of the NMOS transistors 16 and 43 as a core transistor in a subsequent step, within the P well 10 and further a P type diffusion region 10d is formed in a region, which is to be a body contact 18 in a subsequent step, within the P well 10. Note that regions positioned within the P well 10 and defined as a region into which boron dopants have not been implanted in the preceding steps become P type diffusion regions 10a. Then, the resist 61 is removed.

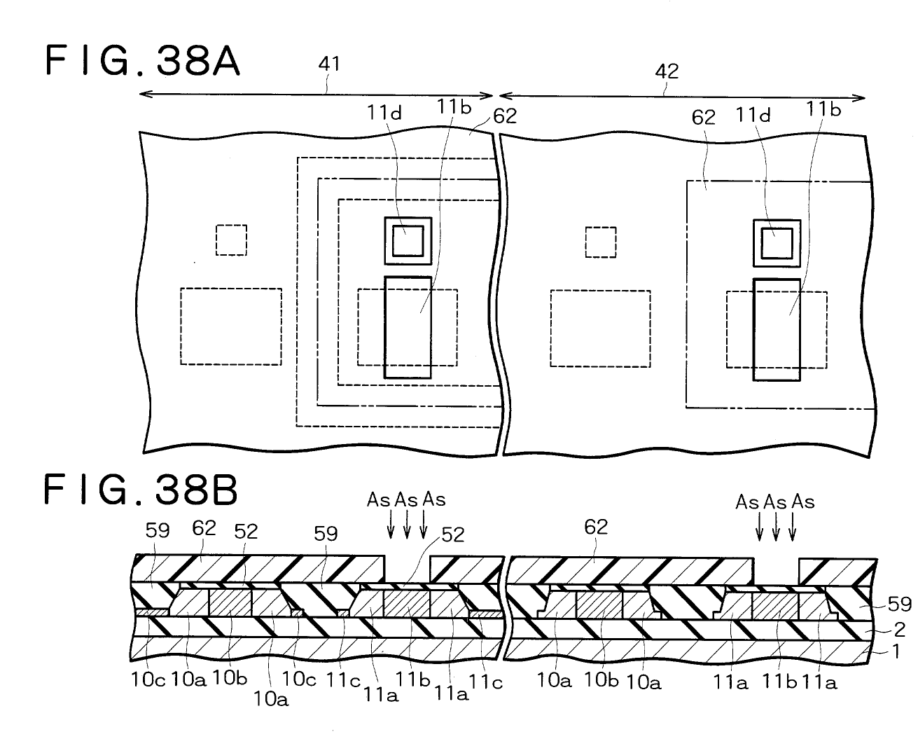

Thereafter, as shown in FIGS. 38A and 38B, a resist 62 is formed. The resist 62 is formed to have openings through which the channel region of a PMOS transistor 17 (refer to FIG. 29A) and the body contact 19 (refer to FIG. 29A) will be formed in the core section of the BST type SOI region 41 and the channel region of a PMOS transistor 44 (refer to FIG. 29A) will be formed in the core section of the Body-Floating type SOI region 42. Note that the resist 62 covers the entire I/O section and the entire SRAM section. Then, arsenic (As) dopants are implanted using the resist 62 as a mask. In this case, for example, the implantation parameter may be 2×10¹² cm⁻² dose and 240 keV energy. Thus, an N type diffusion region 11b is formed in a region, which is to be positioned below the channel region of each of the PMOS transistors 17 and 44 as a core transistor in a subsequent step, within the N well 11 and further an N type diffusion region 11d is formed in a region, which is to be a body contact 19 in a subsequent step, within the N well 11. Note that regions positioned within the N well 11 and defined as a region into which arsenic dopants have not been implanted in the preceding steps become N type diffusion regions 11a. Then, the resist 62 is removed.

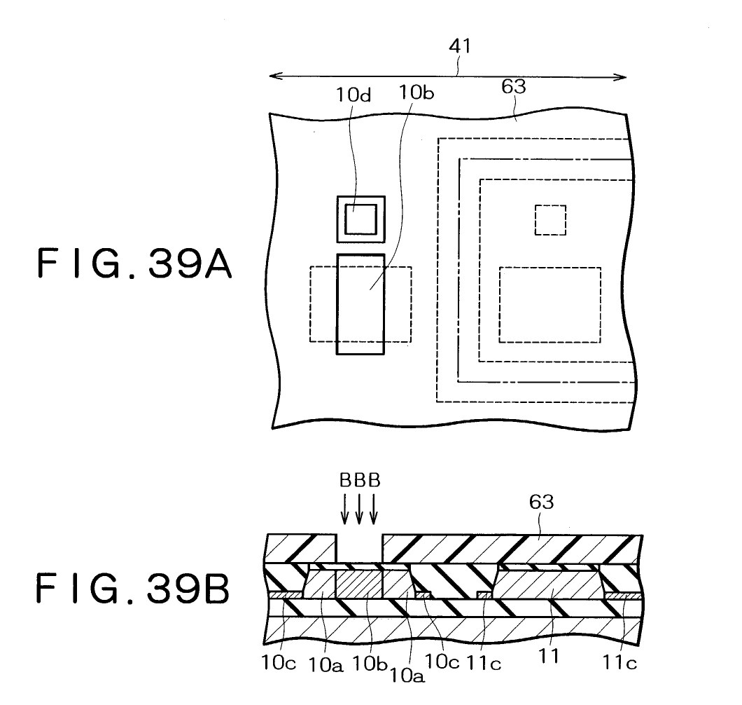

Thereafter, as shown in FIGS. 39A and 39B, a resist 63 is formed. The resist 63 is formed to have openings through which the channel region of an NMOS transistor 16 (refer to FIG. 29A) and the body contact 18 (refer to FIG. 29A) will be formed in the I/O section of the BST type SOI region 41. Note that the resist 63 covers the entire core section and the entire SRAM section of the BST type SOI region 41 and the entire Body-Floating type SOI region 42 (refer to FIG. 38A). Then, boron (B) dopants are implanted using the resist 63 as a mask. In this case, for example, the implantation parameter may be 1.5×10¹² cm⁻² dose and 40 keV energy. Thus, a P type diffusion region 10b is formed in a region, which is to be positioned below the channel region of the NMOS transistor 16 as an I/O transistor in a subsequent step, within the P well 10 and a P type diffusion region 10d is formed in a region, which is to be a body contact 18 in a subsequent step, within the P well 10. Note that regions positioned within the P well 10 and defined as a region into which boron dopants have not been implanted in the preceding steps become P type diffusion regions 10a. Then, the resist 63 is removed.

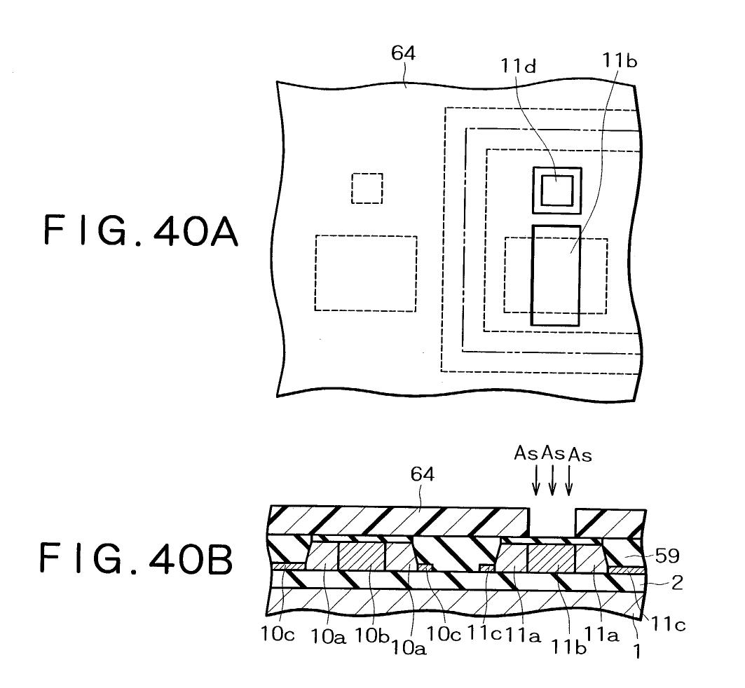

Thereafter, as shown in FIGS. 40A and 40B, a resist 64 is formed. The resist 64 is formed to have openings through which the channel region of a PMOS transistor 17 (refer to FIG. 29A) and the body contact 19 (refer to FIG. 29A) will be formed in the I/O section of the BST type SOI region 41. Note that the resist 64 covers the entire core section and the entire SRAM section of the BST type SOI region 41 and the entire Body-Floating type SOI region 42 (refer to FIG. 38A). Then, arsenic (As) dopants are implanted using the resist 64 as a mask. In this case, for example, the implantation parameter may be 2×10¹² cm⁻² dose and 240 keV energy. Thus, an N type diffusion region 11b is formed in a region, which is to be positioned below the channel region of the PMOS transistor 17 as an I/O transistor in a subsequent step, within the N well 11 and an N type diffusion region lid is formed in a region, which is to be a body contact 19 in a subsequent step, within the N well 11. Note that regions positioned within the N well 11 and defined as a region into which arsenic dopants have not been implanted in the preceding steps become N type diffusion regions 11a. Then, the resist 64 is removed.

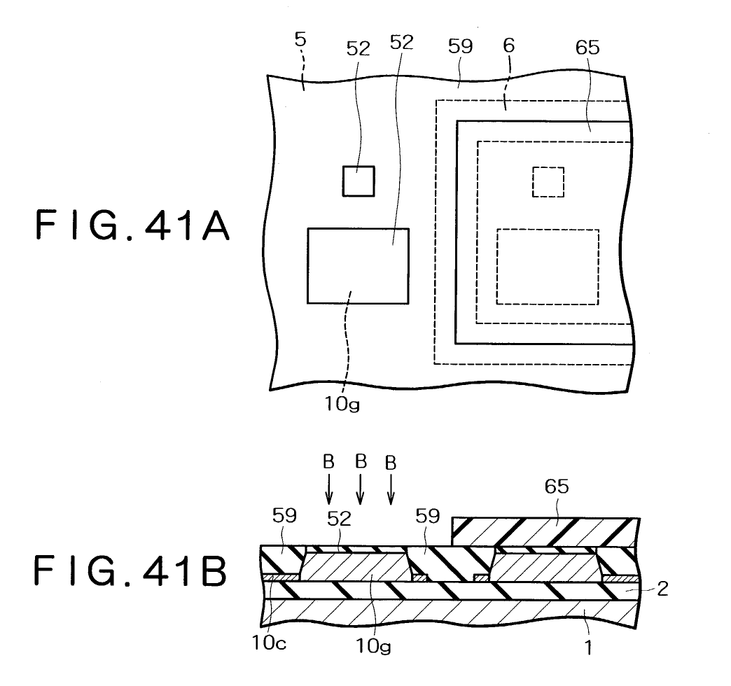

Subsequently, as shown in FIGS. 41A and 41B, a resist 65 is formed. The resist 65 is formed such that the entire NMOS transistor 5 in the SRAM section of the BST type SOI region 41 is exposed and the resist 65 covers the entire PMOS transistor formation region 6 in the SRAM section of the BST type SOI region 41, the entire core and I/O sections of the BST type SOI region 41, and the entire Body-Floating type SOI region 42 (refer to FIG. 38A). Then, boron (B) dopants are implanted using the resist 65 as a mask. In this case, for example, the implantation parameter may be 1.5×10¹² cm⁻² dose and 40 keV energy. Thus, P type diffusion regions 10g are formed in regions that are to be positioned below the channel region and the S/D regions of the NMOS transistor 16 in the SRAM section in a subsequent step and a region that is to be a body contact 18 in the SRAM section in a subsequent step. That is, the region underlying the channel region of the SRAM transistor and the regions underlying the S/D regions thereof are formed within the P well 10 to have the dopant concentrations equal to each other. Then, the resist 65 is removed.

Thereafter, as shown in FIGS. 42A and 42B, a resist 66 is formed. The resist 66 is formed such that the entire PMOS transistor formation region 6 in the SRAM section of the BST type SOI region 41 is exposed and the resist 65 covers the entire NMOS transistor formation region 5 in the SRAM section of the BST type SOI region 41, the entire core and I/O sections of the BST type SOI region 41, and the entire Body-Floating type SOI region 42 (refer to FIG. 38A). Then, arsenic (As) dopants are implanted using the resist 66 as a mask. In this case, for example, the implantation parameter may be 2×10¹² cm⁻² dose and 240 keV energy. Thus, N type diffusion regions 11g are formed in a region that is to be positioned below the channel region and the S/D regions of the PMOS transistor 17 in the SRAM section inca subsequent step and a region that is to be a body contact 19 in the SRAM section in a subsequent step. That is, the region underlying the channel region of the SRAM transistor and the regions underlying the S/D regions thereof are formed within the N well 11 to have the dopant concentrations equal to each other. Then, the resist 66 is removed.

Subsequently, as shown in FIGS. 29A, 29B and 30A through 30C, the SiN film 52 and the pad oxide film 51 are removed by wet-etching. Then, similarly to the method employed in the aforementioned first embodiment, a gate insulating film 7, a gate electrode 8, sidewalls 9 and source/drain regions are formed in each of the transistors. Thus, a semiconductor device incorporating therein the NMOS transistor 16 and the PMOS transistor 17 as a BST type SOI transistor and the NMOS transistor 43 and the PMOS transistor 44 as a BF type SOI transistor is fabricated.

If a comparison between the method employed in the embodiment and the conventional method for manufacturing a semiconductor device formed in a bulk material is carried out, the following result is obtained. That is, just changing a mask (not shown) used in the corresponding step in the conventional method to the mask used to form a pattern in the resist 56 as shown in FIGS. 32A and 32B allows the manufacture of a semiconductor device incorporating together a BST type SOI transistor and a BF type SOI transistor. This permits the semiconductor device of the embodiment to be fabricated utilizing as it is the design property of a semiconductor device formed in a bulk material.

Furthermore, in the embodiment, two types of transistors, a BST type SOI transistor and a BF type SOI transistor, can be formed as a core transistor. This allows preferable one out of two types of core transistors to be manufactured so as to meet the application' demands.

Moreover, the SRAM transistor is constructed such that regions underlying S/D regions are formed to have a dopant concentration equal to that of a region underlying a channel region. This eliminates the need to block implantation of dopants into regions below the S/D regions and implant dopants only into a region below the channel region, allowing reduction in the size of SRAM transistor and increase in the packing density of SRAM cells. Note that since the dopant concentration of regions underlying S/D regions is high, a depletion layer does not reach a BOX layer, increasing junction capacitance. However, in an SRAM transistor, reduction in junction capacitance does not significantly contribute to improving transistor performance, but rather, larger junction capacitance advantageously contribute to providing more effective shielding against alpha radiation. Moreover, since the body is connected to the body contact via the diffusion region underlying the S/D region as well as the diffusion region formed between the SOI layer and the BOX layer, the resistance of body is reduced. Accordingly, even when one body contact is not formed so as to correspond to each of individual transistors, i.e., is formed to correspond to a plurality of transistors, for example, 8 to 16 transistors, the potential of body can securely be fixed, allowing further increase in the density of SRAM cells. Beneficial effects produced by employment of the embodiment and excluding the aforementioned effects are the same as those produced by employment of the aforementioned eighth embodiment.

It should be appreciated that when utilizing as it is the design property of a conventional semiconductor device formed in a bulk material, in some cases, a body contact happens to be formed in the vicinity of a transistor even within the Body-Floating type SOI region 42. However, since the STI region 4a as a completely isolating film exists between the body contact and the transistor, the body contact never affects BF type SOI transistor performance.

What is claimed is:

1. A semiconductor device comprising:
a semiconductor substrate;
an insulation film formed on said semiconductor substrate;
a semiconductor layer formed on said insulation film;
a well of a first conductivity type locally formed in said semiconductor layer;
a transistor of a second conductivity type formed in said well of a first conductivity type; and
a field isolation region formed in a surface of said semiconductor layer and isolating said transistor of a second conductivity type from other transistor components within said semiconductor layer,
said well of a first conductivity type comprising:
first diffusion regions of a first conductivity type formed directly below source/drain regions of said transistor of a second conductivity type;
a second diffusion region of a first conductivity type formed in a region between said insulation film and said field isolation region, said second diffusion region having a dopant concentration higher than that of said first diffusion region of a first conductivity type;
a third diffusion region of a first conductivity type formed at the same level as said second diffusion region of a first conductivity type and directly below a channel region of said transistor, said third diffusion region having a dopant concentration higher than that of said first diffusion region of a first conductivity type; and
a fourth diffusion region of a first conductivity type formed in a surface portion of a region connected to said third diffusion region of a first conductivity type, said fourth diffusion region allowing a reference voltage to be applied thereto.

2. A semiconductor device comprising:
a semiconductor substrate;
an insulation film formed on said semiconductor substrate;
a semiconductor layer formed on said insulation film;
a P well and an N well formed in said semiconductor layer;
an N type transistor and a P type transistor formed in said P well and said N well, respectively; and
a field isolation region formed in surface of said P well and said N well, and isolating each of said N type transistor and said P type transistor from other transistor components,
said P well comprising:
first P type diffusion regions formed directly below source/drain regions of said N type transistor;
a second P type diffusion region formed in a region between said insulation film and said field isolation region, and having a dopant concentration higher than that of said first P type diffusion region;
a third P type diffusion region formed at the same level as said second P type diffusion region and formed directly below a channel region of said N type transistor, said third P type diffusion region having a dopant concentration higher than that of said first P type diffusion region; and
a fourth P type diffusion region formed in a surface portion of a region connected to said third P type diffusion region, said fourth P type diffusion region allowing a first reference voltage to be applied thereto;
said N well including:
first N type diffusion regions formed directly below source/drain regions of said P type transistor;
a second N type diffusion region formed in a region between said insulation film and said field isolation region, and having a dopant concentration higher than that of said first N type diffusion region;
a third N type diffusion region formed at the same level as said second N type diffusion region and directly below a channel region of said P type transistor, and having a dopant concentration higher than that of said first N type diffusion region; and
a fourth N type diffusion region formed in a surface portion of a region connected to said third N type diffusion region, said fourth N type diffusion region allowing a second reference voltage to be applied thereto.

3. The semiconductor device according to claim 2, wherein said second reference voltage is higher than said first reference voltage and wherein both said second P type diffusion region and said second N type diffusion region are disposed in a region positioned between said field isolation region and said insulation film and further between said N type transistor and said P type transistor so as to contact each other.

4. The semiconductor device according to claim 2, wherein a lower end of said field isolation region positioned between said N type transistor and said P type transistor contacts an upper surface of said insulation film.

5. The semiconductor device according to claim 4, wherein a lower end of at least one of said field isolation region surrounding said N type transistor and said field isolation region surrounding said P type transistor contacts an upper surface of said insulation film.

6. The semiconductor device according to claim 2, wherein said N type transistor and said P type transistor share a gate electrode and wherein said fourth P type diffusion region, said N type transistor, said P type transistor and said fourth N type diffusion region are arranged in this order in a line.

7. The semiconductor device according to claim 2, further comprising another field isolation region formed between a region occupied by said P type transistor and a region occupied by said fourth P type diffusion region.

8. The semiconductor device according to claim 2, further comprising another field isolation region formed between a region occupied by said N type transistor and a region occupied by said fourth N type diffusion region.

9. The semiconductor device according to claim 2, wherein said fourth P type diffusion region is formed in a region of said semiconductor layer so as to interpose a part of said field isolation region between said N type transistor and said region of said semiconductor layer and wherein said second P type diffusion region is formed between said part of said field isolation region and said insulation film, and wherein said first reference voltage is applied to said third P type diffusion region via said second P type diffusion region and said fourth P type diffusion region.

10. The semiconductor device according to claim 2, wherein said fourth N type diffusion region is formed in a region of said semiconductor layer so as to interpose a part of said field isolation region between said P type transistor and said region of said semiconductor layer and wherein said second N type diffusion region is formed between said part of said field isolation region and said insulation film, and wherein said second reference voltage is applied to said third N type diffusion region via said second N type diffusion region and said fourth N type diffusion region.

11. A semiconductor device comprising:
a semiconductor substrate;
an insulation film formed on said semiconductor substrate;
a semiconductor layer formed on said insulation film;
a well of a first conductivity type formed in said semiconductor layer;
a first transistor of a second conductivity type and a second transistor of a second conductivity type, both transistors being formed in said well of a first conductivity type; and
a field isolation region formed in a surface of said semiconductor layer and isolating each of said first and second transistors of a second conductivity type from other transistor components,
said well of a first conductivity type comprising:
first diffusion regions of a first conductivity type formed directly below source/drain regions of said first transistor of a second conductivity type;
a second diffusion region of a first conductivity type formed in a region between said insulation film and said field isolation region, and having a dopant concentration higher than that of said first diffusion region of a first conductivity type;
a third diffusion region of a first conductivity type formed at the same level as said second diffusion region of a first conductivity type and directly below a channel region of each of said first and second transistor of a second conductivity type, and having a dopant concentration higher than that of said first diffusion region of a first conductivity type;
a fourth diffusion region of a first conductivity type formed in a surface portion of a region connected to said third diffusion region of a first conductivity type, said fourth diffusion region allowing a reference voltage to be applied thereto; and
fifth diffusion regions of a first conductivity type formed directly below source/drain regions of said second transistor of a second conductivity type, and having a dopant concentration higher than that of said first diffusion region of a first conductivity type.

12. The semiconductor device according to claim 11, wherein a lower end of said field isolation region positioned between said first transistor of a second conductivity type and said second transistor of a second conductivity type contacts an upper surface of said insulation film.

13. The semiconductor device according to claim 12, wherein a lower end of at least one of said field isolation region surrounding said first transistor of a second conductivity type and said field isolation region surrounding said second transistor of a second conductivity type contacts an upper surface of said insulation film.

14. A semiconductor device comprising:
a semiconductor substrate;
an insulation film formed on said semiconductor substrate;
a semiconductor layer formed on said insulation film;
a well of a first conductivity type locally formed in said semiconductor layer;
first and second transistors of a second conductivity type formed in said well of a first conductivity type;
a first field isolation region formed in a surface of said semiconductor layer and having a lower surface positioned such that at least a part of said lower surface does not contact said insulation film, said first field isolation region isolating said first transistor of a second conductivity type from other transistor components; and
a second field isolation region formed in a surface of said semiconductor layer and having a lower surface positioned so as to contact said insulation film, said second field isolation region isolating said second transistor of a second conductivity type from other transistor components,
said well of a first conductivity type comprising:
first diffusion regions of a first conductivity type formed directly below source/drain regions of each of said first and second transistors of a second conductivity type;
a second diffusion region of a first conductivity type formed in a region between said insulation film and said first field isolation region, and having a dopant concentration higher than that of said first diffusion region of a first conductivity type;
a third diffusion region of a first conductivity type formed at the same level as said second diffusion region of a first conductivity type and directly below a channel region of each of said first and second transistors of a second conductivity type, and having a dopant concentration higher than that of said first diffusion region of a first conductivity type; and
a fourth diffusion region of a first conductivity type formed in a surface portion of a region connected to said third diffusion region of a first conductivity type via said second diffusion region of a first conductivity type, said third diffusion region being positioned in said first transistor of a second conductivity type, said fourth diffusion region allowing a reference voltage to be applied thereto.

15. A semiconductor device comprising:
a semiconductor substrate;
an insulation film formed on said semiconductor substrate;
a semiconductor layer formed on said insulation film;
a P well and an N well, both being locally formed in said semiconductor layer;
first and second N type transistors formed in said P well;
first and second P type transistors formed in said N well;
a first field isolation region formed in a surface of said semiconductor layer and having a lower surface positioned such that at least a part of said lower surface does not contact said insulation film, said first field isolation region isolating each of said first P type transistor and said first N type transistor from other transistor components; and
a second field isolation region formed in a surface of said semiconductor layer and having a lower surface positioned so as to contact said insulation film, said second field isolation region isolating each of said second P type transistor and said second N type transistor from other transistor components, said P well including:
first P type diffusion regions formed directly below source/drain regions of each of said first and second N type transistors;
a second P type diffusion region formed in a region between said insulation film and said first field isolation region, and having a dopant concentration higher than that of said first P type diffusion region;
a third P type diffusion region formed at the same level as said second P type diffusion region and directly below a channel region of each of said first and second N type transistors, and having a dopant concentration higher than that of said first P type diffusion region; and
a fourth P type diffusion region formed in a surface portion of a region connected via said second P type diffusion region to said third P type diffusion region of said first N type transistor, said fourth P type diffusion region allowing a first reference voltage to be applied thereto,
said N well comprising:
first N type diffusion regions formed directly below source/drain regions of each of said first and second P type transistors;
a second N type diffusion region formed in a region between said insulation film and said first field isolation region, and having a dopant concentration higher than that of said first N type diffusion region;
a third N type diffusion region formed at the same level as said second N type diffusion region and directly below a channel region of each of said first and second P type transistors, and having a dopant concentration higher than that of said first N type diffusion region; and
a fourth N type diffusion region formed in a surface portion of a region connected via said second N type diffusion region to the third N type diffusion region of said first P type transistor, said fourth N type diffusion region allowing a second reference voltage to be applied thereto.

16. The semiconductor device according to claim 15, further comprising a third N type transistor and a third P type transistor, wherein said P well comprises a fifth P type diffusion region formed directly below a channel region and source/drain regions of said third N type transistor and having a dopant concentration higher than that of said first P type diffusion region, and wherein said N well comprises a fifth N type diffusion region formed directly below a channel region and source/drain regions of said third P type transistor and having a dopant concentration higher than that of said first N type diffusion region.

17. The semiconductor device according to claim 15, wherein said fourth P type diffusion region is formed in a region of said semiconductor layer so as to interpose a part of said first field isolation region between said first N type transistor and said region of said semiconductor layer and wherein said second P type diffusion region is formed between said part of said first field isolation region and said insulation film, and wherein said first reference voltage is applied to said third P type diffusion region via said second P type diffusion region and said fourth P type diffusion region.

18. The semiconductor device according to claim 15, wherein said fourth N type diffusion region is formed in a region of said semiconductor layer so as to interpose a part of said first field isolation region between said first P type transistor and said region of said semiconductor layer and wherein said second N type diffusion region is formed between said part of said first field isolation region and said insulation film, and wherein said second reference voltage is applied to said third N type diffusion region via said second N type diffusion region and said fourth N type diffusion region.

19. The semiconductor device according to claim 1, wherein a thickness of said semiconductor layer ranges from 50 to 300 nm.

20. A method for manufacturing a semiconductor device comprising the steps of:
forming an insulation film on a semiconductor substrate;
forming a semiconductor layer on said insulation film;
forming a well of a first conductivity type within said semiconductor layer;
forming a field isolation region in a surface of said semiconductor layer;
forming a second diffusion region of a first conductivity type between said insulation film and said field isolation region within said well of a first conductivity type, and further, forming a fourth diffusion region of a first conductivity type in a part of a surface portion of said well of a first conductivity type, said fourth diffusion region allowing a reference voltage to be applied thereto;
forming a gate insulating film and a gate electrode on said well of a first conductivity type;
implanting dopants of a first conductivity type within said semiconductor layer through said gate insulating film and said gate electrode to form a third diffusion region of a first conductivity type in a region positioned directly below said gate electrode and at the same level as said second diffusion region of a first conductivity type within said semiconductor layer; and
implanting dopants of a second conductivity type into a surface portion of said well of a first conductivity type using said gate insulating film and said gate electrode as a mask to form source/drain regions in specific regions within said well of a first conductivity type, resulting in formation of a transistor of a second conductivity type, said specific regions interposing a region positioned directly below said gate electrode therebetween.

21. A method for manufacturing a semiconductor device comprising the steps of:
forming an insulation film on a semiconductor substrate;
forming a semiconductor layer on said insulation film;
forming a well of a first conductivity type within said semiconductor layer;
forming a field isolation region in a surface of said semiconductor layer;
implanting dopants of a first conductivity type into said well of a first conductivity type to form a second diffusion region of a first conductivity type in a region between said insulation film and said field isolation region within said well of a first conductivity type, and further, form a third diffusion region of a first conductivity type and a fourth diffusion region of a first conductivity type in a part of a surface portion of said well of a first conductivity type, said fourth diffusion region allowing a reference voltage to be applied thereto;
forming a gate insulating film and a gate electrode on said third diffusion region of a first conductivity type; and
implanting dopants of a second conductivity type into a surface portion of said well of a first conductivity type using said gate insulating film and said gate electrode as a mask to form source/drain regions in specific regions within said well of a first conductivity type, resulting in formation of a transistor of a second conductivity type, said specific regions interposing a region positioned directly below said gate electrode therebetween.

22. A method for manufacturing a semiconductor device comprising the steps of:
forming an insulation film on a semiconductor substrate;
forming a semiconductor layer on said insulation film;
forming a field isolation region in a surface of said semiconductor layer;
forming a well of a first conductivity type within said semiconductor layer;
forming a gate insulating film and a gate electrode on said semiconductor layer;
implanting dopants of a second conductivity type into said well of a first conductivity type using said gate insulating film and said gate electrode as a mask to form first diffusion regions of a first conductivity type in specific regions within said well of a-first conductivity type, said specific regions interposing a region positioned directly below said gate electrode therebetween, said first diffusion regions having a net dopant concentration lower than that of said well of a first conductivity type; and
implanting dopants of a second conductivity type into a surface portion of said well of a first conductivity type using said gate insulating film and said gate electrode as a mask to form source/drain regions in specific regions within said well of a first conductivity type, resulting in formation of a transistor of a second conductivity type, said specific regions interposing a region positioned directly below said gate electrode therebetween.

23. The method for manufacturing a semiconductor device according to claim 20, wherein in the step of forming said field isolation region, said field isolation region is formed to have a part of a lower end thereof positioned so as to contact said insulation film.

24. The method for manufacturing a semiconductor device according to claim 20, wherein in the step of forming said field isolation region, said field isolation region is formed to have a lower end thereof positioned so as not to contact said insulation film.

25. A method for manufacturing a semiconductor device comprising the steps of:
forming an insulation film on a semiconductor substrate;
forming a semiconductor layer on said insulation film;
forming a P well and an N well within said semiconductor layer;
forming a field isolation region in a surface of said semiconductor layer;
forming a second P type diffusion region in a region between said insulation film and said field isolation region within said P well, and further, forming a fourth P type diffusion region in a part of a surface portion of said P well, said fourth P type diffusion region allowing a reference voltage to be applied thereto;
forming a second N type diffusion region in a region between said insulation film and said field isolation region within said N well, and further, forming a fourth N type diffusion region in a part of a surface portion of said N well, said fourth N type diffusion region allowing a reference voltage to be applied thereto;
forming a gate insulating film and a gate electrode on each of said P well and said N well;
implanting P type dopants within said P well through said gate insulating film and said gate electrode to form a third P type diffusion region in a region positioned directly below said gate electrode and at the same level as said second P type diffusion region within said P well;
implanting N type dopants within said N well through said gate insulating film and said gate electrode to form a third N type diffusion region in a region positioned directly below said gate electrode and at the same level as said second N type diffusion region within said N well;
implanting N type dopants into a surface portion of said P well using said gate insulating film and said gate electrode as a mask to form source/drain regions in specific regions within said P well, resulting in formation of an N type transistor, said specific regions interposing a region positioned directly below said gate electrode therebetween; and
implanting P type dopants into a surface portion of said N well using said gate insulating film and said gate electrode as a mask to form source/drain regions in specific regions within said N well, resulting in formation of a P type transistor, said specific regions interposing a region positioned directly below said gate electrode therebetween.

26. A method for manufacturing a semiconductor device comprising the steps of:
forming an insulation film on a semiconductor substrate;
forming a semiconductor layer on said insulation film;
forming a P well and an N well within said semiconductor layer;
forming a field isolation region in a surface of said semiconductor layer;
implanting P type dopants into said P well to form a second P type diffusion region in a region between said insulation film and said field isolation region within said P well, and further, form a third P type diffusion region and a fourth P type diffusion region in a part of a surface portion of said P well, said fourth P type diffusion region allowing a first reference voltage to be applied thereto;
implanting N type dopants into said N well to form a second N type diffusion region in a region between said insulation film and said field isolation region within said N well, and further, form a third N type diffusion region and a fourth N type diffusion region in a part of a surface portion of said N well, said fourth N type diffusion region allowing a second reference voltage to be applied thereto;
forming a gate insulating film and a gate electrode on each of said third P type diffusion region and said third N type diffusion region;
implanting N type dopants into a surface portion of said P well using said gate insulating film and said gate electrode as a mask to form source/drain regions in specific regions within said P well, resulting in formation of an N type transistor, said specific regions interposing a region positioned directly below said gate electrode therebetween; and
implanting P type dopants into a surface portion of said N well using said gate insulating film and said gate electrode as a mask to form source/drain regions in specific regions within said N well, resulting in formation of a P type transistor, said specific regions interposing a region positioned directly below said gate electrode therebetween.

27. A method for manufacturing a semiconductor device comprising the steps of:
forming an insulation film on a semiconductor substrate;
forming a semiconductor layer on said insulation film;
forming a field isolation region in a surface of said semiconductor layer;
forming a P well and an N well within said semiconductor layer;
forming a gate insulating film and a gate electrode on each of said P well and said N well;
implanting N type dopants into said P well using said gate insulating film and said gate electrode as a mask to form first P type diffusion regions in specific regions within said P well, said specific regions interposing a region positioned directly below said gate electrode therebetween, said first P type diffusion regions having a net dopant concentration lower than that of said P well;
implanting P type dopants into said N well using said gate insulating film and said gate electrode as a mask to form first N type diffusion regions in specific regions within said N well, said specific regions interposing a region positioned directly below said gate electrode therebetween, said first N type diffusion regions having a net dopant concentration lower than that of said N well;
implanting N type dopants into a surface portion of said P well using said gate insulating film and said gate electrode as a mask to form source/drain regions in specific regions within said P well, resulting in formation of an N type transistor, said specific regions interposing a region positioned directly below said gate electrode therebetween; and
implanting P type dopants into a surface portion of said N well using said gate insulating film and said gate electrode as a mask to form source/drain regions in specific regions within said N well, resulting in formation of a P type transistor, said specific regions interposing a region positioned directly below said gate electrode therebetween.

28. A method for manufacturing a semiconductor device comprising the steps of:
forming an insulation film on a semiconductor substrate;
forming a semiconductor layer on said insulation film;
forming a P well and an N well within said semiconductor layer;
forming a field isolation region in a surface of said semiconductor layer;
implanting P type dopants into a portion of said P well to form a third P type diffusion region and further form a second P type diffusion region in a region between said insulation film and said field isolation region;
implanting N type dopants into a portion of said N well to form a third N type diffusion region and further form a second N type diffusion region in a region between said insulation film and said field isolation region;
forming a gate insulating film and a gate electrode on each of said third P type diffusion region and said third N type diffusion region; and
implanting N type dopants into a surface portion of said P well using said gate insulating film and said gate electrode as a mask to form source/drain regions in specific regions within said P well, resulting in formation of an N type transistor, said specific regions interposing a region positioned directly below said gate electrode therebetween;
implanting P type dopants into a surface portion of said N well using said gate insulating film and said gate electrode as a mask to form source/drain regions in specific regions within said N well, resulting in formation of a P type transistor, said specific regions interposing a region positioned directly below said gate electrode therebetween;
forming a fourth P type diffusion region in a part of a surface portion of said P well, said fourth P type diffusion region allowing a reference voltage to be applied thereto; and
forming a fourth N type diffusion region in a part of a surface portion of said N well, said fourth N type diffusion region allowing a reference voltage to be applied thereto.

29. The method for manufacturing a semiconductor device according to claim 25, wherein a lower end of each of said field isolation regions formed within said P well and said N well is not in contact with said insulation film.

30. The method for manufacturing a semiconductor device according to claim 25, wherein a lower end of said field isolation region formed in a boundary between said P well and said N well is in contact with said insulation film.

31. A method for manufacturing a semiconductor device comprising the steps of:
forming an insulation film on a semiconductor substrate;
forming a semiconductor layer on said insulation film;
locally forming a well of a first conductivity type within said semiconductor layer;
forming a first trench in a surface of said semiconductor layer, said first trench being formed so as not to reach said insulation film;
forming a second trench in a part of said first trench, said second trench being formed so as to reach said insulation film;
implanting dopants of a first conductivity type into a portion of a region surrounded by said first trench within said well of a first conductivity type to form a second diffusion region of a first conductivity type;
filling said first and second trenches with an insulating material to form first and second field isolation regions, respectively;
implanting dopants of a first conductivity type into a portion of said well of a first conductivity type to form a third diffusion region of a first conductivity type and further form a fourth diffusion region of a first conductivity type connected via said second diffusion region of a first conductivity type to said third diffusion region of a first conductivity type, said third diffusion region being formed in a region partitioned by said first field isolation region, said fourth diffusion region allowing a reference voltage to be applied thereto; and
forming source/drain regions in first diffusion regions of a first conductivity type, said first diffusion regions interposing said third diffusion region of a first conductivity type therebetween, and further, forming a gate insulating film and a gate electrode on said third diffusion region of a first conductivity type, resulting in formation of a first transistor of a second conductivity type in a region partitioned by said first field isolation region and formation of a second transistor of a second conductivity type in a region partitioned by said second field isolation region.

32. A method for manufacturing a semiconductor device comprising the steps of:
forming an insulation film on a semiconductor substrate;
forming a semiconductor layer on said insulation film;
locally forming a P well and an N well within said semiconductor layer;
forming a first trench in a surface of said semiconductor layer, said first trench being formed so as not to reach said insulation film;
forming a second trench in a part of said first trench, said second trench being formed so as to reach said insulation film;
implanting P type dopants into a portion of a region surrounded by said first trench within said P well to form a second P type diffusion region;
implanting N type dopants into a portion of a region surrounded by said first trench within said N well to form a second N type diffusion region;
filling said first and second trenches with an insulating material to form first and second field isolation regions, respectively;
implanting P type dopants into a portion of said P well to form a third P type diffusion region and further form a fourth P type diffusion region connected via said second P type diffusion region to said third P type diffusion region, said third P type diffusion region being formed in a region partitioned by said first field isolation region, said fourth P type diffusion region allowing a first reference voltage to be applied thereto;
implanting N type dopants into a portion of said N well to form a third N type diffusion region and further form a fourth N type diffusion region connected via said second N type diffusion region to said third N type diffusion region, said third N type diffusion region being formed in a region partitioned by said first field isolation region, said fourth N type diffusion region allowing a second reference voltage to be applied thereto;
forming source/drain regions in first P type diffusion regions, said first P type diffusion regions interposing said third P type diffusion region therebetween, and further, forming a gate insulating film and a gate electrode on said third P type diffusion region, resulting in formation of a first N type transistor in a region partitioned by said first field isolation region and formation of a second N type transistor in a region partitioned by said second field isolation region; and
forming source/drain regions in first N type diffusion regions, said first N type diffusion regions interposing said third N type diffusion region therebetween, and further, forming a gate insulating film and a gate electrode on said third N type diffusion region, resulting in formation of a first P type transistor in a region partitioned by said first field isolation region and formation of a second P type transistor in a region partitioned by said second field isolation region.

33. The method for manufacturing a semiconductor device according to claim 32, further comprising the steps of:
implanting P type dopants into another portion of a region surrounded by said first trench within said P well to
